(19) United States
(12) Patent Application Publication
(10) Pub. No.: US 2024/0328308 A1
(43) Pub. Date: Oct. 3, 2024

(54) WELL LOG PREDICTIVE SYSTEMS AND METHODS FOR DRILLING

(71) Applicant: Helmerich & Payne Technologies, LLC, Tulsa, OK (US)

(72) Inventors: Hyungjoo Lee, Denver, CO (US); Alexander Michael Mitkus, Denver, CO (US); Andrew Robert Pare, Littleton, CO (US); Kenneth Robert McCarthy, Lakewood, CO (US); Marc Ernest Willerth, San Luis Obispo, CA (US); Paul Reynerson, Denver, CO (US); Tannor James Ziehm, Highlands Ranch, CO (US); Timothy William Gee, Littleton, CO (US)

(21) Appl. No.: 18/618,189

(22) Filed: Mar. 27, 2024

Related U.S. Application Data
(60) Provisional application No. 63/507,680, filed on Jun. 12, 2023.
(60) Provisional application No. 63/492,469, filed on Mar. 27, 2023.

(51) Int. Cl. E21B 47/12; G01V 5/12; G06N 20/00

(52) U.S. Cl. CPC E21B 47/12; G01V 5/12; G06N 20/00; E21B 2200/20

(57) ABSTRACT

In some implementations, a computing device may include receiving one or more measurements of drilling parameters. In addition, the computing device may include accessing historical drilling logs for one or more wells in a geographic region. Also, the computing device may include training, using one or more processors, a machine learning model to determine predicted values for a triple combo log for a new well in the geographic region. Further, the computing device may include determining, using the one or more processors, one or more formation properties from the triple combo log. In addition, the computing device may include determining, using the one or more processors, an adjustment to one or more drilling parameters based at least on the one or more formation properties. The adjustment can be applied to a drilling process on a drilling rig.

### CROSS-REFERENCES TO RELATED APPLICATIONS

This application claims the benefit of U.S. Provisional Application No. 63/492,469, filed on Mar. 27, 2023, and entitled WELL LOG PREDICTIVE SYSTEMS AND METHODS FOR DRILLING, and further claims the benefit of U.S. Provisional Application No. 63/507,680, filed on Jun. 12, 2023, and entitled WELL LOG PREDICTIVE SYSTEMS AND METHODS FOR DRILLING, both of which are hereby incorporated by reference in their entireties.

### BACKGROUND

### Field of the Disclosure

The present disclosure provides systems and methods useful for drilling a well, such as an oil and gas well. The systems and methods can be computer-implemented using processor executable instructions for execution on a processor and can accordingly be executed with a programmed computer system.

### Description of the Related Art

Drilling a borehole for the extraction of minerals has become an increasingly complicated operation due to the increased depth and complexity of many boreholes, including the complexity added by directional drilling. Drilling is an expensive operation and errors in drilling add to the cost and, in some cases, drilling errors may permanently lower the output of a well for years into the future. Conventional technologies and methods may not adequately address the complicated nature of drilling and may not be capable of gathering and processing various information from downhole sensors and surface control systems in a timely manner, in order to improve drilling operations and minimize drilling errors.

In the oil and gas industry, extraction of hydrocarbon natural resources is done by physically drilling a hole to a reservoir where the hydrocarbon natural resources are trapped. The hydrocarbon natural resources can be up to 10,000 feet or more below the ground surface and be buried under various layers of geological formations. Drilling operations can be conducted by having a rotating drill bit mounted on a bottom hole assembly (BHA) that gives direction to the drill bit for cutting through geological formations and enabled steerable drilling.

Triple combo (sometimes “combination”) logs are measurements for estimating geological, petrophysical and geomechanical properties. Unfortunately, wireline and advanced logging while drilling (LWD) logs are typically dropped from the formation evaluation plan for unconventional wells due to economic constraints or borehole instability risks. Available measurements are typically measurement while drilling (MWD) natural Gamma Ray (GR) logs along with surface measurements such as weight-on-bit (WOB), rate of penetration (ROP), torque, rotations per minute (RPM), and differential pressure. The development of a robust and rapid model for predicting reservoir properties using this limited dataset would be of high value for geological evaluation. Estimating such properties is a challenging task due to the nonlinear relationship between the available log data and unknown reservoir properties.

### SUMMARY

A system of one or more computers can be configured to perform particular operations or actions by virtue of having software, firmware, hardware, or a combo of them installed on the system that in operation causes or cause the system to perform the actions. One or more computer programs can be configured to perform particular operations or actions by virtue of including instructions that, when executed by data processing apparatus, cause the apparatus to perform the actions.

In one general aspect, a method for drilling a borehole may include receiving one or more measurements of drilling parameters. A method for drilling a borehole may in addition include accessing historical drilling logs for one or more wells in a geographic region. A method for drilling a borehole may also include training, using one or more processors, a machine learning model to determine predicted values for a triple combo log for a new well in the geographic region. A “triple combo log” generally refers to the typical set of well logs used for formation evaluation and logging. These logs usually include gamma ray, resistivity, and porosity logs (the latter usually comprising neutron porosity and bulk density logs). A method for drilling a borehole may further include determining, using the one or more processors, one or more formation properties from the triple combo log. A method for drilling a borehole may in addition include determining, using the one or more processors, an adjustment to one or more drilling parameters based at least on the one or more formation properties. Other embodiments of this aspect include corresponding computer systems, apparatus, and computer programs recorded on one or more computer storage devices, each configured to perform the actions of the methods.

Implementations may include one or more of the following features. The method of where the drilling parameters may include one or more of WOB, ROP, torque, RPM, or differential pressure. The method of where the historical drilling logs may include one or more of values for gamma ray, resistivity, neutron porosity, or bulk density. The method of where the training the machine learning model uses one or more of depth shifting, outlier detection, and feature selection to tune one or more parameters of the machine learning model. The method may include applying one or more gradient boosting algorithms to train predictions sequentially for predicted values for the triple combo log. The method of where the one or more formation properties are predicted by applying a physics-based joint inversion model to the predicted values for the triple combo log. The method may include determining one or more of reservoir properties and may include total porosity, clay volume, water saturation, volumetric concentrations of lithology, permeability, rock type, fluid pressure, differential pressure, various other pressures, total organic carbon, and/or other geomechanical parameters. The method further may include determining a geologic model using the predicted values for a triple combo log; and validating the geologic model using one or more of mud logs and Elemental Capture Spectroscopy measurements. The method may include identifying rock type of a formation using the triple combo log. Implementations of the described techniques may include hardware, a method or process, or a computer tangible medium.

In one general aspect, a system for drilling a borehole may include one or more sensors. A system for drilling a borehole may in addition include a drilling rig. A system for drilling a borehole may also include one or more processors. A system for drilling a borehole may further include a memory storing instructions when executed by the one or more processors perform operations, may include: receiving one or more measurements of drilling parameters from the one or more sensors; accessing historical drilling logs for one or more wells in a geographic region; training, using one or more processors, a machine learning model to determine predicted values for a triple combo log for a new well in the geographic region; determining, using the one or more processors, one or more formation properties from the triple combo log; determining, using the one or more processors, an adjustment to one or more drilling parameters; and drilling the borehole using the adjustment to the one or more drilling parameters at the drilling rig. Other embodiments of this aspect include corresponding computer systems, apparatus, and computer programs recorded on one or more computer storage devices, each configured to perform the actions of the methods.

Implementations may include one or more of the following features. The system of where the drilling parameters may include one or more of weight-on-bit, rate of penetration, torque, rotations per minute, or differential pressure. The system of where the historical drilling logs may include one or more of values for gamma ray, resistivity, neutron porosity, or bulk density. The system of where the training the machine learning model uses one or more of depth shifting, outlier detection, and feature selection to tune one or more parameters of the machine learning model. The system of where the operations further may include applying one or more gradient boosting algorithms to train predictions sequentially for predicted values for the triple combo log. The system of where the one or more formation properties are predicted by applying a physics-based joint inversion model to the predicted values for the triple combo log. The system of where the operations further may include determining one or more of reservoir properties may include total porosity, clay volume, water saturation, volumetric concentrations of lithology, permeability, rock type, or geomechanical parameters. The system where the operations further where the operations further may include determining a geologic model using the predicted values for a triple combo log; and validating the geologic model using one or more of mud logs and Elemental Capture Spectroscopy measurements. The system of where the operations further may include identifying rock type of a formation using the triple combo log. Implementations of the described techniques may include hardware, a method or process, or a computer tangible medium.

In one general aspect, a non-transitory computer readable medium storing instructions that when executed by one or more processors perform operations may include receiving one or more measurements of drilling parameters from the one or more sensors. A non-transitory computer readable medium storing instructions that when executed by one or more processors perform operations may in addition include accessing historical drilling logs for one or more wells in a geographic region. A non-transitory computer readable medium storing instructions that when executed by one or more processors perform operations may also include training, using one or more processors, a machine learning model to determine predicted values for a triple combo log for a new well in the geographic region. A non-transitory computer readable medium storing instructions that when executed by one or more processors perform operations may further include determining, using the one or more processors, one or more formation properties from the triple combo log. A non-transitory computer readable medium storing instructions that when executed by one or more processors perform operations may in addition include determining, using the one or more processors, an adjustment to one or more drilling parameters. A non-transitory computer readable medium storing instructions that when executed by one or more processors perform operations may also include drilling the borehole using the adjustment to the one or more drilling parameters at the drilling rig. Other embodiments of this aspect include corresponding computer systems, apparatus, and computer programs recorded on one or more computer storage devices, each configured to perform the actions of the methods.

Implementations may include one or more of the following features. The non-transitory computer readable medium of where the drilling parameters may include one or more of weight-on-bit, rate of penetration, torque, rotations per minute, or differential pressure. The non-transitory computer readable medium of where the historical drilling logs may include one or more of values for gamma ray, resistivity, neutron porosity, or bulk density. The non-transitory computer readable medium of where the training the machine learning model uses one or more of depth shifting, outlier detection, and feature selection to tune one or more parameters of the machine learning model. The non-transitory computer readable medium of where the operations further may include applying one or more gradient boosting algorithms to train predictions sequentially for predicted values for the triple combo log. The non-transitory computer readable medium of where the one or more formation properties are predicted by applying a physics-based joint inversion model to the predicted values for the triple combo log. The non-transitory computer readable medium of where the operations further may include determining one or more of reservoir properties may include total porosity, clay volume, water saturation, volumetric concentrations of lithology, permeability, rock type, or geomechanical parameters. The non-transitory computer readable medium where the operations further where the operations further may include determining a geologic model using the predicted values for a triple combo log; and validating the geologic model using one or more of mud logs and Elemental Capture Spectroscopy measurements. The non-transitory computer readable medium of where the operations further may include identifying rock type of a formation using the triple combo log. Implementations of the described techniques may include hardware, a method or process, or a computer tangible medium.

### BRIEF DESCRIPTION OF THE DRAWINGS

For a more complete understanding of the present invention and its features and advantages, reference is now made to the following description, taken in conjunction with the accompanying drawings, in which:

FIG. 1 is a depiction of a drilling system for drilling a borehole;

FIG. 2 is a depiction of a drilling environment including the drilling system for drilling a borehole;

FIG. 3 is a depiction of a borehole generated in the drilling environment;

FIG. 4 is a depiction of a drilling architecture including the drilling environment;

FIG. 5 is a depiction of rig control systems included in the drilling system;

FIG. 6 is a depiction of algorithm modules used by the rig control systems;

FIG. 7 is a depiction of a steering control process used by the rig control systems;

FIG. 8 is a depiction of a graphical user interface provided by the rig control systems;

FIG. 9 is a depiction of a guidance control loop performed by the rig control systems;

FIG. 10 is a depiction of a controller usable by the rig control systems;

FIG. 11 illustrates an exemplary process for well log and rock property prediction;

FIGS. 12A-B illustrate an exemplary well data log including a triple combo log;

FIG. 13 illustrates a map of various wells in a geographic region;

FIG. 14 illustrates an exemplary Kullback-Leibler divergence matrix for a plurality of wells;

FIGS. 15A-B illustrate a log of measurements of drilling dynamics;

FIG. 16 illustrates an exemplary pair of a particular well;

FIG. 17 illustrates an exemplary process for extreme gradient boosting regression;

FIGS. 18A-B illustrate an exemplary graphical representation for extreme gradient boosting regression;

FIGS. 19A-D illustrate exemplary prediction results for predicting triple combo logs;

FIGS. 20A-C illustrate an exemplary Gamma Ray prediction graph;

FIG. 21 illustrates an exemplary resistivity prediction graph;

FIG. 22 illustrates an exemplary density prediction graph;

FIG. 23 illustrates an exemplary neutron prediction graph;

FIG. 24 illustrates an exemplary shear sonic slowness graph;

FIG. 25 illustrates an exemplary Leverett Rock classification prediction graph;

FIG. 26 illustrates an exemplary Winland R35 Rock classification graph;

FIG. 27 illustrates an exemplary Lorenz Rock Classification graph;

FIG. 28 illustrates first exemplary drill logs for a first well;

FIGS. 29A-D illustrate second exemplary drill logs for a second well;

FIGS. 30A-D illustrate a comparison plot for geologic models and rock types inverted from measured triple combo logs and reconstructed triple combo logs; and

FIG. 31 illustrates an example process for drilling a well.

Like reference symbols in the various drawings indicate like elements, in accordance with certain example implementations. In addition, multiple instances of an element may be indicated by following a first number for the element with a letter or a hyphen and a second number.

### DESCRIPTION

In the following description, details are set forth by way of example to facilitate discussion of the disclosed subject matter. It is noted, however, that the disclosed embodiments are exemplary and not exhaustive of all possible embodiments.

Throughout this disclosure, a hyphenated form of a reference numeral refers to a specific instance of an element and the un-hyphenated form of the reference numeral refers to the element generically or collectively. Thus, as an example (not shown in the drawings), device “12-1” refers to an instance of a device class, which may be referred to collectively as devices “12” and any one of which may be referred to generically as a device “12”. In the FIGS. and the description, like numerals are intended to represent like elements.

Drilling a well typically involves a substantial amount of human decision-making during the drilling process. For example, geologists and drilling engineers use their knowledge, experience, and the available information to make decisions on how to plan the drilling operation, how to accomplish the drilling plan, and how to handle issues that arise during drilling. However, even the best geologists and drilling engineers perform some guesswork due to the unique nature of each borehole. Furthermore, a directional human driller performing the drilling may have drilled other boreholes in the same region and so may have some similar experience. However, during drilling operations, a multitude of input information and other factors may affect a drilling decision being made by a human operator or specialist, such that the amount of information may overwhelm the cognitive ability of the human to properly consider and factor into the drilling decision. Furthermore, the quality or the error involved with the drilling decision may improve with larger amounts of input data being considered, for example, such as formation data from a large number of offset wells. For these reasons, human specialists may be unable to achieve desirable drilling decisions, particularly when such drilling decisions are made under time constraints, such as during drilling operations when continuation of drilling is dependent on the drilling decision and, thus, the entire drilling rig waits idly for the next drilling decision. Furthermore, human decision-making for drilling decisions can result in expensive mistakes because drilling errors can add significant cost to drilling operations. In some cases, drilling errors may permanently lower the output of a well, resulting in substantial long term economic losses due to the lost output of the well.

Therefore, the well plan may be updated based on new stratigraphic information from the wellbore, as it is being drilled. This stratigraphic information can be gained on one hand from MWD and LWD sensor data, but could also include other reference well data, such as drilling dynamics data or sensor data giving information, for example, on the hardness of the rock in individual strata layers being drilled through.

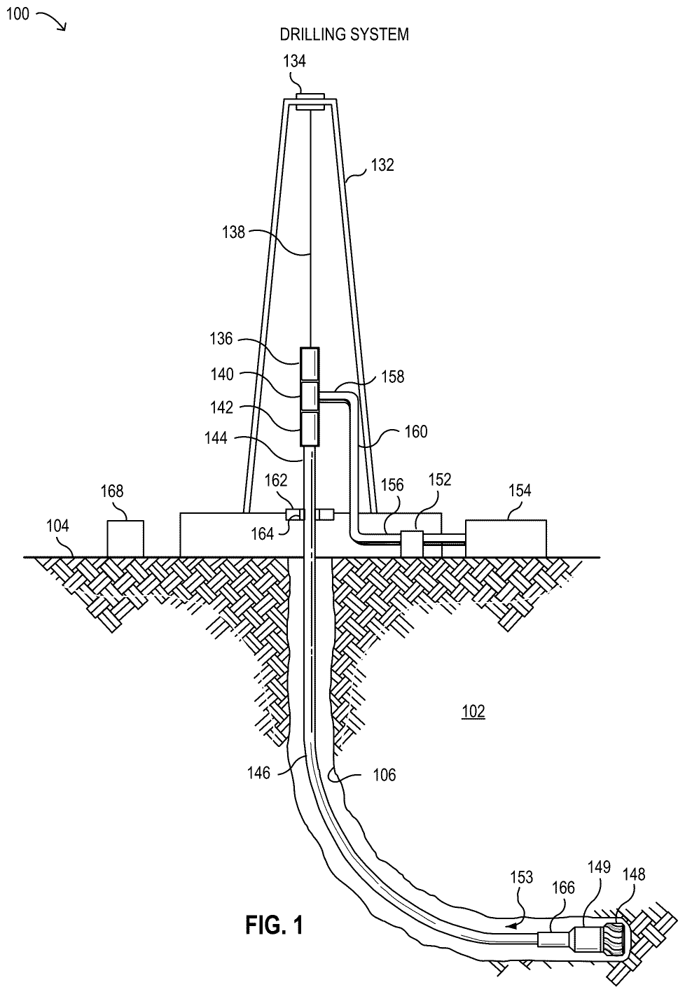

Referring now to the drawings, Referring to FIG. 1, a drilling system 100 is illustrated in one embodiment as a top drive system. As shown, the drilling system 100 includes a derrick 132 on the surface 104 of the earth and is used to drill a borehole 106 into the earth. Typically, drilling system 100 is used at a location corresponding to a geographic formation 102 in the earth that is known.

In FIG. 1, derrick 132 includes a crown block 134 to which a travelling block 136 is coupled via a drilling line 138. In drilling system 100, a top drive 140 is coupled to travelling block 136 and may provide rotational force for drilling. A saver sub 142 may sit between the top drive 140 and a drill pipe 144 that is part of a drill string 146. Top drive 140 may rotate drill string 146 via the saver sub 142, which in turn may rotate a drill bit 148 of a bottom hole assembly (BHA) 149 in borehole 106 passing through formation 102. Also visible in drilling system 100 is a rotary table 162 that may be fitted with a master bushing 164 to hold drill string 146 when not rotating.

A mud pump 152 may direct a fluid mixture 153 (e.g., a mud mixture) from a mud pit 154 into drill string 146. Mud pit 154 is shown schematically as a container, but it is noted that various receptacles, tanks, pits, or other containers may be used. Mud 153 may flow from mud pump 152 into a discharge line 156 that is coupled to a rotary hose 158 by a standpipe 160. Rotary hose 158 may then be coupled to top drive 140, which includes a passage for mud 153 to flow into borehole 106 via drill string 146 from where mud 153 may emerge at drill bit 148. Mud 153 may lubricate drill bit 148 during drilling and, due to the pressure supplied by mud pump 152, mud 153 may return via borehole 106 to surface 104.

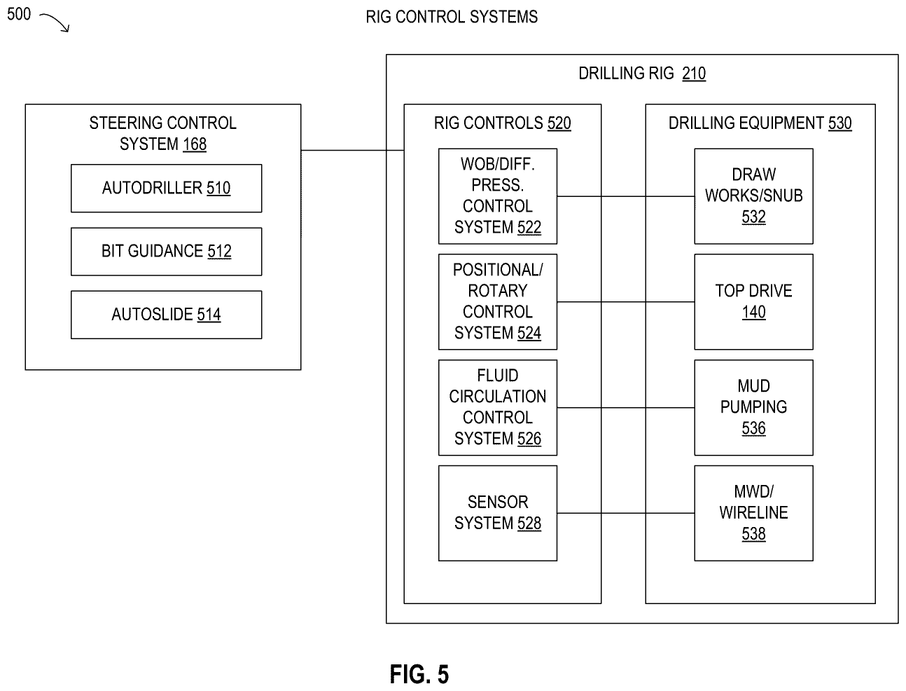

In drilling system 100, drilling equipment (see also FIG. 5) is used to perform the drilling of borehole 106, such as top drive 140 (or rotary drive equipment) that couples to drill string 146 and BHA 149 and is configured to rotate drill string 146 and apply pressure to drill bit 148. Drilling system 100 may include control systems such as a WOB/differential pressure control system 522, a positional/rotary control system 524, a fluid circulation control system 526, and a sensor system 528, as further described below with respect to FIG. 5. The control systems may be used to monitor and change drilling rig settings, such as the WOB or differential pressure to alter the ROP or the radial orientation of the toolface, change the flow rate of drilling mud, and perform other operations. Sensor system 528 may be for obtaining sensor data about the drilling operation and drilling system 100, including the downhole equipment. For example, sensor system 528 may include MWD or logging while drilling (LWD) tools for acquiring information, such as toolface and formation logging information, that may be saved for later retrieval, transmitted with or without a delay using any of various communication means (e.g., wireless, wireline, or mud pulse telemetry), or otherwise transferred to steering control system 168. As used herein, an MWD tool is enabled to communicate downhole measurements without substantial delay to the surface 104, such as using mud pulse telemetry, while a LWD tool is equipped with an internal memory that stores measurements when downhole and can be used to download a stored log of measurements when the LWD tool is at the surface 104. The internal memory in the LWD tool may be a removable memory, such as a universal serial bus (USB) memory device or another removable memory device. It is noted that certain downhole tools may have both MWD and LWD capabilities. Such information acquired by sensor system 528 may include information related to hole depth, bit depth, inclination angle, azimuth angle, true vertical depth, gamma count, standpipe pressure, mud flow rate, rotary rotations per minute (RPM), bit speed, ROP, WOB, among other information. It is noted that all or part of sensor system 528 may be incorporated into a control system, or in another component of the drilling equipment. As drilling system 100 can be configured in many different implementations, it is noted that different control systems and subsystems may be used.

Sensing, detection, measurement, evaluation, storage, alarm, and other functionality may be incorporated into a downhole tool 166 or BHA 149 or elsewhere along drill string 146 to provide downhole surveys of borehole 106. Accordingly, downhole tool 166 may be an MWD tool or a LWD tool or both, and may accordingly utilize connectivity to the surface 104, local storage, or both. In different implementations, gamma ray sensors, magnetometers, accelerometers, and other types of sensors may be used for the downhole surveys. Although downhole tool 166 is shown in singular in drilling system 100, it is noted that multiple instances (not shown) of downhole tool 166 may be located at one or more locations along drill string 146.

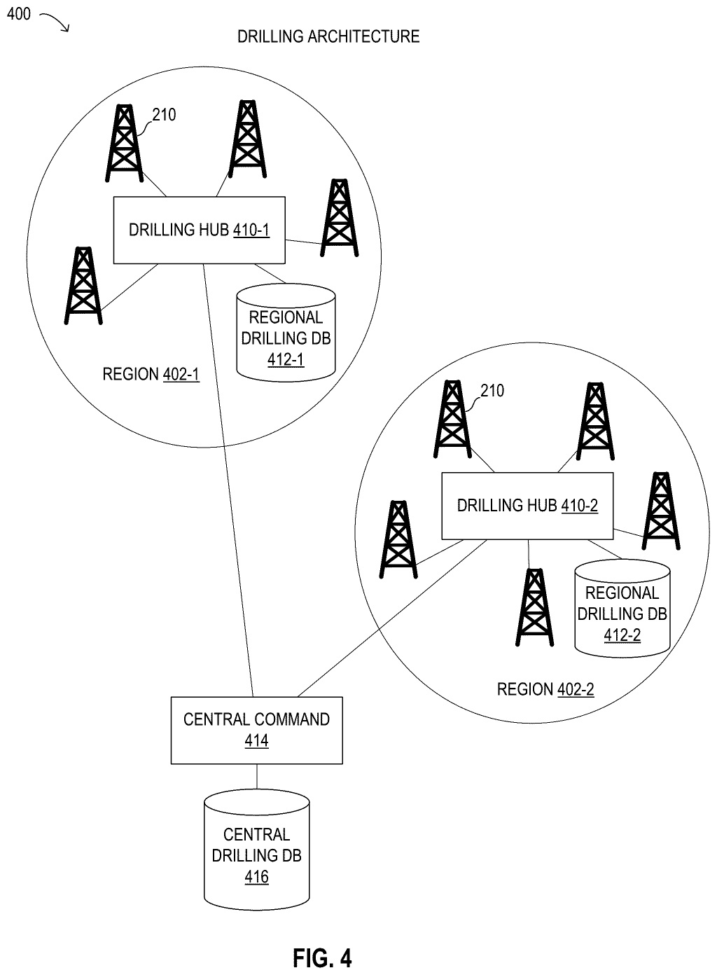

In some embodiments, formation detection and evaluation functionality may be provided via a steering control system 168 on the surface 104. Steering control system 168 may be located in proximity to derrick 132 or may be included with drilling system 100. In other embodiments, steering control system 168 may be remote from the actual location of borehole 106 (see also FIG. 4). For example, steering control system 168 may be a stand-alone system or may be incorporated into other systems included with drilling system 100.

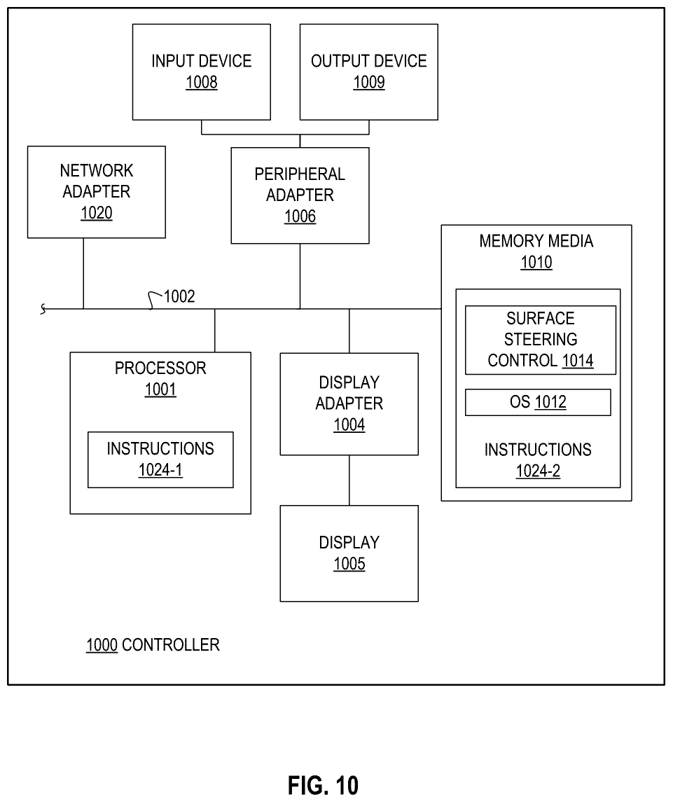

In operation, steering control system 168 may be accessible via a communication network (see also FIG. 10) and may accordingly receive formation information via the communication network. In some embodiments, steering control system 168 may use the evaluation functionality to provide corrective measures, such as a convergence plan to overcome an error in the well trajectory of borehole 106 with respect to a reference, or a planned well trajectory. The convergence plans or other corrective measures may depend on a determination of the well trajectory, and therefore, may be improved in accuracy using surface steering, as disclosed herein.

In particular embodiments, at least a portion of steering control system 168 may be located in downhole tool 166 (not shown). In some embodiments, steering control system 168 may communicate with a separate controller (not shown) located in downhole tool 166. In particular, steering control system 168 may receive and process measurements received from downhole surveys and may perform the calculations described herein for surface steering using the downhole surveys and other information referenced herein.

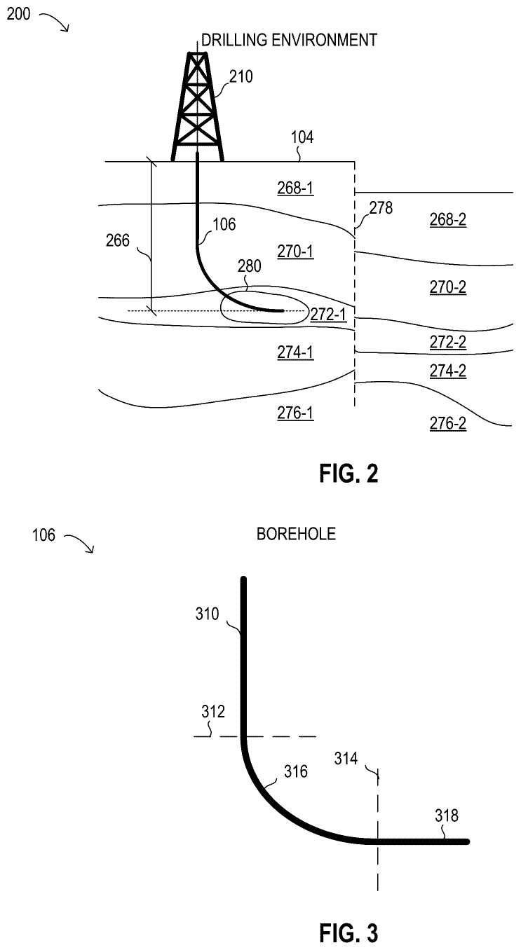

In drilling system 100, to aid in the drilling process, data is collected from borehole 106, such as from sensors in BHA 149, downhole tool 166, or both. The collected data may include the geological characteristics of formation 102 in which borehole 106 was formed, the attributes of drilling system 100, including BHA 149, and drilling information such as weight-on-bit (WOB), drilling speed, and other information pertinent to the formation of borehole 106. The drilling information may be associated with a particular depth or another identifiable marker to index collected data. For example, the collected data for borehole 106 may capture drilling information indicating that drilling of the well from 1,000 feet to 1,200 feet occurred at a first rate of penetration (ROP) through a first rock layer with a first WOB, while drilling from 1,200 feet to 1,500 feet occurred at a second ROP through a second rock layer with a second WOB (see also FIG. 2). In some applications, the collected data may be used to virtually recreate the drilling process that created borehole 106 in formation 102, such as by displaying a computer simulation of the drilling process. The accuracy with which the drilling process can be recreated depends on a level of detail and accuracy of the collected data, including collected data from a downhole survey of the well trajectory.

The collected data may be stored in a database that is accessible via a communication network for example. In some embodiments, the database storing the collected data for borehole 106 may be located locally at drilling system 100, at a drilling hub that supports a plurality of drilling systems 100 in a region, or at a database server accessible over the communication network that provides access to the database (see also FIG. 4). At drilling system 100, the collected data may be stored at the surface 104 or downhole in drill string 146, such as in a memory device included with BHA 149 (see also FIG. 10). Alternatively, at least a portion of the collected data may be stored on a removable storage medium, such as using steering control system 168 or BHA 149 that is later coupled to the database in order to transfer the collected data to the database, which may be manually performed at certain intervals, for example.

In FIG. 1, steering control system 168 is located at or near the surface 104 where borehole 106 is being drilled. Steering control system 168 may be coupled to equipment used in drilling system 100 and may also be coupled to the database, whether the database is physically located locally, regionally, or centrally (see also FIGS. 4 and 5). Accordingly, steering control system 168 may collect and record various inputs, such as measurement data from a magnetometer and an accelerometer that may also be included with BHA 149.

Steering control system 168 may further be used as a surface steerable system, along with the database, as described above. The surface steerable system may enable an operator to plan and control drilling operations while drilling is being performed. The surface steerable system may itself also be used to perform certain drilling operations, such as controlling certain control systems that, in turn, control the actual equipment in drilling system 100 (see also FIG. 5). The control of drilling equipment and drilling operations by steering control system 168 may be manual, manual-assisted, semi-automatic, or automatic, in different embodiments.

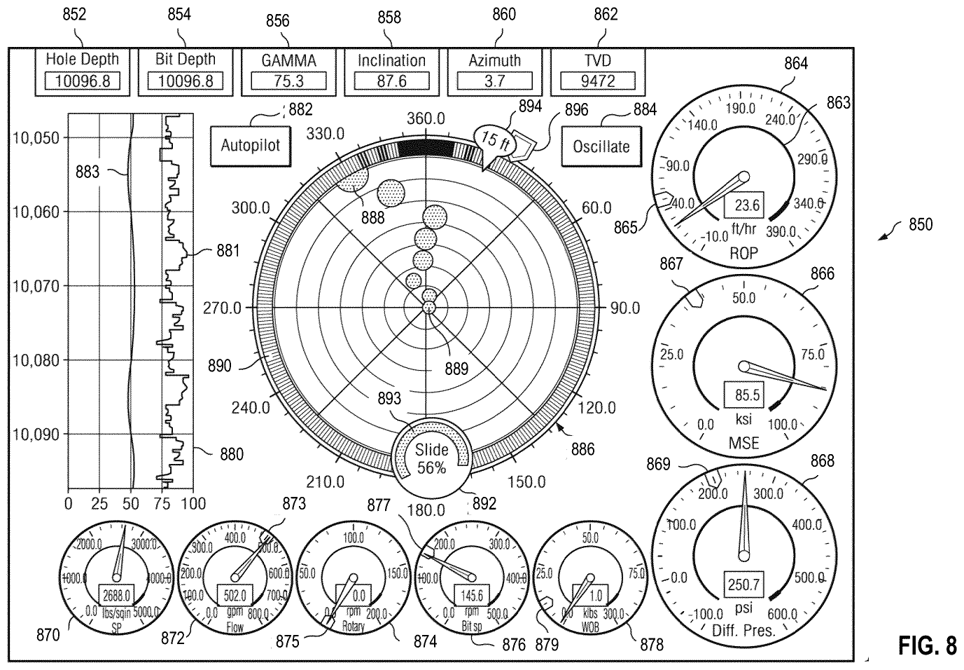

Manual control may involve direct control of the drilling rig equipment, albeit with certain safety limits to prevent unsafe or undesired actions or collisions of different equipment. To enable manual-assisted control, steering control system 168 may present various information, such as using a graphical user interface (GUI) displayed on a display device (see FIG. 8), to a human operator, and may provide controls that enable the human operator to perform a control operation. The information presented to the user may include live measurements and feedback from the drilling rig and steering control system 168, or the drilling rig itself, and may further include limits and safety-related elements to prevent unwanted actions or equipment states, in response to a manual control command entered by the user using the GUI.

To implement semi-automatic control, steering control system 168 may itself propose or indicate to the user, such as via the GUI, that a certain control operation, or a sequence of control operations, should be performed at a given time. Then, steering control system 168 may enable the user to imitate the indicated control operation or sequence of control operations, such that once manually started, the indicated control operation or sequence of control operations is automatically completed. The limits and safety features mentioned above for manual control would still apply for semi-automatic control. It is noted that steering control system 168 may execute semi-automatic control using a secondary processor, such as an embedded controller that executes under a real-time operating system (RTOS), that is under the control and command of steering control system 168. To implement automatic control, the step of manual starting the indicated control operation or sequence of operations is eliminated, and steering control system 168 may proceed with a passive notification to the user of the actions taken.

In order to implement various control operations, steering control system 168 may perform (or may cause to be performed) various input operations, processing operations, and output operations. The input operations performed by steering control system 168 may result in measurements or other input information being made available for use in any subsequent operations, such as processing or output operations. The input operations may accordingly provide the input information, including feedback from the drilling process itself, to steering control system 168. The processing operations performed by steering control system 168 may be any processing operation associated with surface steering, as disclosed herein. The output operations performed by steering control system 168 may involve generating output information for use by external entities, or for output to a user, such as in the form of updated elements in the GUI, for example. The output information may include at least some of the input information, enabling steering control system 168 to distribute information among various entities and processors.

In particular, the operations performed by steering control system 168 may include operations such as receiving drilling data representing a drill path, receiving other drilling parameters, calculating a drilling solution for the drill path based on the received data and other available data (e.g., rig characteristics), implementing the drilling solution at the drilling rig, monitoring the drilling process to gauge whether the drilling process is within a defined margin of error of the drill path, and calculating corrections for the drilling process if the drilling process is outside of the margin of error.

Accordingly, steering control system 168 may receive input information either before drilling, during drilling, or after drilling of borehole 106. The input information may comprise measurements from one or more sensors, as well as survey information collected while drilling borehole 106. The input information may also include a well plan, a regional formation history, drilling engineer parameters, downhole tool face/inclination information, downhole tool gamma/resistivity information, economic parameters, reliability parameters, among various other parameters. Some of the input information, such as the regional formation history, may be available from a drilling hub 410, which may have respective access to a regional drilling database (DB) 412 (see FIG. 4). Other input information may be accessed or uploaded from other sources to steering control system 168. For example, a web interface may be used to interact directly with steering control system 168 to upload the well plan or drilling parameters.

As noted, the input information may be provided to steering control system 168. After processing by steering control system 168, steering control system 168 may generate control information that may be output to drilling rig 210 (e.g., to rig controls 520 that control drilling equipment 530, see also FIGS. 2 and 5). Drilling rig 210 may provide feedback information using rig controls 520 to steering control system 168. The feedback information may then serve as input information to steering control system 168, thereby enabling steering control system 168 to perform feedback loop control and validation. Accordingly, steering control system 168 may be configured to modify its output information to drilling rig 210, in order to achieve the desired results, which are indicated in the feedback information. The output information generated by steering control system 168 may include indications to modify one or more drilling parameters, the direction of drilling, and the drilling mode, among others. In certain operational modes, such as semi-automatic or automatic, steering control system 168 may generate output information indicative of instructions to rig controls 520 to enable automatic drilling using the latest location of BHA 149. Therefore, an improved accuracy in the determination of the location of BHA 149 may be provided using steering control system 168, along with the methods and operations for surface steering disclosed herein.

Referring now to FIG. 2, a drilling environment 200 is depicted schematically and is not drawn to scale or perspective. In particular, drilling environment 200 may illustrate additional details with respect to formation 102 below the surface 104 in drilling system 100 shown in FIG. 1. In FIG. 2, drilling rig 210 may represent various equipment discussed above with respect to drilling system 100 in FIG. 1 that is located at the surface 104.

In drilling environment 200, it may be assumed that a drilling plan (also referred to as a well plan) has been formulated to drill borehole 106 extending into the ground to a true vertical depth (TVD) 266 and penetrating several subterranean strata layers. Borehole 106 is shown in FIG. 2 extending through strata layers 268-1 and 270-1, while terminating in strata layer 272-1. Accordingly, as shown, borehole 106 does not extend or reach underlying strata layers 274-1 and 276-1. A target area 280 specified in the drilling plan may be located in strata layer 272-1 as shown in FIG. 2. Target area 280 may represent a desired endpoint of borehole 106, such as a hydrocarbon producing area indicated by strata layer 272-1. It is noted that target area 280 may be of any shape and size and may be defined using various different methods and information in different embodiments. In some instances, target area 280 may be specified in the drilling plan using subsurface coordinates, or references to certain markers, that indicate where borehole 106 is to be terminated. In other instances, target area may be specified in the drilling plan using a depth range within which borehole 106 is to remain. For example, the depth range may correspond to strata layer 272-1. In other examples, target area 280 may extend as far as can be realistically drilled. For example, when borehole 106 is specified to have a horizontal section with a goal to extend into strata layer 172 as far as possible, target area 280 may be defined as strata layer 272-1 itself and drilling may continue until some other physical limit is reached, such as a property boundary or a physical limitation to the length of drill string 146.

Also visible in FIG. 2 is a fault line 278 that has resulted in a subterranean discontinuity in the fault structure. Specifically, strata layers 268, 270, 272, 274, and 276 have portions on either side of fault line 278. On one side of fault line 278, where borehole 106 is located, strata layers 268-1, 270-1, 272-1, 274-1, and 276-1 are unshifted by fault line 278. On the other side of fault line 278, strata layers 268-2, 270-2, 272-2, 274-2, and 276-2 are shifted downwards by fault line 278.

Current drilling operations frequently include directional drilling to reach a target, such as target area 280. The use of directional drilling has been found to generally increase an overall amount of production volume per well, but also may lead to significantly higher production rates per well, which are both economically desirable. As shown in FIG. 2, directional drilling may be used to drill the horizontal portion of borehole 106, which increases an exposed length of borehole 106 within strata layer 272-1, and which may accordingly be beneficial for hydrocarbon extraction from strata layer 272-1. Directional drilling may also be used to alter an angle of borehole 106 to accommodate subterranean faults, such as indicated by fault line 278 in FIG. 1. Other benefits that may be achieved using directional drilling include sidetracking off of an existing well to reach a different target area or a missed target area, drilling around abandoned drilling equipment, drilling into otherwise inaccessible or difficult to reach locations (e.g., underpopulated areas or bodies of water), providing a relief well for an existing well, and increasing the capacity of a well by branching off and having multiple boreholes extending in different directions or at different vertical positions for the same well. Directional drilling is often not limited to a straight horizontal borehole 106 but may involve staying within a strata layer that varies in depth and thickness as illustrated by strata layer 272. As such, directional drilling may involve multiple vertical adjustments that complicate the trajectory of borehole 106.

Referring now to FIG. 3, one embodiment of a portion of borehole 106 is shown in further detail. Using directional drilling for horizontal drilling may introduce certain challenges or difficulties that may not be observed during vertical drilling of borehole 106. For example, a horizontal portion 318 of borehole 106 may be started from a vertical portion 310. In order to make the transition from vertical to horizontal, a curve may be defined that specifies a so-called “build up” section 316. Build up section 316 may begin at a kickoff point 312 in vertical portion 310 and may end at a begin point 314 of horizontal portion 318. The change in inclination angle in buildup section 316 per measured length drilled is referred to herein as a “build rate” and may be defined in degrees per one hundred feet drilled. For example, the build rate may have a value of 6°/100 ft., indicating that there is a six degree change in inclination angle for every one hundred feet drilled. The build rate for a particular build up section may remain relatively constant or may vary.

The build rate used for any given build up section may depend on various factors, such as properties of the formation (i.e., strata layers) through which borehole 106 is to be drilled, the trajectory of borehole 106, the particular pipe and drill collars/BHA components used (e.g., length, diameter, flexibility, strength, mud motor bend setting, and drill bit), the mud type and flow rate, the specified horizontal displacement, stabilization, and inclination angle, among other factors. An overly aggressive built rate can cause problems such as severe doglegs (e.g., sharp changes in direction in the borehole) that may make it difficult or impossible to run casing or perform other operations in borehole 106. Depending on the severity of any mistakes made during directional drilling, borehole 106 may be enlarged or drill bit 146 may be backed out of a portion of borehole 106 and re-drilled along a different path. Such mistakes may be undesirable due to the additional time and expense involved. However, if the built rate is too cautious, additional overall time may be added to the drilling process because directional drilling generally involves a lower ROP than straight drilling. Furthermore, directional drilling for a curve is more complicated than vertical drilling and the possibility of drilling errors increases with directional drilling (e.g., overshoot and undershoot that may occur while trying to keep drill bit 148 on the planned trajectory).

Two modes of drilling, referred to herein as “rotating” and “sliding,” are commonly used to form borehole 106. Rotating, also called “rotary drilling,” uses top drive 140 or rotary table 162 to rotate drill string 146. Rotating may be used when drilling occurs along a straight trajectory, such as for vertical portion 310 of borehole 106. Sliding, also called “steering” or “directional drilling” as noted above, typically uses a mud motor located downhole at BHA 149. The mud motor may have an adjustable bent housing and is not powered by rotation of drill string 146. Instead, the mud motor uses hydraulic power derived from the pressurized drilling mud that circulates along borehole 106 to and from the surface 104 to directionally drill borehole 106 in buildup section 316.

Thus, sliding is used in order to control the direction of the well trajectory during directional drilling. A method to perform a slide may include the following operations. First, during vertical or straight drilling, the rotation of drill string 146 is stopped. Based on feedback from measuring equipment, such as from downhole tool 166, adjustments may be made to drill string 146, such as using top drive 140 to apply various combinations of torque, WOB, and vibration, among other adjustments. The adjustments may continue until a tool face is confirmed that indicates a direction of the bend of the mud motor is oriented to a direction of a desired deviation (i.e., build rate) of borehole 106. Once the desired orientation of the mud motor is attained, WOB to the drill bit is increased, which causes the drill bit to move in the desired direction of deviation. Once sufficient distance and angle have been built up in the curved trajectory, a transition back to rotating mode can be accomplished by rotating drill string 146 again. The rotation of drill string 146 after sliding may neutralize the directional deviation caused by the bend in the mud motor due to the continuous rotation around a centerline of borehole 106.

Referring now to FIG. 4, a drilling architecture 400 is illustrated in diagram form. As shown, drilling architecture 400 depicts a hierarchical arrangement of drilling hubs 410 and a central command 414, to support the operation of a plurality of drilling rigs 210 in different regions 402. Specifically, as described above with respect to FIGS. 1 and 2, drilling rig 210 includes steering control system 168 that is enabled to perform various drilling control operations locally to drilling rig 210. When steering control system 168 is enabled with network connectivity, certain control operations or processing may be requested or queried by steering control system 168 from a remote processing resource. As shown in FIG. 4, drilling hubs 410 represent a remote processing resource for steering control system 168 located at respective regions 402, while central command 414 may represent a remote processing resource for both drilling hub 410 and steering control system 168.

Specifically, in a region 402-1, a drilling hub 410-1 may serve as a remote processing resource for drilling rigs 210 located in region 402-1, which may vary in number and are not limited to the exemplary schematic illustration of FIG. 4. Additionally, drilling hub 410-1 may have access to a regional drilling DB 412-1, which may be local to drilling hub 410-1. Additionally, in a region 402-2, a drilling hub 410-2 may serve as a remote processing resource for drilling rigs 210 located in region 402-2, which may vary in number and are not limited to the exemplary schematic illustration of FIG. 4. Additionally, drilling hub 410-2 may have access to a regional drilling DB 412-2, which may be local to drilling hub 410-2.

In FIG. 4, respective regions 402 may exhibit the same or similar geological formations. Thus, reference wells, or offset wells, may exist in a vicinity of a given drilling rig 210 in region 402, or where a new well is planned in region 402. Furthermore, multiple drilling rigs 210 may be actively drilling concurrently in region 402 and may be in different stages of drilling through the depths of formation strata layers at region 402. Thus, for any given well being drilled by drilling rig 210 in a region 402, survey data from the reference wells or offset wells may be used to create the well plan, and may be used for surface steering, as disclosed herein. In some implementations, survey data or reference data from a plurality of reference wells may be used to improve drilling performance, such as by reducing an error in estimating TVD or a position of BHA 149 relative to one or more strata layers, as will be described in further detail herein. Additionally, survey data from recently drilled wells, or wells still currently being drilled, including the same well, may be used for reducing an error in estimating TVD or a position of BHA 149 relative to one or more strata layers.

Also shown in FIG. 4 is central command 414, which has access to central drilling DB 416, and may be located at a centralized command center that is in communication with drilling hubs 410 and drilling rigs 210 in various regions 402. The centralized command center may have the ability to monitor drilling and equipment activity at any one or more drilling rigs 210. In some embodiments, central command 414 and drilling hubs 412 may be operated by a commercial operator of drilling rigs 210 as a service to customers who have hired the commercial operator to drill wells and provide other drilling-related services.

In FIG. 4, it is particularly noted that central drilling DB 416 may be a central repository that is accessible to drilling hubs 410 and drilling rigs 210. Accordingly, central drilling DB 416 may store information for various drilling rigs 210 in different regions 402. In some embodiments, central drilling DB 416 may serve as a backup for at least one regional drilling DB 412 or may otherwise redundantly store information that is also stored on at least one regional drilling DB 412. In turn, regional drilling DB 412 may serve as a backup or redundant storage for at least one drilling rig 210 in region 402. For example, regional drilling DB 412 may store information collected by steering control system 168 from drilling rig 210.

In some embodiments, the formulation of a drilling plan for drilling rig 210 may include processing and analyzing the collected data in regional drilling DB 412 to create a more effective drilling plan. Furthermore, once the drilling has begun, the collected data may be used in conjunction with current data from drilling rig 210 to improve drilling decisions. As noted, the functionality of steering control system 168 may be provided at drilling rig 210, or may be provided, at least in part, at a remote processing resource, such as drilling hub 410 or central command 414.

As noted, steering control system 168 may provide functionality as a surface steerable system for controlling drilling rig 210. Steering control system 168 may have access to regional drilling DB 412 and central drilling DB 416 to provide the surface steerable system functionality. As will be described in greater detail below, steering control system 168 may be used to plan and control drilling operations based on input information, including feedback from the drilling process itself. Steering control system 168 may be used to perform operations such as receiving drilling data representing a drill trajectory and other drilling parameters, calculating a drilling solution for the drill trajectory based on the received data and other available data (e.g., rig characteristics), implementing the drilling solution at drilling rig 210, monitoring the drilling process to gauge whether the drilling process is within a margin of error that is defined for the drill trajectory, or calculating corrections for the drilling process if the drilling process is outside of the margin of error.

Referring now to FIG. 5, an example of rig control systems 500 is illustrated in schematic form. It is noted that rig control systems 500 may include fewer or more elements than shown in FIG. 5 in different embodiments. As shown, rig control systems 500 includes steering control system 168 and drilling rig 210. Specifically, steering control system 168 is shown with logical functionality including an autodriller 510, a bit guidance 512, and an autoslide 514. Drilling rig 210 is hierarchically shown including rig controls 520, which provide secure control logic and processing capability, along with drilling equipment 530, which represents the physical equipment used for drilling at drilling rig 210. As shown, rig controls 520 include WOB/differential pressure control system 522, positional/rotary control system 524, fluid circulation control system 526, and sensor system 528, while drilling equipment 530 includes a draw works/snub 532, top drive 140, a mud pumping 536, and an MWD/wireline 538.

Steering control system 168 represent an instance of a processor having an accessible memory storing instructions executable by the processor, such as an instance of controller 1000 shown in FIG. 10. Also, WOB/differential pressure control system 522, positional/rotary control system 524, and fluid circulation control system 526 may each represent an instance of a processor having an accessible memory storing instructions executable by the processor, such as an instance of controller 1000 shown in FIG. 10, but for example, in a configuration as a programmable logic controller (PLC) that may not include a user interface but may be used as an embedded controller. Accordingly, it is noted that each of the systems included in rig controls 520 may be a separate controller, such as a PLC, and may autonomously operate, at least to a degree. Steering control system 168 may represent hardware that executes instructions to implement a surface steerable system that provides feedback and automation capability to an operator, such as a driller. For example, steering control system 168 may cause autodriller 510, bit guidance 512 (also referred to as a bit guidance system (BGS)), and autoslide 514 (among others, not shown) to be activated and executed at an appropriate time during drilling. In particular implementations, steering control system 168 may be enabled to provide a user interface during drilling, such as the user interface 850 depicted and described below with respect to FIG. 8. Accordingly, steering control system 168 may interface with rig controls 520 to facilitate manual, assisted manual, semi-automatic, and automatic operation of drilling equipment 530 included in drilling rig 210. It is noted that rig controls 520 may also accordingly be enabled for manual or user-controlled operation of drilling and may include certain levels of automation with respect to drilling equipment 530.

In rig control systems 500 of FIG. 5, WOB/differential pressure control system 522 may be interfaced with draw works/snubbing unit 532 to control WOB of drill string 146. Positional/rotary control system 524 may be interfaced with top drive 140 to control rotation of drill string 146. Fluid circulation control system 526 may be interfaced with mud pumping 536 to control mud flow and may also receive and decode mud telemetry signals. Sensor system 528 may be interfaced with MWD/wireline 538, which may represent various BHA sensors and instrumentation equipment, among other sensors that may be downhole or at the surface.

In rig control systems 500, autodriller 510 may represent an automated rotary drilling system and may be used for controlling rotary drilling. Accordingly, autodriller 510 may enable automate operation of rig controls 520 during rotary drilling, as indicated in the well plan. Bit guidance 512 may represent an automated control system to monitor and control performance and operation drilling bit 148.

In rig control systems 500, autoslide 514 may represent an automated slide drilling system and may be used for controlling slide drilling. Accordingly, autoslide 514 may enable automate operation of rig controls 520 during a slide and may return control to steering control system 168 for rotary drilling at an appropriate time, as indicated in the well plan. In particular implementations, autoslide 514 may be enabled to provide a user interface during slide drilling to specifically monitor and control the slide. For example, autoslide 514 may rely on bit guidance 512 for orienting a tool face and on autodriller 510 to set WOB or control rotation or vibration of drill string 146.

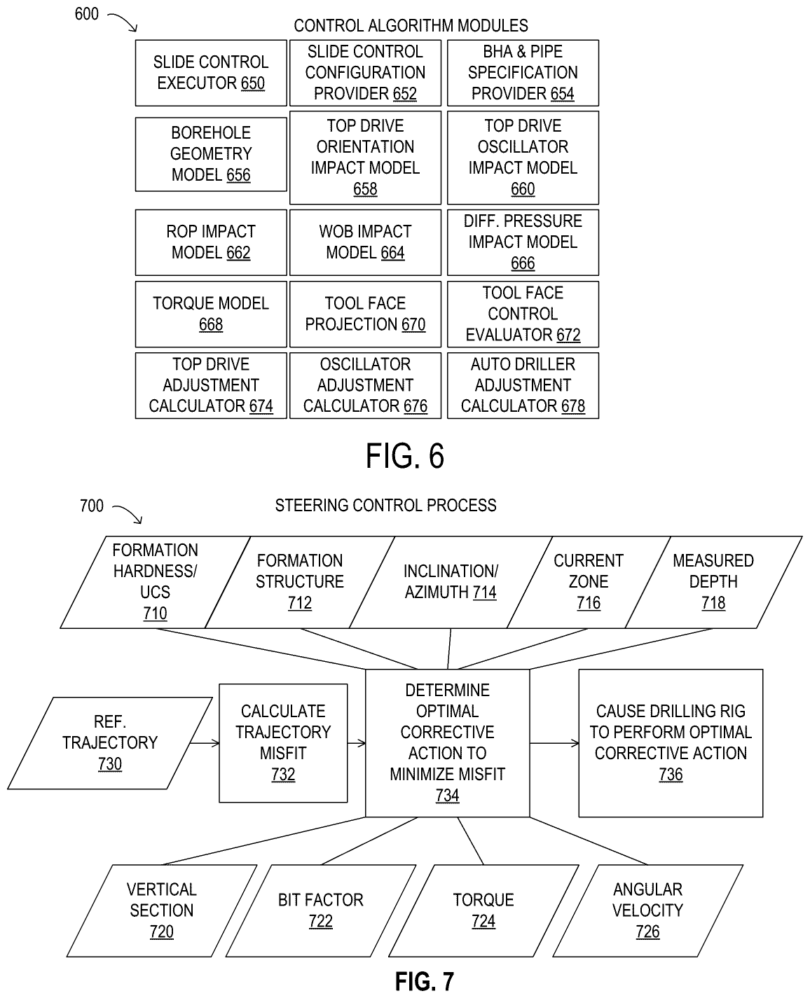

FIG. 6 illustrates one embodiment of control algorithm modules 600 used with steering control system 168. The control algorithm modules 600 of FIG. 6 include: a slide control executor 650 that is responsible for managing the execution of the slide control algorithms; a slide control configuration provider 652 that is responsible for validating, maintaining, and providing configuration parameters for the other software modules; a BHA & pipe specification provider 654 that is responsible for managing and providing details of BHA 149 and drill string 146 characteristics; a borehole geometry model 656 that is responsible for keeping track of the borehole geometry and providing a representation to other software modules; a top drive orientation impact model 658 that is responsible for modeling the impact that changes to the angular orientation of top drive 140 have had on the tool face control; a top drive oscillator impact model 660 that is responsible for modeling the impact that oscillations of top drive 140 has had on the tool face control; an ROP impact model 662 that is responsible for modeling the effect on the tool face control of a change in ROP or a corresponding ROP set point; a WOB impact model 664 that is responsible for modeling the effect on the tool face control of a change in WOB or a corresponding WOB set point; a differential pressure impact model 666 that is responsible for modeling the effect on the tool face control of a change in differential pressure (DP) or a corresponding DP set point; a torque model 668 that is responsible for modeling the comprehensive representation of torque for surface, downhole, break over, and reactive torque, modeling impact of those torque values on tool face control, and determining torque operational thresholds; a tool face control evaluator 672 that is responsible for evaluating factors impacting tool face control and whether adjustments may to be projected, determining whether re-alignment off-bottom is indicated, and determining off-bottom tool face operational threshold windows; a tool face projection 670 that is responsible for projecting tool face behavior for top drive 140, the top drive oscillator, and auto driller adjustments; a top drive adjustment calculator 674 that is responsible for calculating top drive adjustments resultant to tool face projections; an oscillator adjustment calculator 676 that is responsible for calculating oscillator adjustments resultant to tool face projections; and an autodriller adjustment calculator 678 that is responsible for calculating adjustments to autodriller 510 resultant to tool face projections.

FIG. 7 illustrates one embodiment of a steering control process 700 for determining a corrective action for drilling. Steering control process 700 may be used for rotary drilling or slide drilling in different embodiments.

Steering control process 700 in FIG. 7 illustrates a variety of inputs that can be used to determine an optimum corrective action. As shown in FIG. 7, the inputs include formation hardness/unconfined compressive strength (UCS) 710, formation structure 712, inclination/azimuth 714, current zone 716, measured depth 718, desired tool face 730, vertical section 720, bit factor 722, mud motor torque 724, reference trajectory 730, vertical section 720, bit factor 722, torque 724 and angular velocity 726. In FIG. 7, reference trajectory 730 of borehole 106 is determined to calculate a trajectory misfit in a step 732. Step 732 may output the trajectory misfit to determine a corrective action to minimize the misfit at step 734, which may be performed using the other inputs described above. Then, at step 736, the drilling rig is caused to perform the corrective action.

It is noted that in some implementations, at least certain portions of steering control process 700 may be automated or performed without user intervention, such as using rig control systems 700 (see FIG. 7). In other implementations, the corrective action in step 736 may be provided or communicated (by display, SMS message, email, or otherwise) to one or more human operators, who may then take appropriate action. The human operators may be members of a rig crew, which may be located at or near drilling rig 210 or may be located remotely from drilling rig 210.

Referring to FIG. 8, one embodiment of a user interface 850 that may be generated by steering control system 168 for monitoring and operation by a human operator is illustrated. User interface 850 may provide many different types of information in an easily accessible format. For example, user interface 850 may be shown on a computer monitor, a television, a viewing screen (e.g., a display device) associated with steering control system 168.

As shown in FIG. 8, user interface 850 provides visual indicators such as a hole depth indicator 852, a bit depth indicator 854, a GAMMA indicator 856, an inclination indicator 858, an azimuth indicator 860, and a TVD indicator 862. Other indicators may also be provided, including a ROP indicator 864, a mechanical specific energy (MSE) indicator 866, a differential pressure indicator 868, a standpipe pressure indicator 870, a flow rate indicator 872, a rotary RPM (angular velocity) indicator 874, a bit speed indicator 876, and a WOB indicator 878.

In FIG. 8, at least some of indicators 864, 866, 868, 870, 872, 874, 876, and 878 may include a marker representing a target value. For example, markers may be set as certain given values, but it is noted that any desired target value may be used. Although not shown, in some embodiments, multiple markers may be present on a single indicator. The markers may vary in color or size. For example, ROP indicator 864 may include a marker 865 indicating that the target value is 50 feet/hour (or 15 m/h). MSE indicator 866 may include a marker 867 indicating that the target value is 37 kilo-pounds per square inch (kpsi) (or 255 MegaPascals (MPa)). Differential pressure indicator 868 may include a marker 869 indicating that the target value is 200 psi (or 1.38 kPa). ROP indicator 864 may include a marker 865 indicating that the target value is 50 feet/hour (or 15 m/h). Standpipe pressure indicator 870 may have no marker in the present example. Flow rate indicator 872 may include a marker 873 indicating that the target value is 500 gallons per minute (gpm) (or 31.5 Liters per second (L/s)). Rotary RPM indicator 874 may include a marker 875 indicating that the target value is 0 RPM (e.g., due to sliding). Bit speed indicator 876 may include a marker 877 indicating that the target value is 150 RPM. WOB indicator 878 may include a marker 879 indicating that the target value is 10 kilo-pounds (klbs) (or 4,500 kilograms (kg)). Each indicator may also include a colored band, or another marking, to indicate, for example, whether the respective gauge value is within a safe range (e.g., indicated by a green color), within a caution range (e.g., indicated by a yellow color), or within a danger range (e.g., indicated by a red color).

In FIG. 8, a log chart 880 may visually indicate depth versus one or more measurements (e.g., may represent log inputs relative to a progressing depth chart). For example, log chart 880 may have a Y-axis representing depth and an X-axis representing a measurement such as GAMMA count 881 (as shown), ROP 883 (e.g., empirical ROP and normalized ROP), or resistivity. An autopilot button 882 and an oscillate button 884 may be used to control activity. For example, autopilot button 882 may be used to engage or disengage autodriller 510, while oscillate button 884 may be used to directly control oscillation of drill string 146 or to engage/disengage an external hardware device or controller.

In FIG. 8, a circular chart 886 may provide current and historical tool face orientation information (e.g., which way the bend is pointed). For purposes of illustration, circular chart 886 represents three hundred and sixty degrees. A series of circles within circular chart 886 may represent a timeline of tool face orientations, with the sizes of the circles indicating the temporal position of each circle. For example, larger circles may be more recent than smaller circles, so a largest circle 888 may be the newest reading and a smallest circle 889 may be the oldest reading. In other embodiments, circles 889, 888 may represent the energy or progress made via size, color, shape, a number within a circle, etc. For example, a size of a particular circle may represent an accumulation of orientation and progress for the period of time represented by the circle. In other embodiments, concentric circles representing time (e.g., with the outside of circular chart 886 being the most recent time and the center point being the oldest time) may be used to indicate the energy or progress (e.g., via color or patterning such as dashes or dots rather than a solid line).

In user interface 850, circular chart 886 may also be color coded, with the color coding existing in a band 890 around circular chart 886 or positioned or represented in other ways. The color coding may use colors to indicate activity in a certain direction. For example, the color red may indicate the highest level of activity, while the color blue may indicate the lowest level of activity. Furthermore, the arc range in degrees of a color may indicate the amount of deviation. Accordingly, a relatively narrow (e.g., thirty degrees) arc of red with a relatively broad (e.g., three hundred degrees) arc of blue may indicate that most activity is occurring in a particular tool face orientation with little deviation. As a non-limiting example, in user interface 850, the color blue may extend from approximately 22-337 degrees, the color green may extend from approximately 15-22 degrees and 337-345 degrees, the color yellow may extend a few degrees around the 13 and 345 degree marks, while the color red may extend from approximately 347-10 degrees. Transition colors or shades may be used with, for example, the color orange marking the transition between red and yellow or a light blue marking the transition between blue and green. This color coding may enable user interface 850 to provide an intuitive summary of how narrow the standard deviation is and how much of the energy intensity is being expended in the proper direction. Furthermore, the center of energy may be viewed relative to the target. For example, user interface 850 may clearly show that the target is at 90 degrees, but the center of energy is at 45 degrees.

In user interface 850, other indicators, such as a slide indicator 892, may indicate how much time remains until a slide occurs or how much time remains for a current slide. For example, slide indicator 892 may represent a time, a percentage (e.g., as shown, a current slide may be 56% complete), a distance completed, or a distance remaining. Slide indicator 892 may graphically display information using, for example, a colored bar 893 that increases or decreases with slide progress. In some embodiments, slide indicator 892 may be built into circular chart 886 (e.g., around the outer edge with an increasing/decreasing band), while in other embodiments slide indicator 892 may be a separate indicator such as a meter, a bar, a gauge, or another indicator type. In various implementations, slide indicator 892 may be refreshed by autoslide 514.

In user interface 850, an error indicator 894 may indicate a magnitude and a direction of error. For example, error indicator 894 may indicate that an estimated drill bit position is a certain distance from the planned trajectory, with a location of error indicator 894 around the circular chart 886 representing the heading. For example, FIG. 8 illustrates an error magnitude of 15 feet and an error direction of 15 degrees. Error indicator 894 may be any color but may be red for purposes of example. It is noted that error indicator 894 may present a zero if there is no error. Error indicator may represent that drill bit 148 is on the planned trajectory using other means, such as being a green color. Transition colors, such as yellow, may be used to indicate varying amounts of error. In some embodiments, error indicator 894 may not appear unless there is an error in magnitude or direction. A marker 896 may indicate an ideal slide direction. Although not shown, other indicators may be present, such as a bit life indicator to indicate an estimated lifetime for the current bit based on a value such as time or distance.

It is noted that user interface 850 may be arranged in many different ways. For example, colors may be used to indicate normal operation, warnings, and problems. In such cases, the numerical indicators may display numbers in one color (e.g., green) for normal operation, may use another color (e.g., yellow) for warnings, and may use yet another color (e.g., red) when a serious problem occurs. The indicators may also flash or otherwise indicate an alert. The gauge indicators may include colors (e.g., green, yellow, and red) to indicate operational conditions and may also indicate the target value (e.g., an ROP of 100 feet/hour). For example, ROP indicator 868 may have a green bar to indicate a normal level of operation (e.g., from 10-300 feet/hour), a yellow bar to indicate a warning level of operation (e.g., from 300-360 feet/hour), and a red bar to indicate a dangerous or otherwise out of parameter level of operation (e.g., from 360-390 feet/hour). ROP indicator 868 may also display a marker at 100 feet/hour to indicate the desired target ROP.

Furthermore, the use of numeric indicators, gauges, and similar visual display indicators may be varied based on factors such as the information to be conveyed and the personal preference of the viewer. Accordingly, user interface 850 may provide a customizable view of various drilling processes and information for a particular individual involved in the drilling process. For example, steering control system 168 may enable a user to customize the user interface 850 as desired, although certain features (e.g., standpipe pressure) may be locked to prevent a user from intentionally or accidentally removing important drilling information from user interface 850. Other features and attributes of user interface 850 may be set by user preference. Accordingly, the level of customization and the information shown by the user interface 850 may be controlled based on who is viewing user interface 850 and their role in the drilling process.

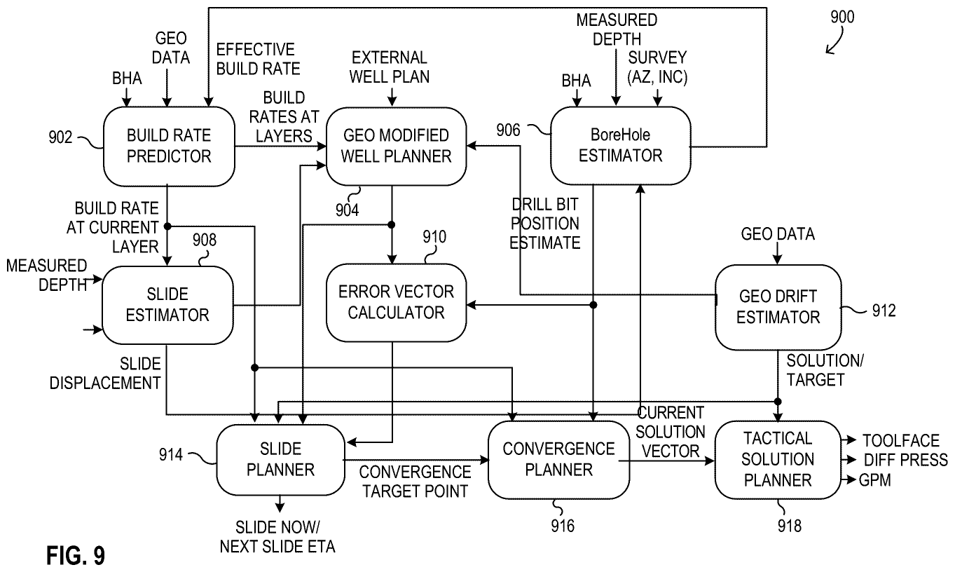

Referring to FIG. 9, one embodiment of a guidance control loop (GCL) 900 is shown in further detail GCL 900 may represent one example of a control loop or control algorithm executed under the control of steering control system 168. GCL 900 may include various functional modules, including a build rate predictor 902, a geological modified well planner 904, a borehole estimator 906, a slide estimator 908, an error vector calculator 910, a geological drift estimator 912, a slide planner 914, a convergence planner 916, and a tactical solution planner 918. In the following description of GCL 900, the term “external input” refers to input received from outside GCL 900, while “internal input” refers to input exchanged between functional modules of GCL 900.

In FIG. 9, build rate predictor 902 receives external input representing BHA information and geological information, receives internal input from the borehole estimator 906, and provides output to geological modified well planner 904, slide estimator 908, slide planner 914, and convergence planner 916. Build rate predictor 902 is configured to use the BHA information and geological information to predict drilling build rates of current and future sections of borehole 106. For example, build rate predictor 902 may determine how aggressively a curve will be built for a given formation with BHA 149 and other equipment parameters.

In FIG. 9, build rate predictor 902 may use the orientation of BHA 149 to the formation to determine an angle of attack for formation transitions and build rates within a single layer of a formation. For example, if a strata layer of rock is below a strata layer of sand, a formation transition exists between the strata layer of sand and the strata layer of rock. Approaching the strata layer of rock at a 90 degree angle may provide a good tool face and a clean drill entry, while approaching the rock layer at a 45 degree angle may build a curve relatively quickly. An angle of approach that is near parallel may cause drill bit 148 to skip off the upper surface of the strata layer of rock. Accordingly, build rate predictor 902 may calculate BHA orientation to account for formation transitions. Within a single strata layer, build rate predictor 902 may use the BHA orientation to account for internal layer characteristics (e.g., grain) to determine build rates for different parts of a strata layer. The BHA information may include bit characteristics, mud motor bend setting, stabilization, and mud motor bit to bend distance. The geological information may include formation data such as compressive strength, thicknesses, and depths for formations encountered in the specific drilling location. Such information may enable a calculation-based prediction of the build rates and ROP that may be compared to both results obtained while drilling borehole 106 and regional historical results (e.g., from the regional drilling DB 412) to improve the accuracy of predictions as drilling progresses. Build rate predictor 902 may also be used to plan convergence adjustments and confirm in advance of drilling that targets can be achieved with current parameters.

In FIG. 9, geological modified well planner 904 receives external input representing a well plan, internal input from build rate predictor 902 and geological drift estimator 912 and provides output to slide planner 914 and error vector calculator 910. Geological modified well planner 904 uses the input to determine whether there is a more desirable trajectory than that provided by the well plan, while staying within specified error limits. More specifically, geological modified well planner 904 takes geological information (e.g., drift) and calculates whether another trajectory solution to the target may be more efficient in terms of cost or reliability. The outputs of geological modified well planner 904 to slide planner 914 and error vector calculator 910 may be used to calculate an error vector based on the current vector to the newly calculated trajectory and to modify slide predictions. In some embodiments, geological modified well planner 904 (or another module) may provide functionality to track a formation trend. For example, in horizontal wells, a geologist may provide steering control system 168 with a target inclination angle as a set point for steering control system 168 to control. For example, the geologist may enter a target to steering control system 168 of 90.5-91.0 degrees of inclination angle for a section of borehole 106. Geological modified well planner 904 may then treat the target as a vector target, while remaining within the error limits of the original well plan. In some embodiments, geological modified well planner 904 may be an optional module that is not used unless the well plan is to be modified. For example, if the well plan is marked in steering control system 168 as non-modifiable, geological modified well planner 904 may be bypassed altogether or geological modified well planner 904 may be configured to pass the well plan through without any changes.

In FIG. 9, borehole estimator 906 may receive external inputs representing BHA information, measured depth information, survey information (e.g., azimuth angle and inclination angle), and may provide outputs to build rate predictor 902, error vector calculator 910, and convergence planner 916. Borehole estimator 906 may be configured to provide an estimate of the actual borehole and drill bit position and trajectory angle without delay, based on either straight line projections or projections that incorporate sliding. Borehole estimator 906 may be used to compensate for a sensor being physically located some distance behind drill bit 148 (e.g., 50 feet) in drill string 146, which makes sensor readings lag the actual bit location by 50 feet. Borehole estimator 906 may also be used to compensate for sensor measurements that may not be continuous (e.g., a sensor measurement may occur every 100 feet). Borehole estimator 906 may provide the most accurate estimate from the surface to the last survey location based on the collection of survey measurements. Also, borehole estimator 906 may take the slide estimate from slide estimator 908 (described below) and extend the slide estimate from the last survey point to a current location of drill bit 148. Using the combination of these two estimates, borehole estimator 906 may provide steering control system 168 with an estimate of the drill bit's location and trajectory angle from which guidance and steering solutions can be derived. An additional metric that can be derived from the borehole estimate is the effective build rate that is achieved throughout the drilling process.

In FIG. 9, slide estimator 908 receives external inputs representing measured depth and differential pressure information, receives internal input from build rate predictor 902, and provides output to borehole estimator 906 and geological modified well planner 904. Slide estimator 908 may be configured to sample tool face orientation, differential pressure, measured depth (MD) incremental movement, MSE, and other sensor feedback to quantify/estimate a deviation vector and progress while sliding.

Traditionally, deviation from the slide would be predicted by a human operator based on experience. The operator would, for example, use a long slide cycle to assess what likely was accomplished during the last slide. However, the results are generally not confirmed until the downhole survey sensor point passes the slide portion of the borehole, often resulting in a response lag defined by a distance of the sensor point from the drill bit tip (e.g., approximately 50 feet). Such a response lag may introduce inefficiencies in the slide cycles due to over/under correction of the actual trajectory relative to the planned trajectory.

In GCL 900, using slide estimator 908, each tool face update may be algorithmically merged with the average differential pressure of the period between the previous and current tool face readings, as well as the MD change during this period to predict the direction, angular deviation, and MD progress during the period. As an example, the periodic rate may be between 10 and 60 seconds per cycle depending on the tool face update rate of downhole tool 166. With a more accurate estimation of the slide effectiveness, the sliding efficiency can be improved. The output of slide estimator 908 may accordingly be periodically provided to borehole estimator 906 for accumulation of well deviation information, as well to geological modified well planner 904. Some or all of the output of the slide estimator 908 may be output to an operator, such as shown in the user interface 850 of FIG. 8.

In FIG. 9, error vector calculator 910 may receive internal input from geological modified well planner 904 and borehole estimator 906. Error vector calculator 910 may be configured to compare the planned well trajectory to an actual borehole trajectory and drill bit position estimate. Error vector calculator 910 may provide the metrics used to determine the error (e.g., how far off) the current drill bit position and trajectory are from the well plan. For example, error vector calculator 910 may calculate the error between the current bit position and trajectory to the planned trajectory and the desired bit position. Error vector calculator 910 may also calculate a projected bit position/projected trajectory representing the future result of a current error.

In FIG. 9, geological drift estimator 912 receives external input representing geological information and provides outputs to geological modified well planner 904, slide planner 914, and tactical solution planner 918. During drilling, drift may occur as the particular characteristics of the formation affect the drilling direction. More specifically, there may be a trajectory bias that is contributed by the formation as a function of ROP and BHA 149. Geological drift estimator 912 is configured to provide a drift estimate as a vector that can then be used to calculate drift compensation parameters that can be used to offset the drift in a control solution.

In FIG. 9, slide planner 914 receives internal input from build rate predictor 902, geological modified well planner 904, error vector calculator 910, and geological drift estimator 912, and provides output to convergence planner 916 as well as an estimated time to the next slide. Slide planner 914 may be configured to evaluate a slide/drill ahead cost calculation and plan for sliding activity, which may include factoring in BHA wear, expected build rates of current and expected formations, and the well plan trajectory. During drill ahead, slide planner 914 may attempt to forecast an estimated time of the next slide to aid with planning. For example, if additional lubricants (e.g., fluorinated beads) are indicated for the next slide, and pumping the lubricants into drill string 146 has a lead time of 30 minutes before the slide, the estimated time of the next slide may be calculated and then used to schedule when to start pumping the lubricants. Functionality for a loss circulation material (LCM) planner may be provided as part of slide planner 914 or elsewhere (e.g., as a stand-alone module or as part of another module described herein). The LCM planner functionality may be configured to determine whether additives should be pumped into the borehole based on indications such as flow-in versus flow-back measurements. For example, if drilling through a porous rock formation, fluid being pumped into the borehole may get lost in the rock formation. To address this issue, the LCM planner may control pumping LCM into the borehole to clog up the holes in the porous rock surrounding the borehole to establish a more closed-loop control system for the fluid.

In FIG. 9, slide planner 914 may also look at the current position relative to the next connection. A connection may happen every 90 to 100 feet (or some other distance or distance range based on the particulars of the drilling operation) and slide planner 914 may avoid planning a slide when close to a connection or when the slide would carry through the connection. For example, if the slide planner 914 is planning a 50 foot slide but only 20 feet remain until the next connection, slide planner 914 may calculate the slide starting after the next connection and make any changes to the slide parameters to accommodate waiting to slide until after the next connection. Such flexible implementation avoids inefficiencies that may be caused by starting the slide, stopping for the connection, and then having to reorient the tool face before finishing the slide. During slides, slide planner 914 may provide some feedback as to the progress of achieving the desired goal of the current slide. In some embodiments, slide planner 914 may account for reactive torque in drill string 146. More specifically, when rotating is occurring, there is a reactional torque wind up in drill string 146. When the rotating is stopped, drill string 146 unwinds, which changes tool face orientation and other parameters. When rotating is started again, drill string 146 starts to wind back up. Slide planner 914 may account for the reactional torque so that tool face references are maintained, rather than stopping rotation and then trying to adjust to a desired tool face orientation. While not all downhole tools may provide tool face orientation when rotating, using one that does supply such information for GCL 900 may significantly reduce the transition time from rotating to sliding.

In FIG. 9, convergence planner 916 receives internal inputs from build rate predictor 902, borehole estimator 906, and slide planner 914, and provides output to tactical solution planner 918. Convergence planner 916 is configured to provide a convergence plan when the current drill bit position is not within a defined margin of error of the planned well trajectory. The convergence plan represents a path from the current drill bit position to an achievable and desired convergence target point along the planned trajectory. The convergence plan may take account the amount of sliding/drilling ahead that has been planned to take place by slide planner 914. Convergence planner 916 may also use BHA orientation information for angle of attack calculations when determining convergence plans as described above with respect to build rate predictor 902. The solution provided by convergence planner 916 defines a new trajectory solution for the current position of drill bit 148. The solution may be immediate without delay, or planned for implementation at a future time that is specified in advance.

In FIG. 9, tactical solution planner 918 receives internal inputs from geological drift estimator 912 and convergence planner 916 and provides external outputs representing information such as tool face orientation, differential pressure, and mud flow rate. Tactical solution planner 918 is configured to take the trajectory solution provided by convergence planner 916 and translate the solution into control parameters that can be used to control drilling rig 210. For example, tactical solution planner 918 may convert the solution into settings for control systems 522, 524, and 526 to accomplish the actual drilling based on the solution. Tactical solution planner 918 may also perform performance optimization to optimizing the overall drilling operation as well as optimizing the drilling itself (e.g., how to drill faster).

Other functionality may be provided by GCL 900 in additional modules or added to an existing module. For example, there is a relationship between the rotational position of the drill pipe on the surface and the orientation of the downhole tool face. Accordingly, GCL 900 may receive information corresponding to the rotational position of the drill pipe on the surface. GCL 900 may use this surface positional information to calculate current and desired tool face orientations. These calculations may then be used to define control parameters for adjusting the top drive 140 to accomplish adjustments to the downhole tool face in order to steer the trajectory of borehole 106.

For purposes of example, an object-oriented software approach may be utilized to provide a class-based structure that may be used with GCL 900, or other functionality provided by steering control system 168. In GCL 900, a drilling model class may be defined to capture and define the drilling state throughout the drilling process. The drilling model class may include information obtained without delay. The drilling model class may be based on the following components and sub-models: a drill bit model, a borehole model, a rig surface gear model, a mud pump model, a WOB/differential pressure model, a positional/rotary model, an MSE model, an active well plan, and control limits. The drilling model class may produce a control output solution and may be executed via a main processing loop that rotates through the various modules of GCL 900. The drill bit model may represent the current position and state of drill bit 148. The drill bit model may include a three dimensional (3D) position, a drill bit trajectory, BHA information, bit speed, and tool face (e.g., orientation information). The 3D position may be specified in north-south (NS), east-west (EW), and true vertical depth (TVD). The drill bit trajectory may be specified as an inclination angle and an azimuth angle. The BHA information may be a set of dimensions defining the active BHA. The borehole model may represent the current path and size of the active borehole. The borehole model may include hole depth information, an array of survey points collected along the borehole path, a gamma log, and borehole diameters. The hole depth information is for current drilling of borehole 106. The borehole diameters may represent the diameters of borehole 106 as drilled over current drilling. The rig surface gear model may represent pipe length, block height, and other models, such as the mud pump model, WOB/differential pressure model, positional/rotary model, and MSE model. The mud pump model represents mud pump equipment and includes flow rate, standpipe pressure, and differential pressure. The WOB/differential pressure model represents draw works or other WOB/differential pressure controls and parameters, including WOB. The positional/rotary model represents top drive or other positional/rotary controls and parameters including rotary RPM and spindle position. The active well plan represents the target borehole path and may include an external well plan and a modified well plan. The control limits represent defined parameters that may be set as maximums and/or minimums. For example, control limits may be set for the rotary RPM in the top drive model to limit the maximum rotations per minute (RPMs) to the defined level. The control output solution may represent the control parameters for drilling rig 210.

Each functional module of GCL 900 may have behavior encapsulated within a respective class definition. During a processing window, the individual functional modules may have an exclusive portion in time to execute and update the drilling model. For purposes of example, the processing order for the functional modules may be in the sequence of geological modified well planner 904, build rate predictor 902, slide estimator 908, borehole estimator 906, error vector calculator 910, slide planner 914, convergence planner 916, geological drift estimator 912, and tactical solution planner 918. It is noted that other sequences may be used in different implementations.

In FIG. 9, GCL 900 may rely on a programmable timer module that provides a timing mechanism to provide timer event signals to drive the main processing loop. While steering control system 168 may rely on timer and date calls driven by the programming environment, timing may be obtained from other sources than system time. In situations where it may be advantageous to manipulate the clock (e.g., for evaluation and testing), a programmable timer module may be used to alter the system time. For example, the programmable timer module may enable a default time set to the system time and a time scale of 1.0 minutes (or any other unit of time as desired), may enable the system time of steering control system 168 to be manually set, may enable the time scale relative to the system time to be modified, or may enable periodic event time requests scaled to a requested time scale.

Referring now to FIG. 10, a block diagram illustrating selected elements of an embodiment of a controller 1000 for performing surface steering according to the present disclosure. In various embodiments, controller 1000 may represent an implementation of steering control system 168. In other embodiments, at least certain portions of controller 1000 may be used for control systems 510, 512, 514, 522, 524, and 526 (see FIG. 5).

In the embodiment depicted in FIG. 10, controller 1000 includes processor 1001 coupled via shared bus 1002 to storage media collectively identified as memory media 1010.

Controller 1000, as depicted in FIG. 10, further includes network adapter 1020 that interfaces controller 1000 to a network (not shown in FIG. 10). In embodiments suitable for use with user interfaces, controller 1000, as depicted in FIG. 10, may include peripheral adapter 1006, which provides connectivity for the use of input device 1008 and output device 1009. Input device 1008 may represent a device for user input, such as a keyboard or a mouse, or even a video camera. Output device 1009 may represent a device for providing signals or indications to a user, such as loudspeakers for generating audio signals.

Controller 1000 is shown in FIG. 10 including display adapter 1004 and further includes a display device 1005. Display adapter 1004 may interface shared bus 1002, or another bus, with an output port for one or more display devices, such as display device 1005. Display device 1005 may be implemented as a liquid crystal display screen, a computer monitor, a television, or the like. Display device 1005 may comply with a display standard for the corresponding type of display. Standards for computer monitors include analog standards such as video graphics array (VGA), extended graphics array (XGA), etc., or digital standards such as digital visual interface (DVI), definition multimedia interface (HDMI), DisplayPort (DP), and USB Type-C, among others. A television display may comply with standards such as NTSC (National Television System Committee), PAL (Phase Alternating Line), or another suitable standard. Display device 1005 may include an output device 1009, such as one or more integrated speakers to play audio content, or may include an input device 1008, such as a microphone or video camera.

In FIG. 10, memory media 1010 encompasses persistent and volatile media, fixed and removable media, and magnetic and semiconductor media. Memory media 1010 is operable to store instructions, data, or both. Memory media 1010 as shown includes sets or sequences of instructions 1024-2, namely, an operating system 1012 and surface steering control 1014. Operating system 1012 may be a UNIX or UNIX-like operating system, a Windows® family operating system, or another suitable operating system. Instructions 1024 may also reside, completely or at least partially, within processor 1001 during execution thereof. It is further noted that processor 1001 may be configured to receive instructions 1024-1 from instructions 1024-2 via shared bus 1002. In some embodiments, memory media 1010 is configured to store and provide executable instructions for executing GCL 900, as mentioned previously, among other methods and operations disclosed herein.

The following disclosure explains additional and improved methods and systems for drilling. In particular, the following systems and methods can be useful to drill deeper wells, especially through harder rock formations, faster and more efficiently than with conventional drilling techniques. It should be noted that the following methods may be implemented by a computer system such as any of those described above. For example, the computer system used to monitor, perform and/or control the methods described below may be a part of the steering control system 168, a part of the rig controls system 500, a part of the drilling system 100, included with the controller 1000, or may be a similar or different computer system and may be coupled to one or more of the foregoing systems. The computer system may be located at or near the rig site or may be located at a remote location from the rig site and may be configured to transmit and receive data to and from a rig site while a well is being drilled.

Moreover, it should be noted that the computer system and/or the control system for controlling the flow of fuel and/or drilling mud may be located downhole in some situations.

### Well Log Predictive Systems

Triple combo logs can provide measurements for estimating geological, petrophysical and geomechanical properties. Traditionally, reservoir properties can be derived from inverting triple combo logs or advanced logs and core data. But many wells, especially unconventional wells do not have wireline and even LWD logs. Unfortunately, wireline and advanced LWD logs are typically dropped from the formation evaluation plan for unconventional wells due to economic constraints or borehole instability risks. Available measurements can typically be MWD natural Gamma Ray (GR) logs along with surface measurements such as WOB, ROP, torque, RPM, and differential pressure. The development of a robust and rapid model for predicting reservoir properties using this limited dataset would be of high value for geological evaluation. Estimating such properties can be a challenging task due to the nonlinear relationship between the available log data and unknown reservoir properties.

A novel workflow can be presented that combines two sequential models. First, a machine learning (ML) algorithm can be used to predict triple combo logs from drilling dynamic measurements and GR logs. To train the ML algorithm, well logs can be obtained from multiple wells located in a geographic area (e.g., the Eagle Ford and Permian basins). The wells in the geographic area can be scrutinized to identify important features and/or features of interest, among other features. This process can include depth shifting, outlier detection, and feature selection, which can allow for strategic hyperparameter tuning. Several regression algorithms can be used, in particular gradient boosting algorithms can yield superior prediction performance. Unlike commonly used regressors such as Random Forest methods, boosting algorithms train predictors sequentially, each trying to correct its predecessor. After triple combo logs are predicted from MWD logs, a physics-based joint inversion model can be applied to estimate reservoir properties such as total porosity, clay types, pore pressure, rock strength, rock facies, clay volume, water saturation, volumetric concentrations of lithology, permeability, rock type, and geomechanical parameters.

The trained model can be deployed on a blind test well and the predicted logs show an excellent agreement when compared to the corresponding triple combo measurements. The multi-mineral inversion using predicted triple combo logs can yield a geologic model that is validated with both mud logs and Elemental Capture Spectroscopy (ECS) measurements. Additionally, reconstructed logs from the geologic model can closely match measured logs by minimizing the cost function. Therefore, real-time estimated geological, petrophysical and geomechanical properties can reveal complex geologic information and can be used to mitigate uncertainty related to drilling optimization, reservoir characterization, development planning, and reserve estimation.

This disclosure describes a hybrid model combining machine learning to predict triple combo logs and physics model to invert them to have real-time formation evaluation while drilling operations. Using the MWD logs to predict triple combo logs followed by a joint inversion can be an innovative approach for a geological evaluation with a limited dataset. The developed workflow can successfully provide (1) geologic lithofacies identification and rock typing, (2) more confidence in real-time drilling operation, (3) reservoir properties prediction, (4) missing log imputations and pseudo-log generation with forward modeling, (5) guidance for future logging and perforation (6) reference for seismic QI and well tic, and (7) potentially massive computation time saving from days to minutes. As previously noted, a multitude of unconventional wells lack extensive logging measurements beyond MWD logs. In such cases, traditional formation evaluation remains unattainable and interpolation from nearby wells may introduce misleading interpretations of petrophysical properties. To tackle this issue, prior endeavors have sought to directly estimate reservoir properties from MWD data through machine learning techniques. However, as discussed previously, these approaches predominantly rely on statistical data analysis and correlations, often disregarding the underlying physics of the measurements. Additionally, the models generated through these methods typically offer only partial insights into geologic and petrophysical properties. The hybrid model disclosed herein incorporates both physics-based principles and data-driven approaches. Additionally, or alternatively, instead of relying solely on well logs obtained from a single nearby well, the approaches described herein may incorporate data from multiple wells within the same region as inputs to calibrate the machine learning model.

Accurately estimating reservoir properties may improve production and profitability in unconventional reservoirs, among other benefits. Triple combo logs from LWD and/or wireline have historically been considered essential measurements for determining geological, petrophysical, and geomechanical properties. Unconventional wells with triple combo logs can be exceedingly rare, however due to rig time, cost constraints, and the technical challenges associated with running logging tools in extended reach lateral wellbores. Consequently, the only downhole measurements available, on most unconventional wells are directional surveys along with natural Gamma Ray (GR) logs. More commonly available are surface measurements of the drilling operation, such as weight on bit (WOB), rate of penetration (ROP), torque, RPM, and differential pressure. Although these measurements are primarily used to characterize the quality of the drilling process, because that process is sensitive to the rock being drilled through it is possible to draw associations with specific formation properties.

Several recent endeavors have been made to apply drilling dynamics for estimating diverse petrophysical properties. A geomechanical facies prediction model, based on surface drilling data, exhibited a 75% classification accuracy on the test dataset (Tran et al., 2020). Real-time drilling parameters were utilized to predict rock porosity in studies by Al-Sabaa et al. (2021) and Gamal et al. (2021). Prasad et al. (2022) introduced the estimation of rock strengths, including Unconfined Compressive Strength (UCS), Confined Compressive Strength (CCS), and mechanical Specific Energy (MSE), using downhole drilling data. Moreover, Bentosa et al. (2022) employed MWD Gamma Ray logs and surface drilling parameters in conjunction with ML algorithms to predict bulk density and sonic logs for geomechanical evaluation. Although these studies developed reasonable ML models with acceptable prediction accuracies, most of them relied purely on data statistics and correlations without consideration of the underlying physics of the measurements. Additionally, these models only provide incomplete information on geologic and petrophysical properties.

Additional ML studies have focused on geomechanical properties. Negara et al. (2017) utilized support vector regression (SVR) to develop a data-driven model for predicting brittleness index from elemental spectroscopy and X-ray fluorescence (XRF). Nacini et al. (2019) introduced a neural network model to forecast petrophysical volume logs, pore pressure, and geomechanical properties from different wireline logs. These models provide reasonably accurate predictions, but they necessitate additional logging tool measurements that are costly and time-consuming to execute. Colombo et al. (2021) presented a novel approach to joint inversion of geophysical electromagnetic data using deep learning techniques to optimize model parameter estimations. However, this approach still requires triple combo logs, including electromagnetic data, to enhance the inversion process.

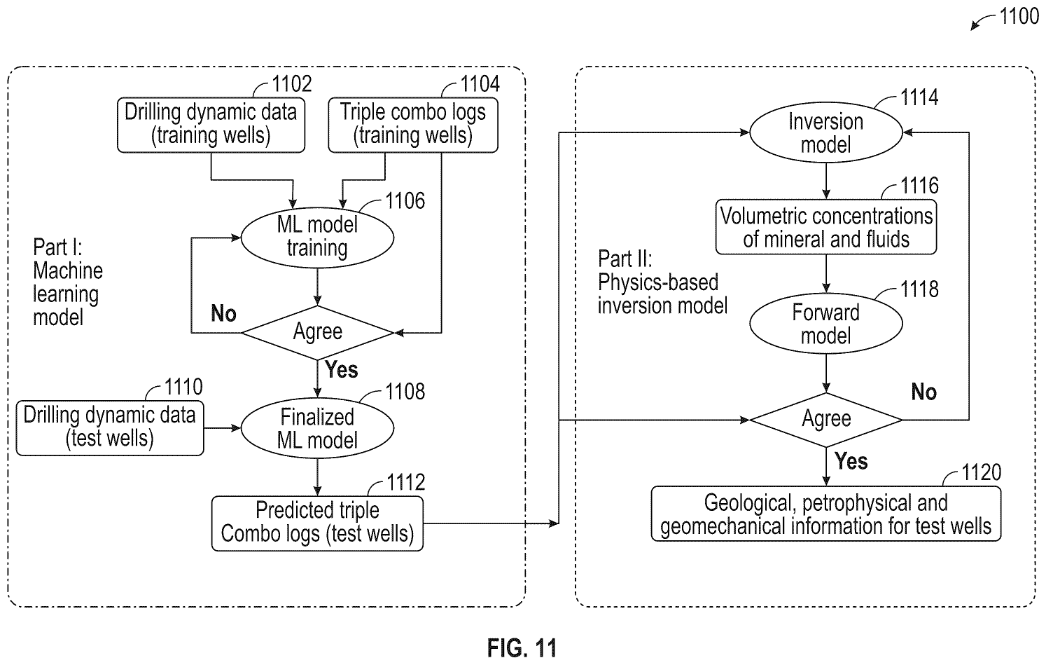

A new approach can be used to address these issues by combining machine learning and physics-based joint inversion to estimate reservoir properties. Given the limited dataset, a two-step workflow has been developed for building a robust and dependable model for predicting reservoir properties in real time. First, a machine learning algorithm can be employed to forecast triple combo logs from drilling dynamic measurements and GR logs. This algorithm can be trained using well logs from multiple wells located in a particular area (e.g., the Eagle Ford and Permian basins), where important features and/or features of interest and/or other features were identified through thorough examination. After the prediction of triple combo logs from MWD logs, a physics-based joint inversion model was utilized to estimate reservoir properties such as total porosity, clay volume, water saturation, volumetric concentrations of lithology, permeability, rock type, and geomechanical parameters. FIG. 11 depicts an overview of the proposed workflow, which includes both machine learning and joint inversion components.

This disclosure describes into the use of drilling dynamic measurements for formation evaluation. It details the processing of MWD and LWD logs, and the selection of the most appropriate logs and offset wells using the Kullback-Leibler divergence matrix. Then, a machine learning approach can be used to predict traditional triple combo logs. Next, the disclosure outlines a physics-based joint inversion technique to estimate various geological, petrophysical, and geomechanical properties from the produced triple combo log to mitigate uncertainty during the drilling process. Finally, the disclosure will examine the applications of using drilling dynamics for formation evaluation in several field examples and discuss the potential advantages of implementing this methodology.

FIG. 11 illustrates a workflow diagram. The first part comprises a machine learning model. Input data for training can include drilling dynamics from MWD and target outputs can include triple combo logs. The machine learning (ML) model can refine the parameters to obtain finalized model. The ML model can use drilling dynamics from a test well, to predict triple combo logs. The predicted triple combo logs can be used as inputs for joint inversion. The inversion can provide volumetric concentrations of minerals and fluids. Next, the system can compare reconstructed triple combo logs to those from actual measurements to verify they agreed each other. At the end of the inversion, the system can obtain real-time geological, petrophysical and geomechanical properties from the test well.

FIG. 11 illustrates a process for the utilization of drilling dynamic measurements for formation evaluation. This process can commence with processing both MWD drilling dynamic data 1102 and LWD/wireline logs 1104, and the selection of the most appropriate wells using the Kullback-Leibler divergence matrix. The machine learning model 1106 can receive the drilling dynamic data 1102 and values from the triple combo logs 1104 from a plurality of training wells. The coefficients for the machine learning model 1106 can be adjusted until the machine learning model 1106 can accurately predict the triple combo logs 1103 from the drilling dynamic data 1102 and the triple combo logs 1104. If the machine learning model 1106 cannot predict the values for the triple combo logs 1104 withing predetermined thresholds, the training process can continue until the machine learning model 1106 is within the predetermined threshold.

If the machine learning model 1106 can predict the training triple combo logs 1104 from the drilling dynamic data 1102 within a predetermined threshold, a finalized machine learning model 1108 has been attained. Dynamic drilling data 1110 from test wells can be used as an input to the finalized machine learning model 1108 to determine predicted triple combo logs (test wells) 1112.

The predicted triple combo logs (test wells) 1112 can be input into an inversion model 1114. The inversion model 1114 can be used to determine volumetric concentration values 1116 of minerals and fluids. The determined volumetric concentrations values 1116 can be used to determine a forward model 1118. The forward model 1118 can be compared with known geological properties to validate the model. If the model is not validated, the inversion model 1114 can continue to be adjusted until the forward model 1118 is validated. Once the forward model 1118 is validated, the obtained geological model can be used to predict geological, petrophysical, and geomechanical information for test wells. A physics-based joint inversion technique can be used to estimate various geological, petrophysical, and geomechanical properties 1120 of intricate geology in order to mitigate uncertainty. Finally, this disclosure examines the applications of using drilling dynamics for formation evaluation in several field examples and consider the potential advantages of implementing this methodology.

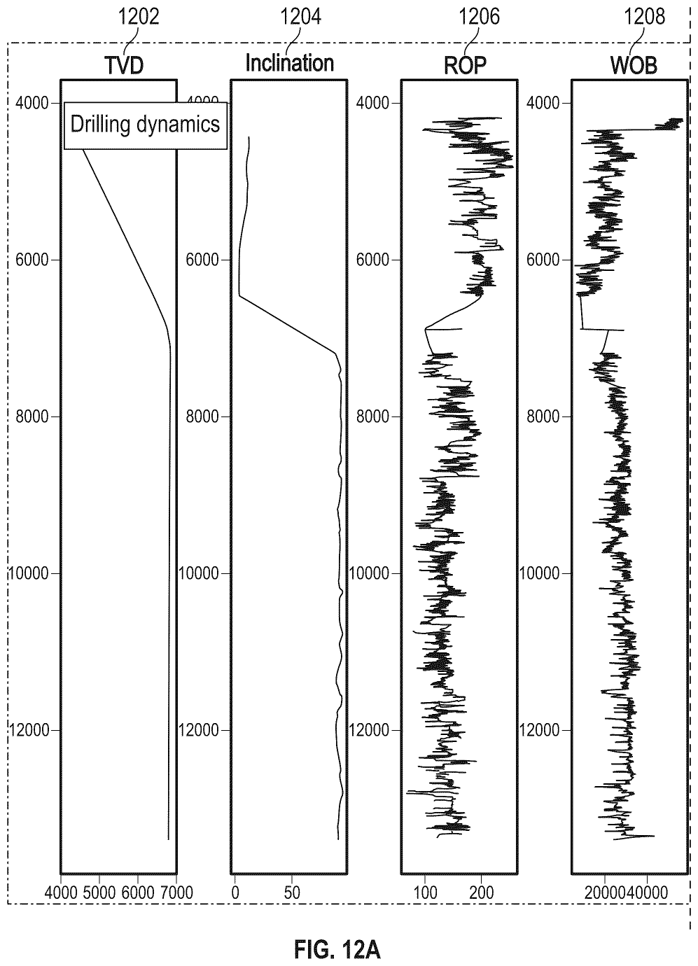

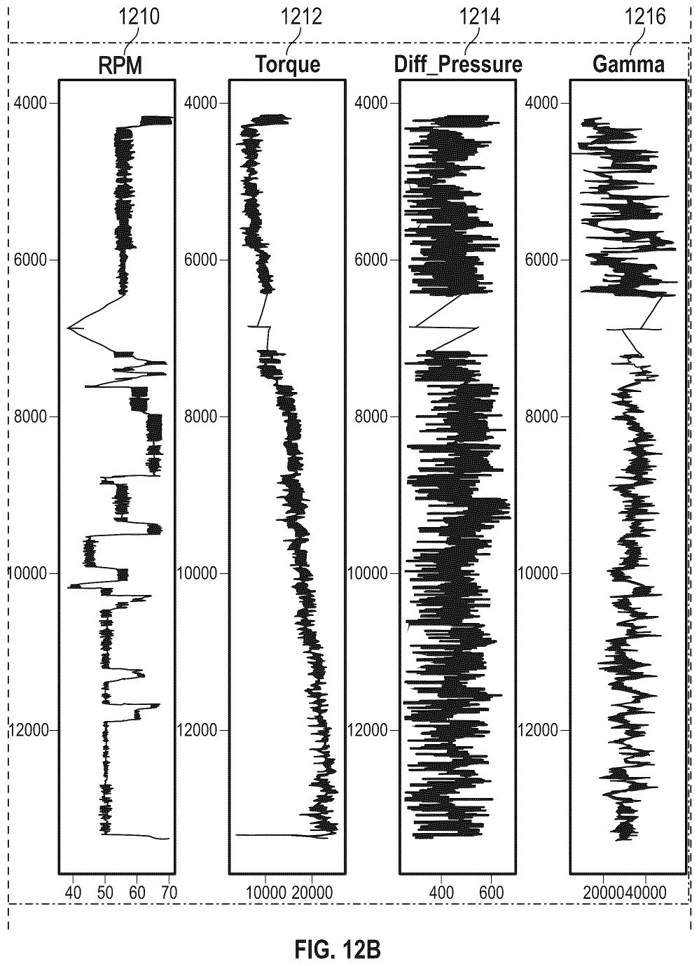

FIGS. 12A-B illustrate an exemplary well data log including a well data log 1200. The well data log 1200 can include input data that can include true vertical depth (TVD) 1202, inclination 1204, ROP 1206, WOB 1208, RPM 1210, torque 1212, differential pressure 1214, gamma 1216. The output data or predicted data can include density 1218, gamma ray 1220, neutron 1222, and resistivity 1224.

### Data Selection and Processing

For the machine learning model to achieve the best triple combo log prediction, the machine learning model may be trained on a set of well logs with the least statistical difference between measurements to identify the optimal training data set, the process can use Kullback-Leibler (KL) divergence theory (Kullback and Leibler, 1951), which is a measure of statistical distance between two probability distributions. The discrete KL divergence is defined as:

$${D}_{KL} ( p ( x ) ‖ q ( x ) ) = {\sum }_{x ∈ X} p ( x ) ln \frac{p ( x )}{q ( x )} \qquad ( 1 )$$

where p(x) and q(x) are two probability distributions of discrete random variable x on the same sample space X. KL divergence represents relative entropy from q(x) to p(x) or less formally, the information lost when q(x) is used as an approximation of p(x).

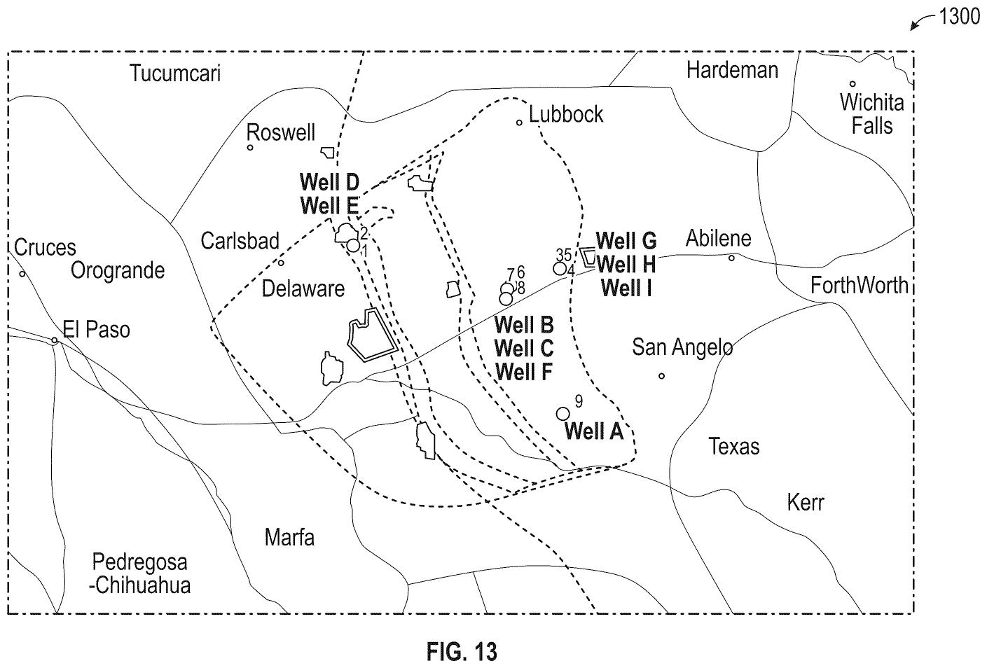

FIG. 13 illustrates a geographical map 1300 of various well locations. In one example, nine unconventional wells are located on the map 1300 on Midland basin are selected and their locations are marked with dots. To identify the best training wells, a Kullback-Leibler divergence matrix can be applied.

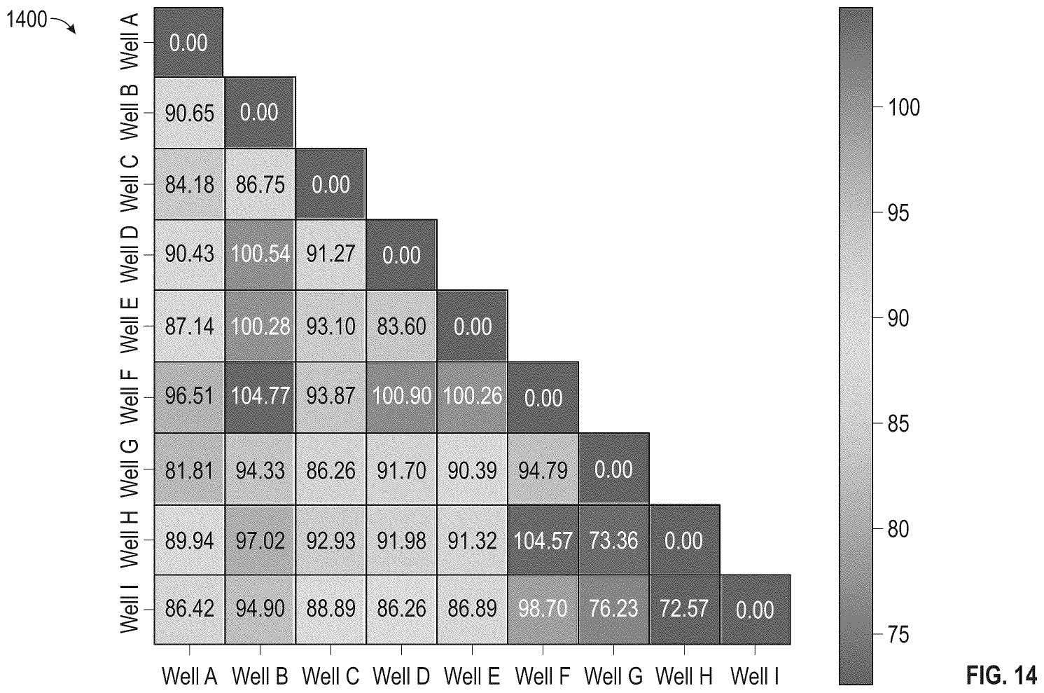

A lower KL divergence thus indicates p(x) and q(x) are more similar. Note that in the case where p(x)=q(x) the KL divergence is zero. In our case, the process can use GR logs as the probability distributions p(x) and q(x) to determine statistical difference between well pairs. The GR log holds a unique position as a reference for both drillers and geosteerers, influencing parameters such as but not limited to torque, pump pressure, and hookload set points. Consequently, variations in drilling dynamics are more likely to be correlated with changes in GR log responses. Given that drilling dynamics serve as input features for predicting triple combo logs, it becomes imperative to select a well with similar drilling dynamics and GR logs to ensure robust petrophysical interpretations. The results are presented in FIG. 14 pairwise in a Kullback-Leibler matrix representing the divergence between all wells.

FIG. 14 illustrates an exemplary Kullback-Leibler divergence matrix for nine unconventional wells. The KL divergence score quantifies how much one probability distribution differs from another probability distribution.

Comparing FIG. 13 and FIG. 14, wells located nearby tend to present lower KL divergence score compared to those located further away. Wells G, H, and I showed the lowest score indicating their GR logs and geologic properties are most similar to each other. Therefore, Wells H and I are the best candidates for training and test wells to predict triple combo logs from drilling. After determining which wells to choose, the technique can access available measurements from MWD logs.

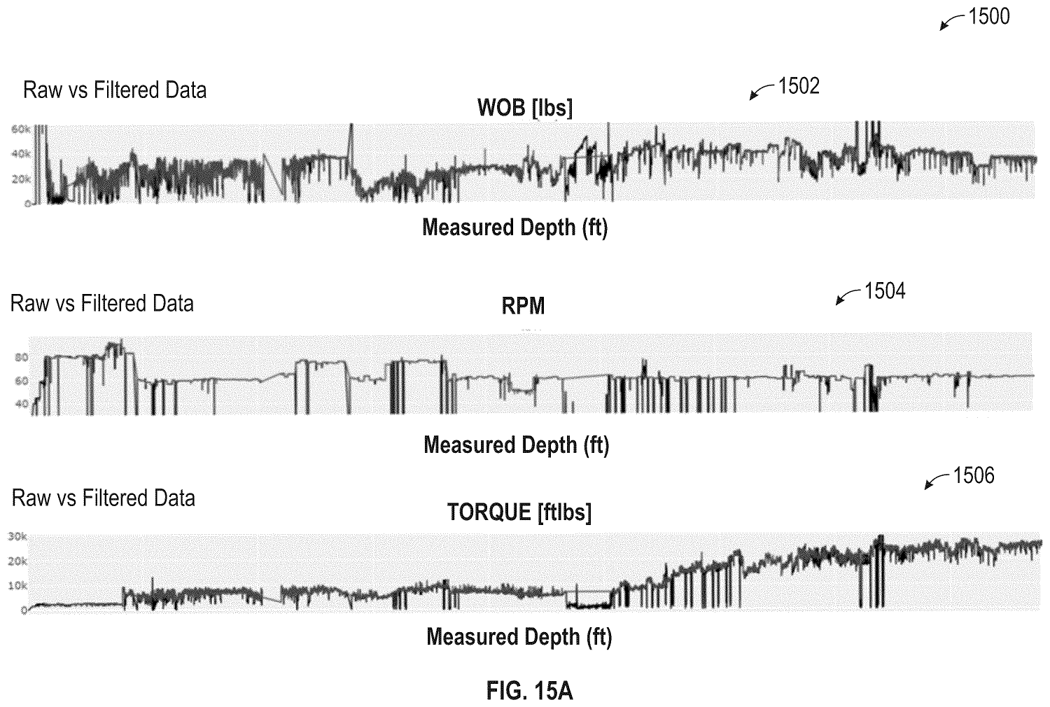

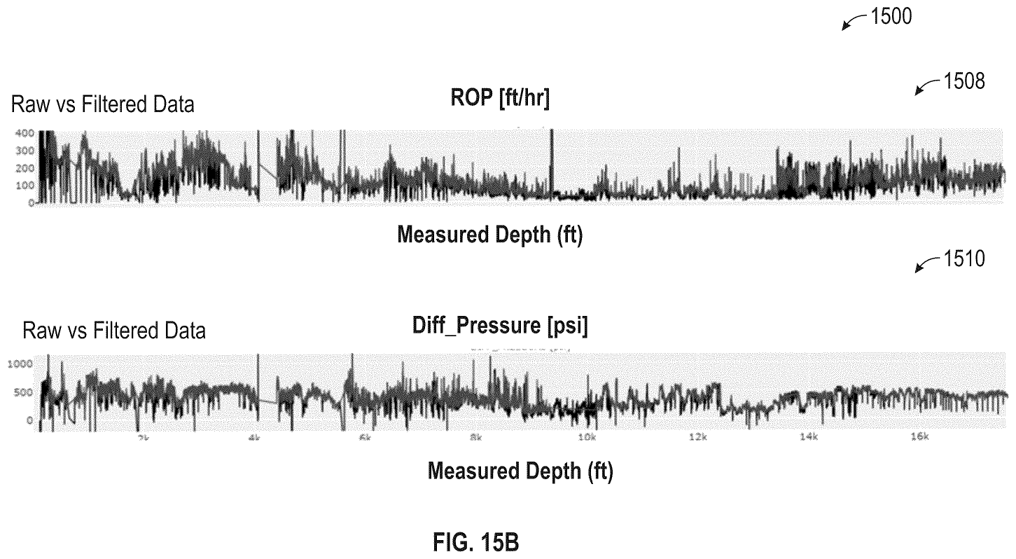

FIGS. 15A-B illustrate exemplary drilling dynamic measurements for a given well. The drilling dynamic measurements can include measured depth (MD), target vertical depth (TVD), NS, EW, inclination (inc), ROP 1508, WOB 1502, RPM 1504, torque 1506, pump_rate, diff_pressure 1510, standpipe_pressure, bit_diameter, slide, gamma, and many more logs.

Similar to most other machine learning applications, input or raw data may be cleaned. In FIGS. 15A-B, from top to the bottom, black lines represent raw measurements and red lines are filtered to remove noise due to drilling vibration and engine load fluctuation. Also, nonphysical measurements and slide sections to be removed which are shown on the straight lines. In the end, the techniques can identify MWD input features for predicting each triple combo log by comparing correlation plots and pair plots.

Drilling dynamics data is notoriously noisy and isolating periods where clear geologic signal is challenging. It is known that within drilling dynamics channels are indicators of geologic truth and drilling noise, the former of which being of the most value in predicting reservoir properties. The drilling dynamics channels can be filtered to isolate the sections with the highest confidence in geologic signal. The logs can be first coarsely processed manually to remove bad data sections typically present at the start and end of the logs, along with any easily identifiable sections of outliers. Following this, a drilling dynamics channel filtering scheme is employed to limit the datasets to periods of realistic, steady-state drilling. Each filter utilizes inferences made from a particular channel and removes those sections of drilling data across the entire set. The specific channels filtered can include WOB, RPM, torque, ROP, and differential pressure utilizing the following series of successive filtering operations.

All channels are first subject to a reasonable value thresholding scheme to eliminate non-physical values indicative of poor data or nonproductive drilling time. Following this, a series of centered rolling filters are utilized to remove undesired sections of drilling based on specific indicator channels. For instance, this disclosure is concerned with rotary drilling and the removal of slides and stand changes; accomplished via a slide indicator and a rolling ROP filter. Both differential pressure and RPM have smaller scale outliers that are removed via a centered rolling median. These noises are mainly caused by the change of engine loads, tool vibrations, drilling pipe connections, and drilling dysfunctions. FIGS. 15A-B showcases Well D where this filtering scheme has been applied, with the raw data represented in black and the filtered data represented in red. Statistical summary of selected input features and triple combo logs from a training well are summarized in Table 1.

TABLE 1
A statistical summary of dataset from a training well.

| | MWD | | | | | | LWD | | | |
|---|---|---|---|---|---|---|---|---|---|---|
| | MD | ROP | Torque | Diff Pres | Stand Pres | Gamma | DEN | GR | Neu | COND |
| count | 66657 | 66657 | 66657 | 66657 | 66657 | 66657 | 66657 | 66657 | 66657 | 66657 |
| mean | 11166.8 | 112.7 | 19282.0 | 414.8 | 2779.9 | 47.9 | 2.80 | 68.76 | 0.06 | 0.12 |
| std | 2486.4 | 30.9 | 3630.3 | 99.0 | 241.4 | 14.9 | 0.14 | 31.48 | 0.06 | 0.07 |
| min | 6321.9 | 33.0 | 7840.0 | 113.4 | 1977.4 | 4.0 | 2.51 | 0.00 | −0.05 | 0.04 |
| 25% | 9133.2 | 88.0 | 16420.0 | 351.8 | 2598.5 | 38.0 | 2.66 | 46.08 | 0.02 | 0.06 |
| 50% | 10893.9 | 111.2 | 19700.0 | 415.4 | 2782.8 | 50.0 | 2.82 | 71.45 | 0.04 | 0.09 |
| 75% | 13381.3 | 134.6 | 21960.0 | 479.9 | 2982.6 | 60.0 | 2.95 | 92.42 | 0.09 | 0.16 |
| max | 15531.5 | 205.6 | 28950.0 | 714.9 | 3390.6 | 84.0 | 2.99 | 161.73 | 0.24 | 0.35 |

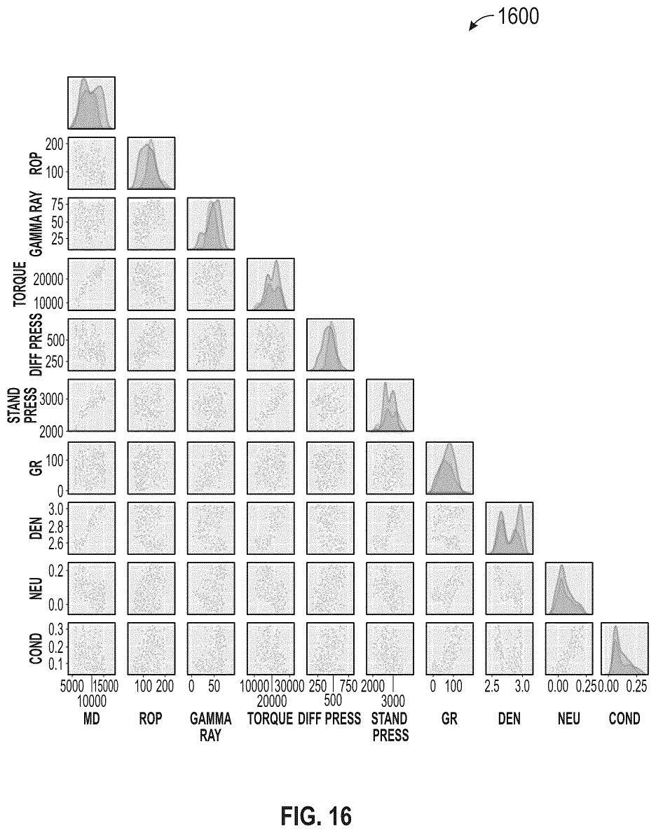

For each offset well, the associated drilling dynamics and triple combo logs will be referenced to a local depth and the log curves will be representative of the local formation thicknesses. To be used together for analysis, they may be aligned precisely. This is a time-intensive process, but it is imperative that all logs are shifted accurately with a reference of the GR log. Cross plots and histograms can identify outliers that may be eliminated from the input dataset. Correlation and pair plots can aid in identifying and selecting particular features (e.g., crucial features, important features, other features of interest, and/or as otherwise desired), which allow for strategic hyperparameter tuning. FIG. 16 displays the relationships between selected drilling dynamics and triple combo logs. Once drilling dynamics are filtered, cleaned, and selected, they can serve as input features for the machine learning model to predict corresponding triple combo logs.

Due to the distinct sampling rate, reference gamma ray (GR) log, and scale of triple combo logs and drilling dynamics, they may be aligned precisely. FIG. 16 illustrates a pair plot of training well H and test well I. Selected combinations of cross plots with input features and target outputs present statistical distributions that can help identifying the relationships between them. FIG. 16 displays the relationships between selected drilling dynamics and triple combo logs. Once drilling dynamics are filtered, cleaned, and selected, they can serve as input features for the machine learning model to predict corresponding triple combo logs.

To estimate reservoir properties from MWD measurements, a two-step workflow is proposed consisting of a machine learning model and joint inversion. The first step involves using a gradient boosting algorithm to predict triple combo logs from drilling dynamic measurements and GR logs. The second step of the workflow utilizes the predicted triple combo logs in a physics-based joint inversion to estimate lithologies, petrophysical, and geomechanical properties.

### Part I: Machine Learning Model

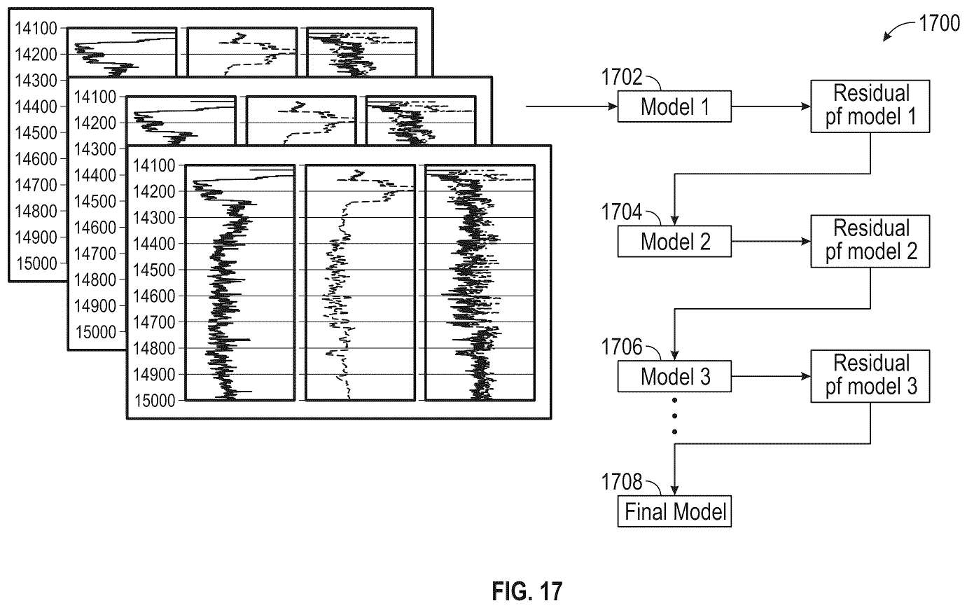

FIG. 17 illustrates an exemplary process for extreme gradient boosting regression (XGBR). During extreme gradient boosting regression can use homogeneous models to learn data sequentially in a very adaptive way to minimize residuals. XGB is a ML algorithm that uses an ensemble of decision trees and gradient boosting to make predictions. However, unlike Random Forest methods, boosting algorithms train homogeneous predictors sequentially, each model trying to correct its previous residual. This is a graphical description of XGBR that as model develops, residuals are getting smaller and ensemble prediction get closer to the log measurements. A first model 1702 can be used to predict the triple combo logs. The residuals from the first model 1702 can be input into the second model 1704. The residuals from the second model 1704 can be input into the third model 1706. The residuals from the third model 1706 can be used to determine a final model 1708, either directly and/or indirectly (e.g., using models in between) as desired.

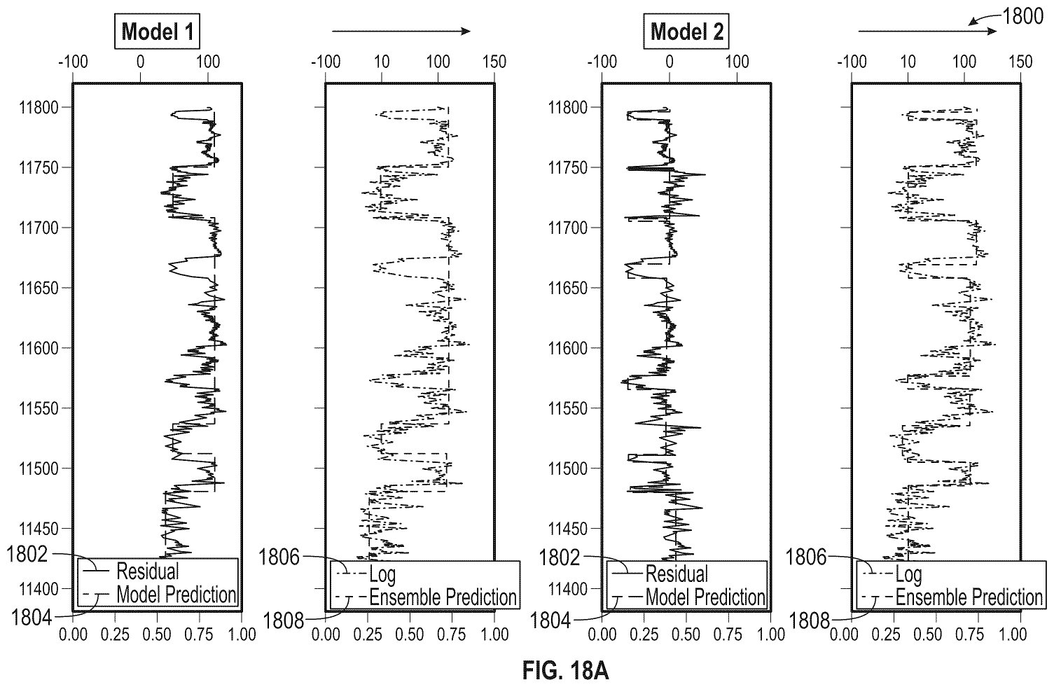

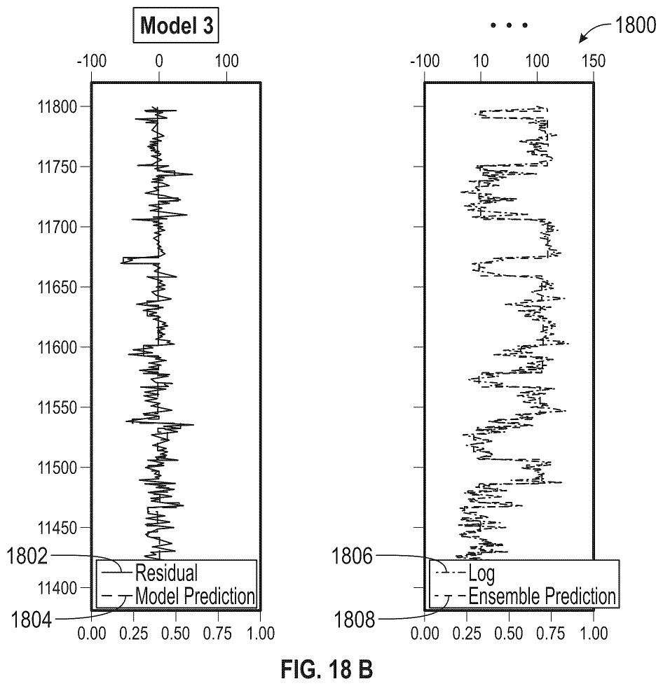

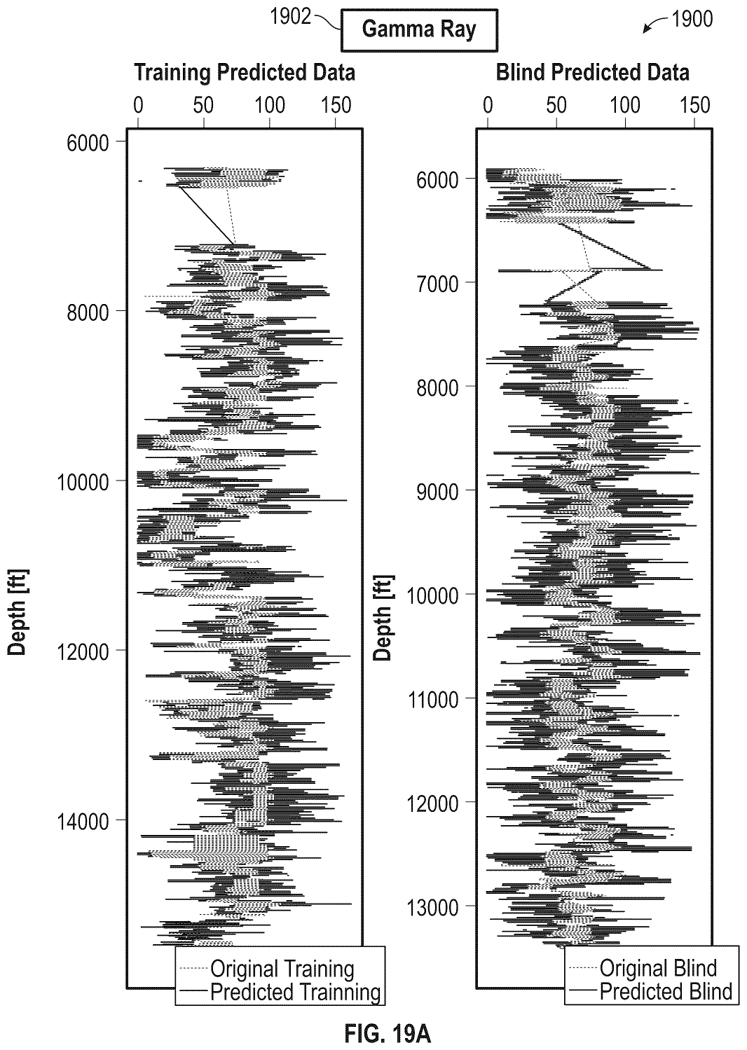

FIGS. 18A-B illustrate an exemplary graphical representation for extreme gradient boosting regression. FIGS. 18A-B illustrate using the residuals 1802 from the model prediction 1804 and the log 1806 and the ensemble prediction 1808 that gets fit into the subsequent model to further refine the model prediction and the ensemble prediction from the log data.

Extreme gradient boosting (XGBoost, Chen and Guestrin, 2016) is a powerful machine learning algorithm used for supervised learning tasks. It is a type of gradient boosting, a method for improving the accuracy of a predictive model by iteratively training a sequence of weak learners. Popular for its scalability and accuracy, it is used for a variety of tasks including regression and classification.

A gradient boosting algorithm works by using decision trees as its base learners and correcting errors from prior learners by focusing on instances with higher errors. Essentially, the problem is posed as a regression or classification problem, where the process can classify the data based on input features. It is represented as a decision tree, where the end leaves represent the possible classifications, and the branch logic is what gets trained. A traditional Gradient Boosting algorithm starts by training a full decision tree via gradient descent on the objective function, and then evaluating its performance. Regions of high error gradient are then identified, and another decision tree is trained which focuses on addressing the error. This is repeated, and ultimately the collection of decision trees (taken sequentially together) becomes a high-quality regressor or classifier. A Root Mean Square Error (RMSE) was adopted as the cost function when training the XGB model. A comparison for selected algorithms to predict compressional sonic slowness (DTC) using drilling dynamics is illustrated below in Table 2. All RMSE values are rounded to 5 decimal places.

TABLE 2
A comparison for selected algorithms to predict DTC using drilling dynamics

| Model | RMSE | Model | RMSE |
|---|---|---|---|
| ExtremeGradientBoosting | 1.68202 | TransformedTargetRegressor | 8.60501 |
| GradientBoostingRegressor | 1.78338 | LassoLarsIC | 8.60501 |
| K-nn | 1.80644 | PLSRegression | 8.68035 |
| HistGradientBoostingRegressor | 2.14836 | LassoCV | 8.92696 |
| RandomForestRegressor | 2.15556 | LarsCV | 8.96681 |
| BaggingRegressor | 2.19665 | Lars | 9.10194 |
| LightGradientBoosting | 2.59613 | ElasticNetCV | 9.30712 |
| CatBoostRegressor | 2.81863 | OrthogonalMatchingPursuitCV | 9.41226 |
| Decision Tree Regressor | 3.15892 | RANSACRegressor | 10.4803 |
| Extra trees | 5.81762 | HuberRegressor | 11.2043 |
| AdaBoostRegressor | 6.39868 | SVR | 11.9551 |
| LassoLars | 8.59847 | NuSVR | 14.1764 |
| ElasticNet | 8.60395 | TheilSenRegressor | 14.2921 |
| BayesianRidge | 8.60477 | LinearSVR | 14.3369 |
| Lasso | 8.60488 | OrthogonalMatchingPursuit | 14.6053 |
| RidgeCV | 8.60499 | DummyRegressor | 15.8036 |
| Ridge | 8.60501 | PassiveAggressiveRegressor | 17.3516 |
| LinearRegression | 8.60501 | MLPRegressor | 60.5173 |

Gradient boosting is quite powerful, but can experience large computation time, especially when run on individual workstations. XGBoost addresses this shortcoming by building and evaluating the decision trees in parallel, one level at a time. This can take advantage of processor-level parallelization and can reach accurate predictors much more quickly due to full gradient knowledge at every decision point. This model is capable of training and testing on large datasets, and so should be able to accurately predict the triple combo logs given MWD measurements.

The Extreme Gradient Boosting Regression (XGBR) objective function contains a cost function and a regularization term as

$$Obj ( θ ) = {\sum }_{i = 1}^{n} C ( {y}_{i} , {\hat{y}}_{i} ) + {\sum }_{k = 1}^{K} Ω ( {f}_{k} ) \qquad ( 2 )$$

$$Ω ( {f}_{k} ) = γ T + \frac{1}{2} λ {\sum }_{j = 1}^{T} {w}_{j}^{2} \qquad ( 3 )$$

where i represents the number of samples in the data. For the tree k, n is the total amount of data used, fₖ is the score, Ω(fₖ) is the regularization term, T denotes the number of its leaves, wⱼ is the weight of j^{th} leave, γ is the complexity parameter to limit the maximum number of leaf nodes, and λ is the control parameter to limit the size of the node score to smooth the final learnt weight. However, unlike Random Forest methods, boosting algorithms train predictors sequentially, each trying (at time t) to correct its predecessor (at time t−1). This process continues optimizing trees until it reaches a predetermined threshold value as

$${\hat{y}}_{i}^{( t )} = {\sum }_{k = 1}^{t} {f}_{k} ( {x}_{i} ) = {\hat{y}}_{i}^{( t - 1 )} + {f}_{t} ( {x}_{i} ) . \qquad ( 4 )$$

When all predictions are combined, ensemble learning involves multiple individual models, i.e. weak learners or base learners, and combines them to improve the prediction accuracy.

To prevent overfitting and reduce variance in an XGBoost model, there are several techniques that can be used. One of the most common is regularization, which can help to reduce the complexity of the model by specifying the required gain for a tree split to occur. L2 regularization (Ridge) can be used by adding a penalty term to the objective function. Additionally, the process can select input features based on correlation plots and pair plots to reduce the risk of overfitting. Some features selected for triple combo logs are listed in Table 3. This listing should not be considered limiting. To evaluate the performance of the XGBoost model and find the optimal hyperparameters, the process applies 5-fold cross-validation by testing the model on unseen data to prevent overfitting to the training data. Finally, the methods and systems of the disclosure can use early stopping to find the best iteration number for training, which can be helpful in further preventing overfitting.

TABLE 3
Selected input features to predict triple combo logs

| | Selected input features from MWD |
|---|---|
| Gamma Ray | MD, Torque, and Gamma Ray |
| Bulk Density | MD, Torque, Standpipe Pressure, ROP, Differential |
| | Pressure, and Gamma Ray |
| Neutron | MD, Gamma Ray, Torque, Standpipe |
| Porosity | Pressure, ROP, and Differential Pressure |
| Conductivity | Gamma Ray, ROP, Torque, |
| | Standpipe Pressure, and Differential Pressure |

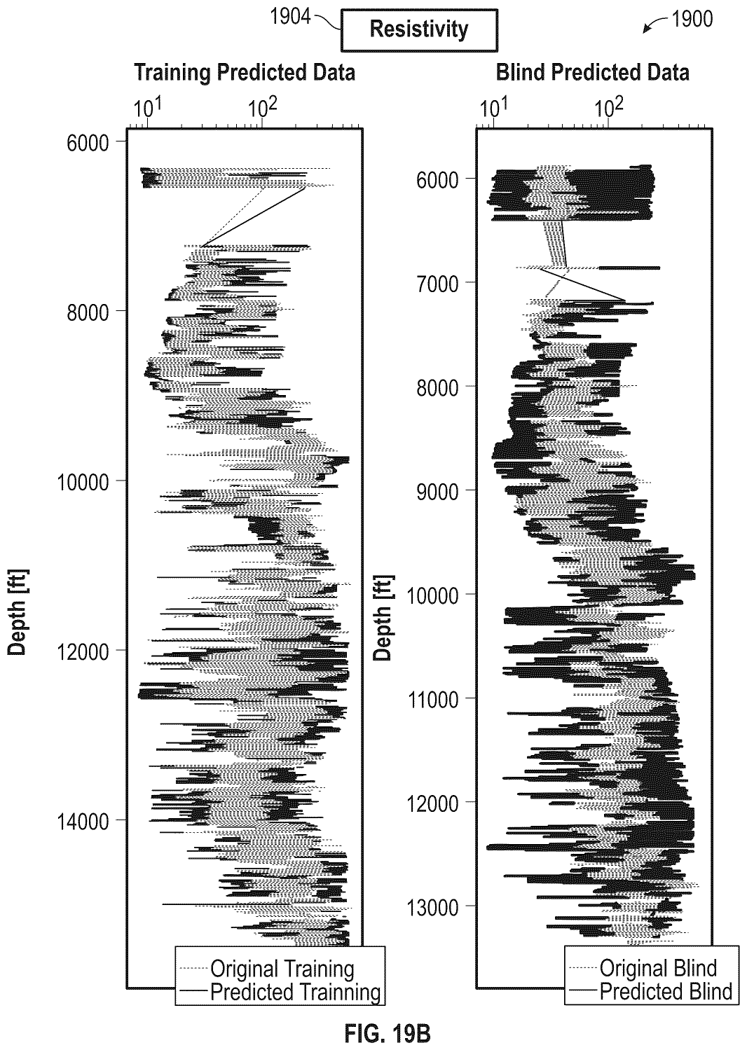

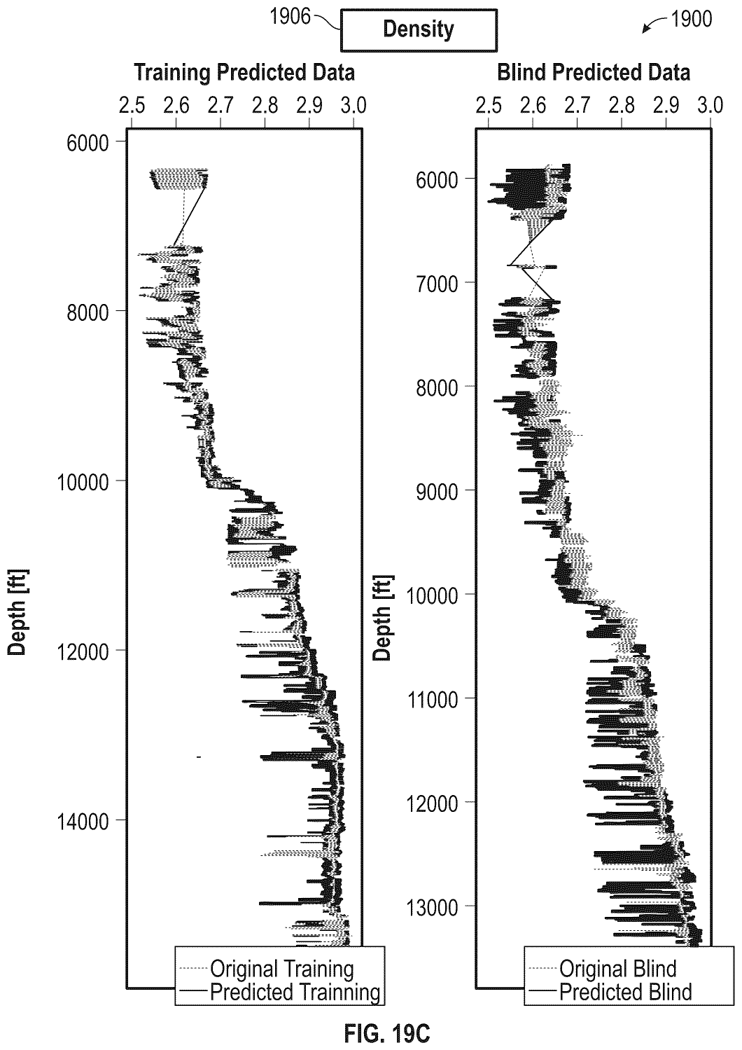

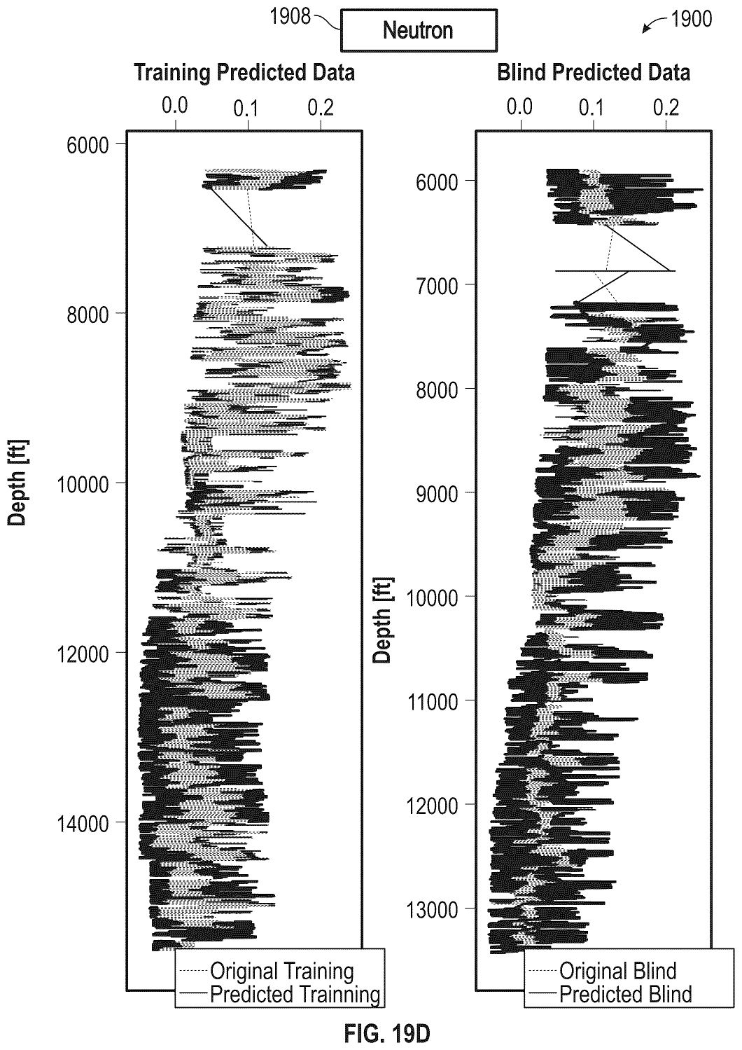

The trained model was then deployed on a blind test well where triple combo logs have been acquired. The model results were compared to the corresponding actual measurements. The predicted logs in FIGS. 19A-D showed excellent agreements when compared to the triple combo measurements, demonstrating the effectiveness of the proposed workflow. A Table 4 presents selected input features used and corresponding RMSE and R² values of training and test dataset prediction results.

TABLE 4
RMSE and R² values of training and test
dataset for each triple combo log

| | |
|---|---|
| Training | Test |

| | RMSE | R² | RMSE | R² |
|---|---|---|---|---|
| Gamma Ray | 11.381 | 0.872 | 28.299 | 0.116 |
| Bulk Density | 0.013 | 0.991 | 0.035 | 0.920 |
| Neutron Porosity | 0.024 | 0.848 | 0.047 | 0.452 |
| Resistivity | 88.316 | 0.591 | 109.37 | 0.400 |

Once the technique has finalized the machine learning model, the process can use drilling dynamics obtained from a training well to predict triple combo logs. Solid lines can represent original measurements and dashed lines can represent predictions for GR, bulk density, neutron porosity, and resistivity. And the process has applied the same model to the blind test well to generate triple combo logs. The table above provides RMSE and R squared values of these prediction results. To prevent overfitting, the process can apply regularization, feature selection, k-fold cross-validation, or hyperparameter tuning.

FIGS. 19A-D illustrate exemplary prediction results for predicting triple combo logs 1900. The exemplary prediction results can include Gamma Ray 1902, Resistivity 1904, Density 1906, and Neutron values 1906, Each of the prediction results can include training predicted results and blind predicted data. XGBR can be used to successfully predict triple combo logs using the drilling dynamics measurements.

### Part II—Physics-Based Joint Inversion

After obtaining triple combo logs from the machine learning model, the techniques can use them as inputs into the physics-based joint inversion. A fundamental idea is to minimize the cost function that has a difference between measured (d) and reconstructed f(x) logs multiplied with data weighting matrix and a regularization term with alpha. Also, material balanced equation and non-negative constraint can be applied because all volumetric concentrations of minerals and fluids have values between 0 and 1. The inversion is linear and deterministic, and it provides reconstructed well logs. In some cases, one or more computations can be done in real-time so that reservoir properties can be estimated simultaneously while drilling into the target formations.

Joint inversion is a valuable technique used to estimate various reservoir properties, including total porosity, clay volume, water saturation, volumetric concentrations of lithology, permeability, rock type, and geomechanical parameters. This method enables accurate estimation of subsurface properties by incorporating measurements from natural Gamma Ray (GR), resistivity, bulk density, and neutron porosity logs. Optional measurements can be used to augment the inversion, such as sonic, photoelectric factor (PEF), X-ray diffraction (XRD), and ECS logs. Joint inversion is particularly advantageous in areas where there is limited well logging data, and traditional techniques like core analysis and outcrop examination are not possible.

The inversion process involves several steps to estimate reservoir properties such as total porosity, clay volume, water saturation, volumetric concentrations of lithology, permeability, rock type, and geomechanical parameters. The first step is to obtain temperature, pressure, and salinity from various sources such as geothermal gradient, mud weight, fluid samples, drilling report, and Pickett plot (Pickett, 1973). This information is used to establish earth models with multi-mineral sets. The bulk density of water, oil, and gas can then be calculated based on the established models and input parameters. The inversion process may utilize several input logs, including natural Gamma Ray, resistivity, bulk density, and neutron porosity logs predicted from previous ML models. Sonic logs can also be added to avoid underdetermined conditions in complex lithologic scenarios.

Once the input logs and plausible minerals and fluids are defined, corresponding uncertainties and weightings can be assigned. The kernel matrix is predefined with default parameters, but they can be modified during the iteration process. The wet clay model is used to consider bound water inside the formation and corresponding wet clay porosity varies with temperature and pressure. Additionally, constraints such as the material balanced equation (MBE), carbonate flag, or Illite-Smectite ratio can be applied throughout the intervals.

The inversion takes conductivity instead of resistivity, as it shows a relatively linear relationship with the amount of conductive materials in the formation. Since the inversion is a linear model, the relationships between input logs and unknown parameters may be linearized. Linear inversions do not involve Hessian and Jacobian matrix, thus saving computational time. However, small perturbations in inputs can result in high deviations in outputs, which may needs regularization. Therefore, Tikhonov regularization is applied to ensure robust and stable solutions can be found.

The cost function with a data weighting matrix can be represented by the following formula:

$$C ( \overline{x} ) = \overline{\overline{{W}_{d}^{2}}} \cdot {[ \overline{f} ( \overline{x} ) - \overline{d} ]}^{T} \cdot [ \overline{f} ( \overline{x} ) - \overline{d} ] + {α}^{2} {\overline{x}}^{T} \overline{x} \qquad ( 2 )$$

where W̅_̅{̅d̅}̅, f̅(x̅), d̅, x̅, and α are the data weighting matrix, reconstructed measurements from a forward model, measurement vector, unknown parameter vector, and a regularization parameter, respectively.

The regularization parameter may be carefully selected to balance reducing the value of ∥x̅∥₂² and the error of ∥f̅(x̅)−d̅∥₂². By minimizing the cost function, a least-squares solution can be obtained. Non-negative constraint can be added since all unknown parameters range from 0 to 1.

After completing the joint inversion with triple combo logs, the forward model can be used to reconstruct input well logs from the inverted geologic model. This is achieved by multiplying the kernel matrix with the estimated unknown parameters. By comparing the reconstructed triple combo logs to the measured logs, errors can be calculated and minimized through iterations. The forward model can also predict other logs, such as compressional sonic slowness, which were not used in the inversion. Total porosity can be computed as the sum of bound water, free water, oil, and gas. Permeability can be calculated using various equations, but the disclosure adapts Herron's permeability model (Herron, 1987) based on Kozeny-Carman's equation and inverted volumetric concentrations of lithologies.

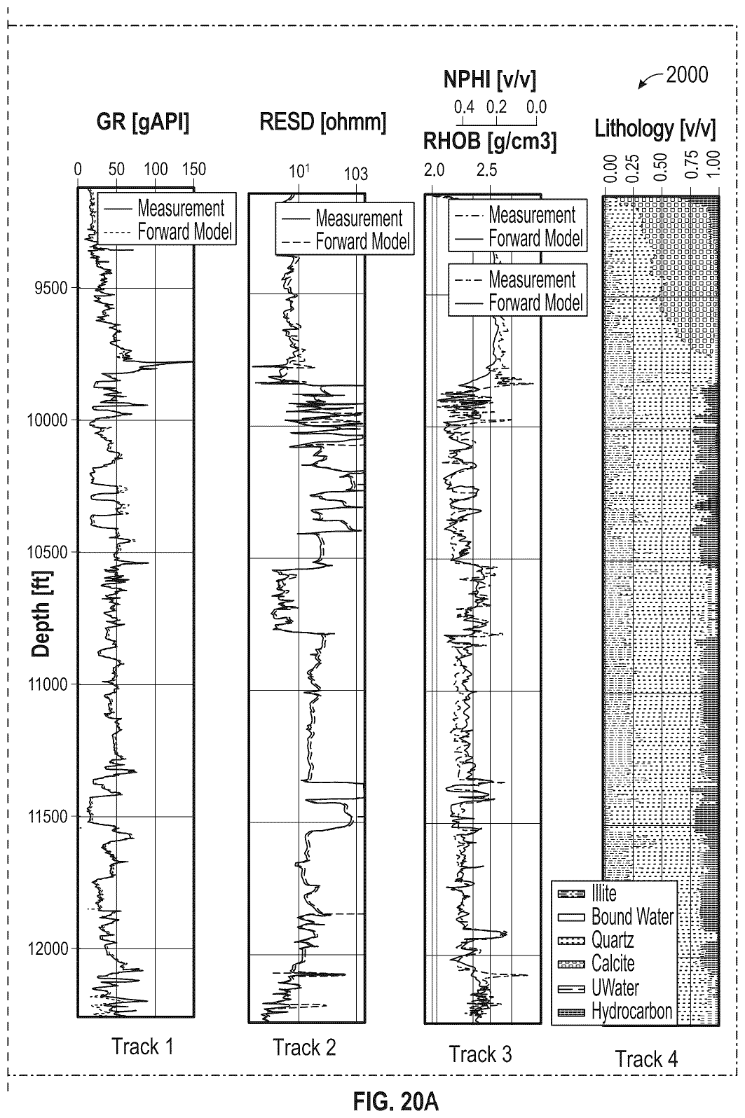

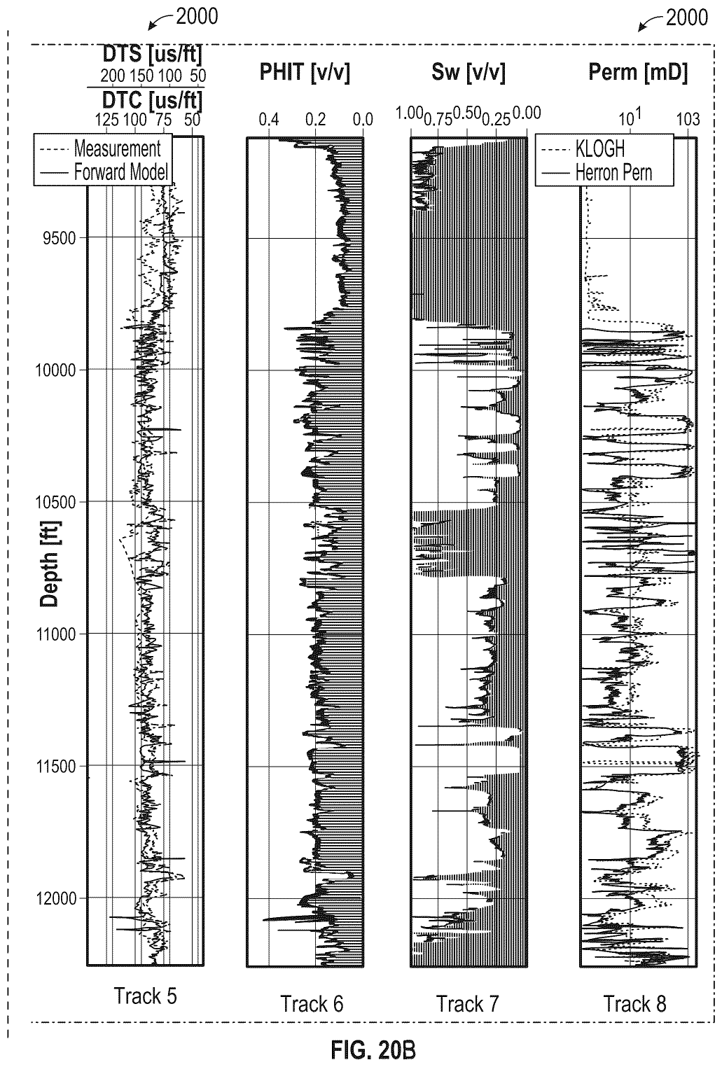

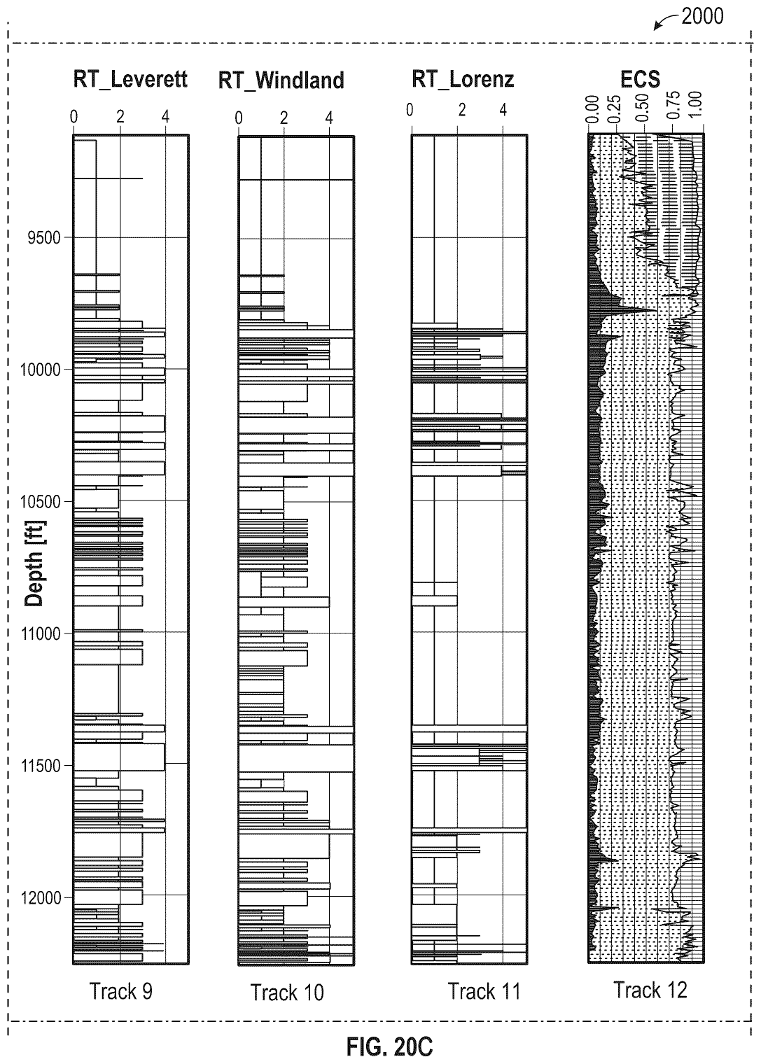

FIGS. 20A-C illustrate example well log interpretation for a conventional well from Equinor Volve field. Tracks 1-3 present triple combo logs with reconstructed logs from the forward model. Track 4 shows inverted volumetric concentrations of minerals and fluids (e.g., Illite, Quartz, Calcite, water and hydrocarbon) which can be verified with lithology computed from elemental capture spectroscopy shown on the last track. Track 5 shows compressional and shear sonic logs and their forward models. Following tracks present petrophysical properties. For example, Track 6 presents total porosity, and Track 7 presents water saturation. Track 8 displays both the permeability calculated by a petrophysicist and estimated with Herron's model. Tracks 9-11 illustrate classified rock types estimated with Leverett (Track 11), Winland (Track 10), and Lorenz (Track 9) methods, respectively. The last track, Track 12, presents mineral compositions from ECS measurements, which can be compared with those from inversion.

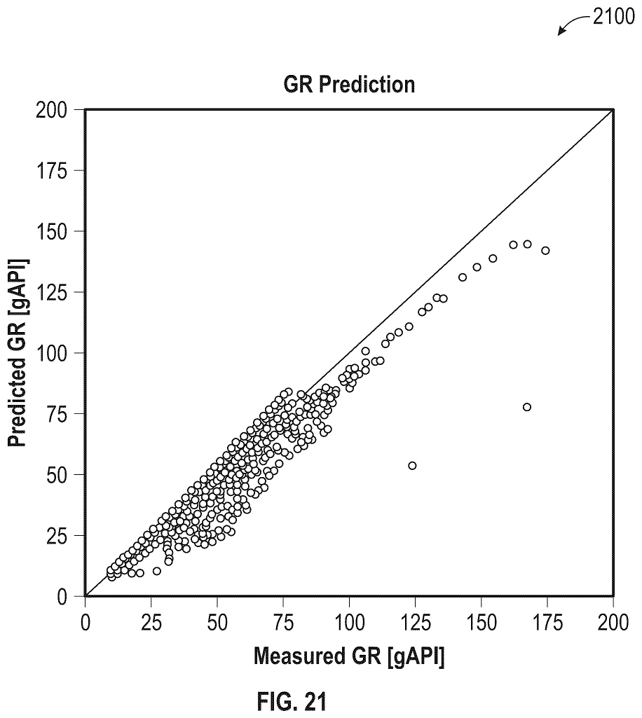

FIGS. 21-25 show the comparisons of measured and reconstructed logs from the forward model. These cross plots are comparisons between measured logs on x axis and reconstructed logs on y axis, respectively. Most triple combo logs from the forward modeling are in excellent agreement with measured logs. Bulk density cross plot shows relatively scattered but it can be mitigated with higher data weighting values. Interesting point here is that although sonic log was not used in the inversion, the joint inversion can reconstruct it that honors original measurements. This indicates that the inversion model is robust and stable and inverted geologic model is more likely represented to the formation properties from the reservoir.

The comparisons of measured and reconstructed triple combo and sonic log prediction results can be constructed for both training and test wells. Despite generally following the trends observed in measured logs, reconstructed logs display some discrepancies in resistivity, bulk density, and sonic logs. To minimize these differences, several approaches can be taken, including: (1) interpreting different formation intervals separately and then combining them, (2) decreasing the weights assigned to gamma-ray and neutron porosity while increasing those assigned to resistivity and bulk density, (3) adding or removing an additional element, (4) calibrating inversion parameters using core data, (5) using an alternate water saturation model, (6) applying supplementary constraints, and (7) refining the regularization parameter.

FIG. 21 illustrates an exemplary Gamma Ray prediction graph 2100. In FIGS. 20A-C the Gamma Ray prediction is plotted against the measured Gamma Ray values.

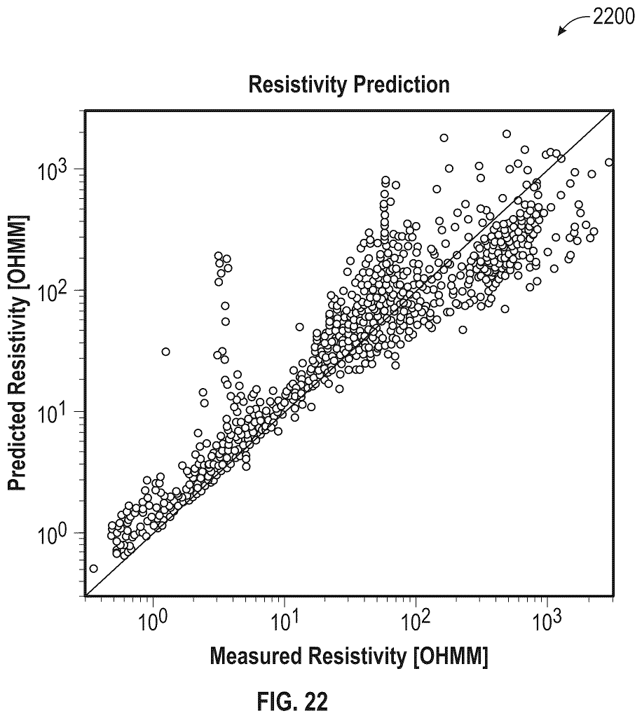

FIG. 22 illustrates an exemplary resistivity prediction graph 2200. In FIG. 21 the resistivity prediction is plotted against the measured resistivity values.

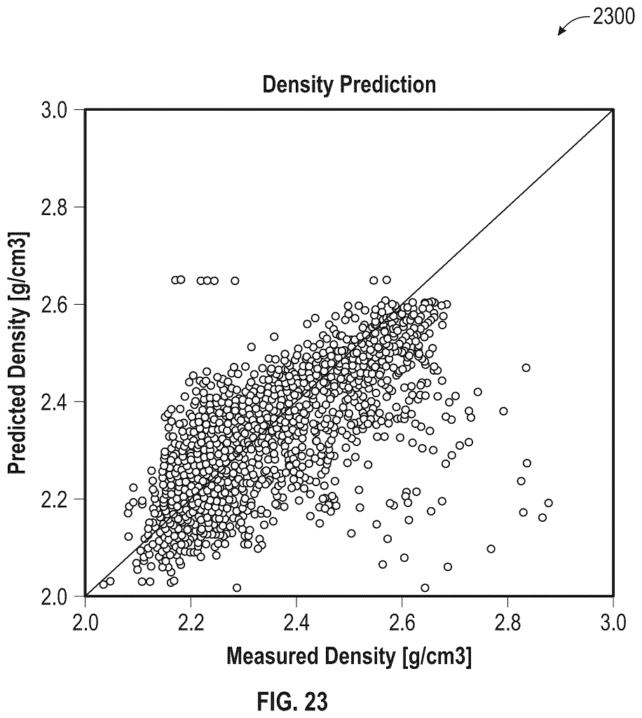

FIG. 23 illustrates an exemplary bulk density prediction graph 2300. In FIG. 23 the density prediction is plotted against the measured density values.

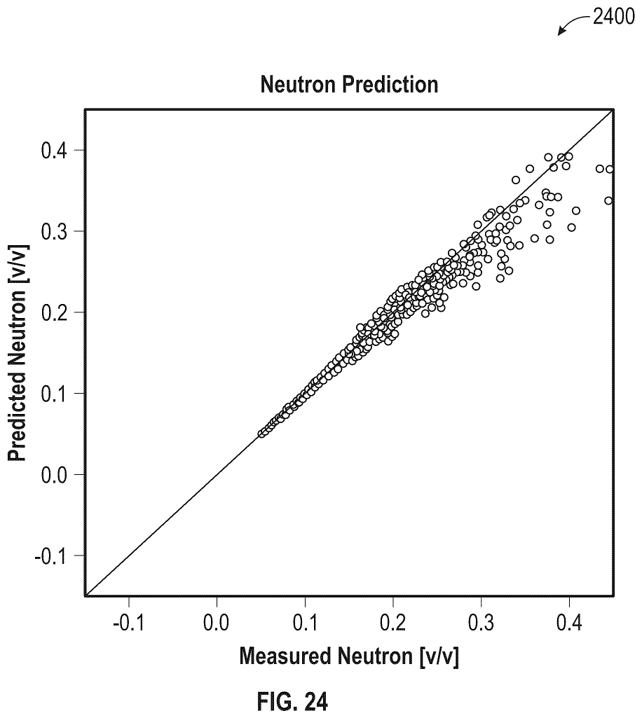

FIG. 24 illustrates an exemplary neutron porosity prediction graph 2400. In FIG. 24 the Neutron prediction is plotted against the measured Neutron values.

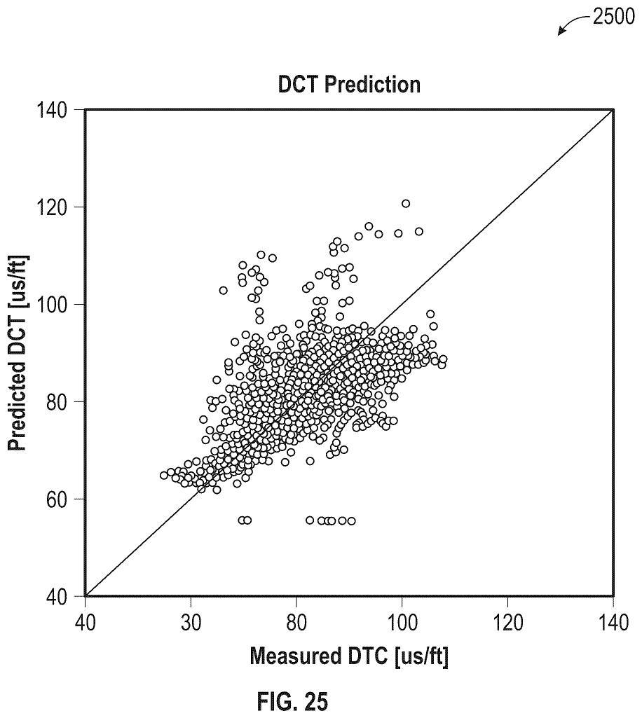

FIG. 25 illustrates an exemplary shear sonic slowness graph 2500. In FIG. 25 the compressional sonic slowness (DTC) prediction is plotted against the measured DTC values.

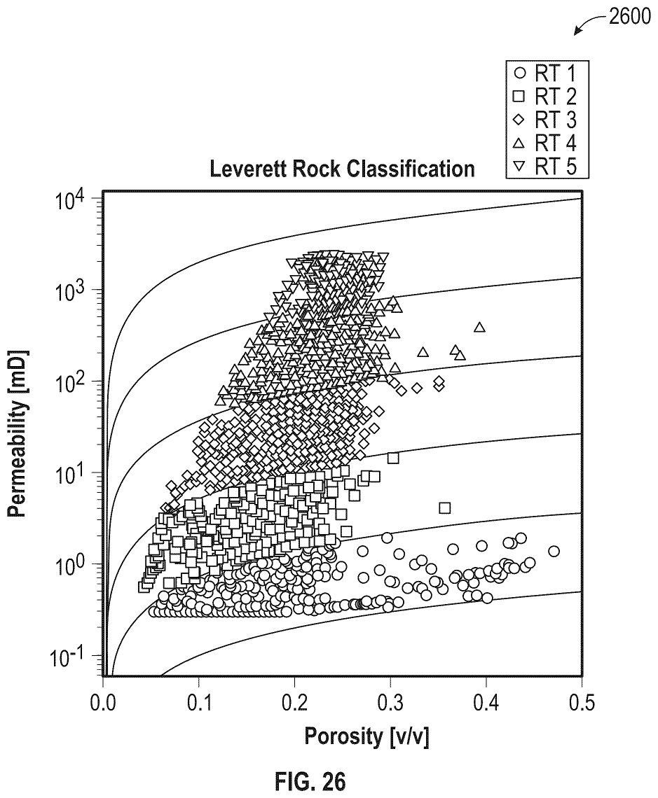

FIGS. 26-28 illustrate three rock classifications that can be based on total porosity and permeability. Total porosity was calculated from the summation of free water, bound water, oil, and gas and the permeability can be estimated from Herron's paper, 1987. Previously calculated total porosity and permeability enable rock classifications that can greatly benefit reservoir modeling and simulation. Several well log-based rock classification methods are widely used. One of the earliest methods, the reservoir quality index (RQI), was introduced (Leverett, 1941) established on the porosity and permeability ratio. FIG. 26 illustrates an exemplary Leverett Rock classification prediction graph 2500 that can plot permeability versus porosity for the formation.

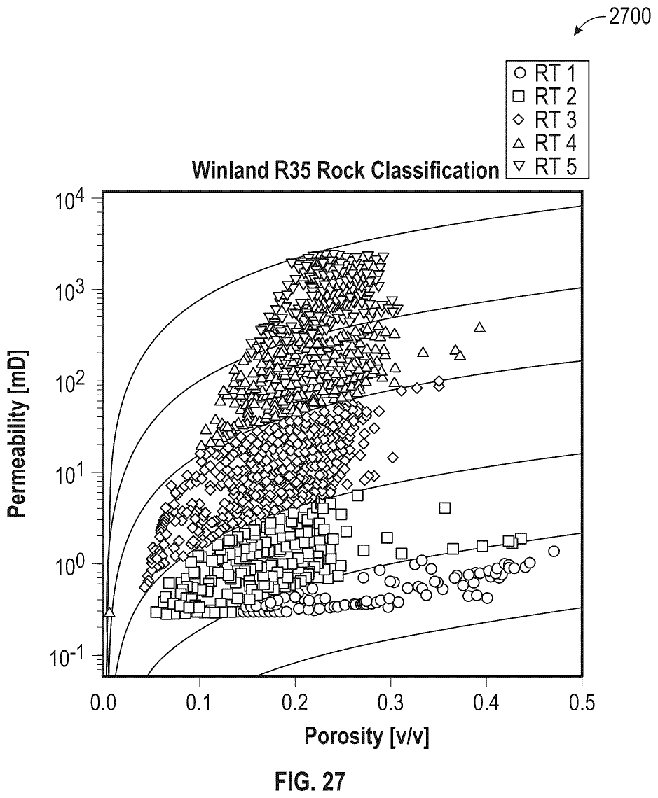

FIG. 27 illustrates an exemplary Winland R35 Rock classification graph 2600. The Winland R35 method, derived from Spindle field sandstone core samples, was presented to find a relationship of porosity to permeability (Pittman, 1992). The Winland R35 Rock classification graph 2600 can plot permeability versus porosity.

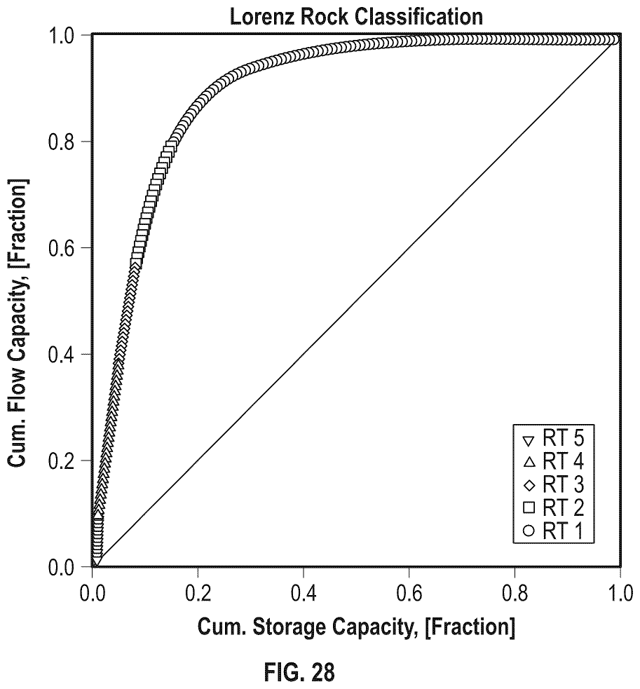

FIG. 28 illustrates an exemplary Lorenz Rock Classification graph 2700. The Lorenz Rock Classification graph 2700 plots cumulative flow capacity versus cumulative storage capacity. Lorenz's method, based on Hydraulic Flow Unit (HFU) with storage and flow capacity, is another popular classification method (Amacfule et al., 1993). All three methods show Rock Type 1 (worst) to Rock Type 5 (best). The Lorenz rock types tend to be more pessimistic, while the Leverett method is more optimistic in terms of predicted rock types. However, the thresholds for each rock type can be adjusted according to reservoir properties.

By analyzing the subsurface's mechanical state, geomechanical properties can be calculated, which may be utilized by operation geologists and/or geomechanical specialists to ensure the safety and efficiency of drilling operations and hydrocarbon resource development. Compressional (DTC) and shear (DTS) sonic slowness provide the basis for computing a range of elastic and inelastic properties, such as Young's modulus, shear and bulk moduli, Poisson's ratio, unconfined compressive strength (UCS), tensile strength, angle of internal friction, and confined compressive strength (CCS). These UCS and CCS values can be compared to the mechanical specific energy (MSE) to identify drilling dysfunctions. A comparison of various UCS equations can be found in previous disclosure Chang et al., 2006.

A Python 3.9 environment was used to script all computations in this application. For a well containing a 3,000 ft interval with a 0.5 ft sampling, the total computation time is approximately 10 seconds. Given the fast runtime, this method could be used for real-time formation evaluations using pre-trained machine learning models created from dynamic measurements obtained during drilling operations. This could circumvent the need to run additional logging tools, reducing the time and cost of acquiring well logs.

### Results: Field Examples

In this section, field examples can be used to demonstrate the outcomes of the proposed workflow and compare them with traditional petrophysical interpretations. The Equinor Volve field will be the first example presented, as depicted in FIG. 20A-C. Track 1 displays both the measured and reconstructed GR logs from the forward model, followed by the measured and reconstructed deep resistivity logs in Track 2, and the measured and reconstructed bulk density and neutron porosity logs in Track 3. Track 4 shows the inverted concentrations of minerals and fluids, and Track 5 features the measured and reconstructed sonic logs from the forward model. Track 6 presents total porosity, and Track 7 presents water saturation. Track 8 displays both the permeability calculated by a petrophysicist and estimated with Herron's model. Finally, the tracks showcase the classified rock types using the Leverett (Track 9), Winland R35 (Track 10), and Lorenz (Track 11) methods. In Track 12, mineral compositions from ECS measurements can be compared with those from inversion.

The inverted lithology model provides an estimate of the possible geological elements present in the formation, including sandstone, shale, or limestone. This model was verified with ECS measurements and achieved a high degree of accuracy. Furthermore, the agreement between the measured and reconstructed triple combo and sonic logs, as well as the permeability (indicated by black dashed lines), supports the inverted geologic model. Other petrophysical properties include total porosity, permeability, and water saturation, which refer to the percentage of rock that consists of pores or open spaces, the ability of fluids to move through the rock, and the percentage of pore space filled with water, respectively.

It is worth noting that the proposed inversion model did not use sonic logs (DTC and DTS). Although the measured and reconstructed sonic logs seem generally similar, a closer inspection reveals that the proposed methodology is slightly more robust against missing or noisy logs. This observation holds throughout the interval, especially in the section around 10,500 ft-10,800 ft, where non-physical constant sonic values resulted from an interpolation due to missing data. Additionally, there are several spikes in resistivity and neutron porosity measurements around 10,240 ft, 11,480 ft, and 11,850 ft that were not present in the reconstructed logs.

The predicted permeability is slightly underestimated, but it can be improved by adjusting the permeability factor of each element. Furthermore, knowledge of the corresponding rock types may aid in determining the optimal location for perforation to maximize production, which is strongly linked to total porosity and permeability.

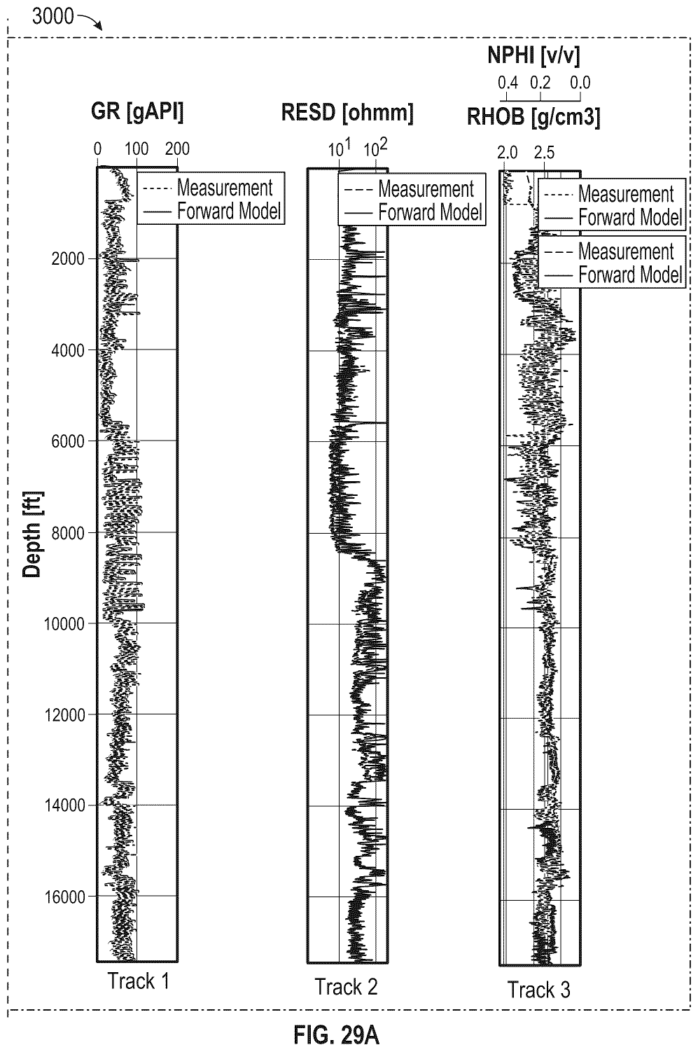

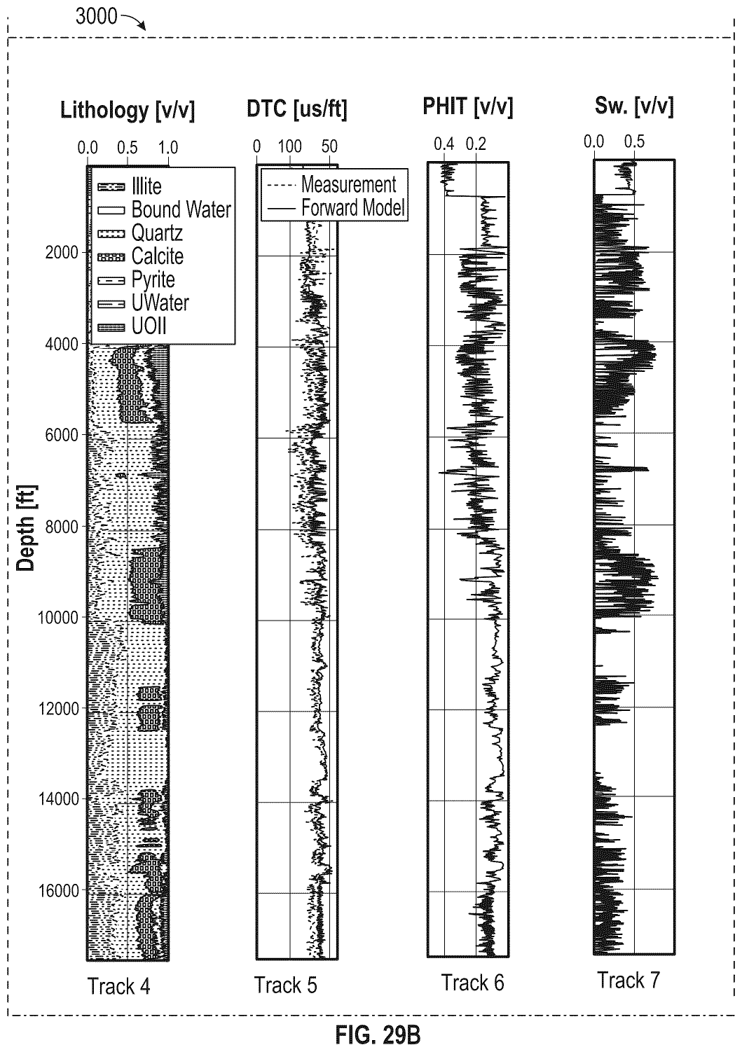

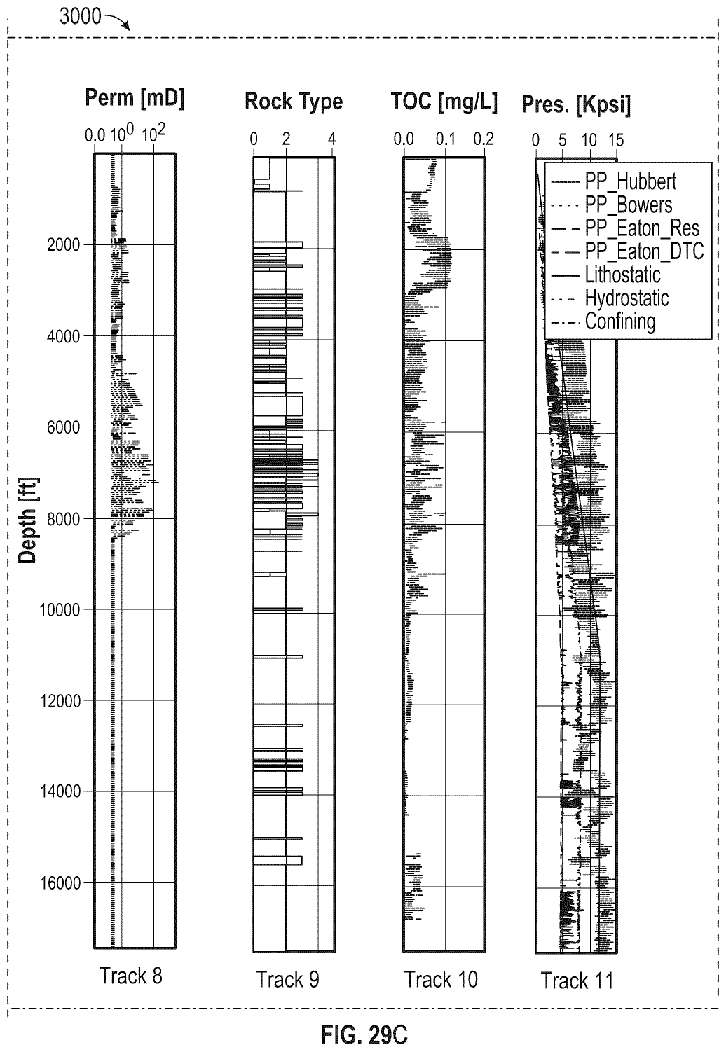

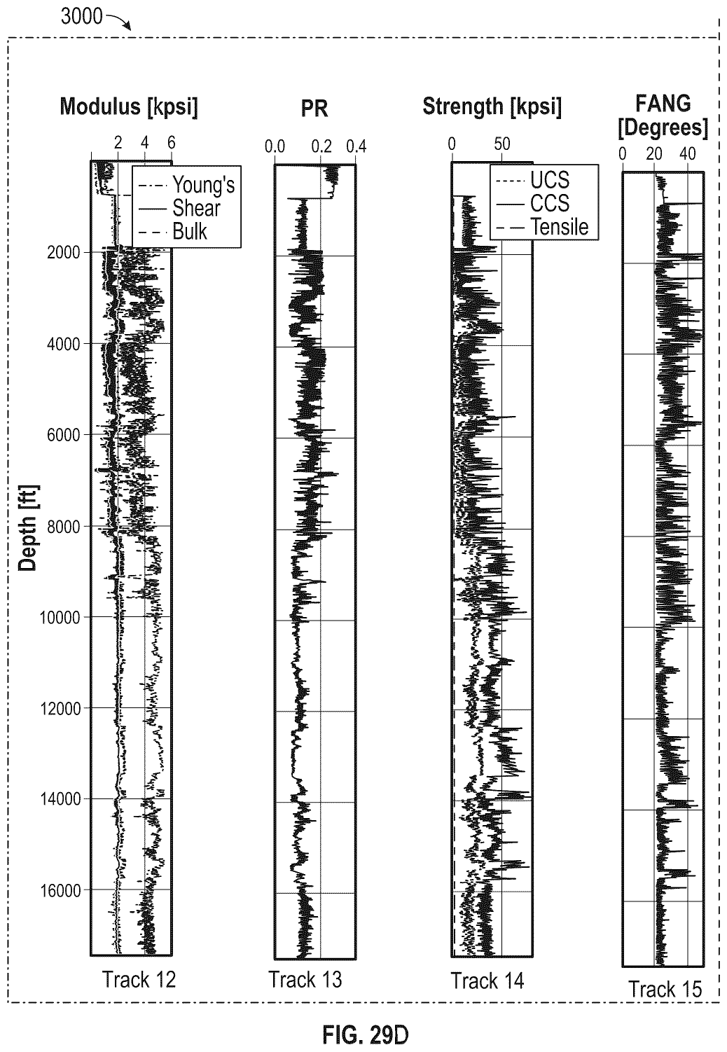

FIGS. 29A-D depict the second example field from a Permian basin well. Tracks 1-4 illustrate the measured and reconstructed triple combo logs (Tracks 1-3), as well as the inverted lithologic concentrations of minerals and fluids (Track 4). Track 5 shows the measured and reconstructed sonic logs, while Track 6 displays total porosity and Track 7 displays water saturation. Tracks 8 and 9 display permeability calculated using Herron's model and classified rock types using the Winland R35 method. Other geological and geomechanical properties, such as total organic content (TOC) predicted from Schumacher's equation (Schumacher, 2002), are presented Track 10. Track 11 summarizes pressure analysis, including pore pressures (Hubbert et al., 1957; Bowers, 1995; Eaton, 1972 and 1975), lithostatic and hydrostatic pressures, and confining pressure, indicating vertical and lateral sections of the well trajectory. The remaining tracks showcase various geomechanical properties, including Young's modulus, bulk modulus, and shear modulus (Edimann et al., 1998) in Track 12, Poisson's Ratio in Track 13, UCS, CCS, and tensile strength (Riberio et al., 2015) in Track 14, and friction angle (Plumb, 1994) in Track 15. These geomechanical properties estimated from MWD measurements during the drilling operation can improve drilling efficiency, identify wellbore stability, enhance safety, help reservoir understanding, and save cost. Following with inverted lithology, compressional sonic log, total porosity, water saturation, permeability calculated from Herron, and corresponding rock types. In addition, Total Organic Carbon was calculated from Schumacher 2002 paper. Pore pressure prediction may be utilized to prevent unexpected kick during the drilling so the process has calculated lithostatic, hydrostatic and pore pressure from Hubbert, Bowers, and Eaton's equations. The plateau pressures below 10 thousand feet indicating horizontal drilling sections. For geomechanical properties, Young's modulus, Shear modulus, and bulk modulus can be estimated with Poisson's ration. Also, various rock strengths including UCS, CCS, and tensile strength can be calculated to compare with mechanical specific energy for drilling efficiency. Friction angle on the last track represents the information on shear strength of the rock being drilled.

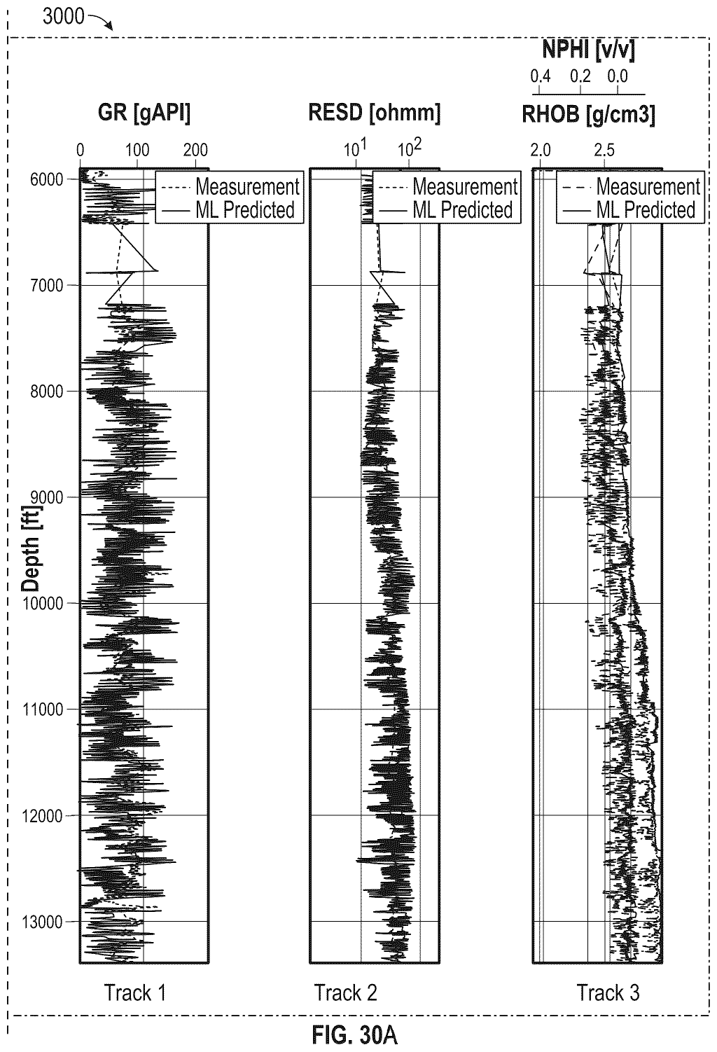

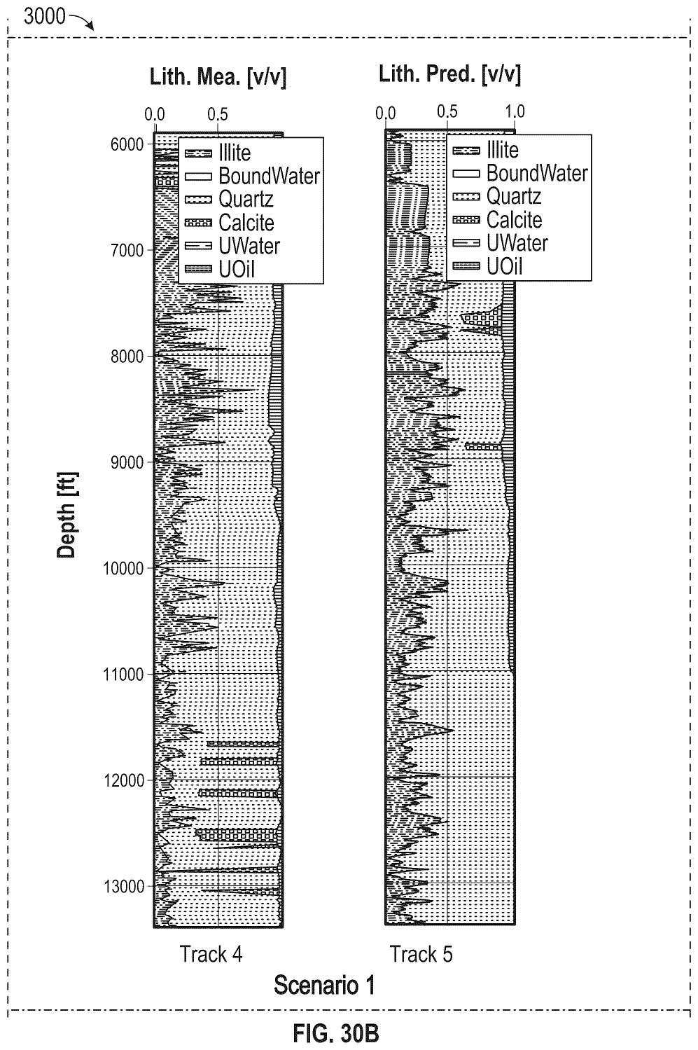

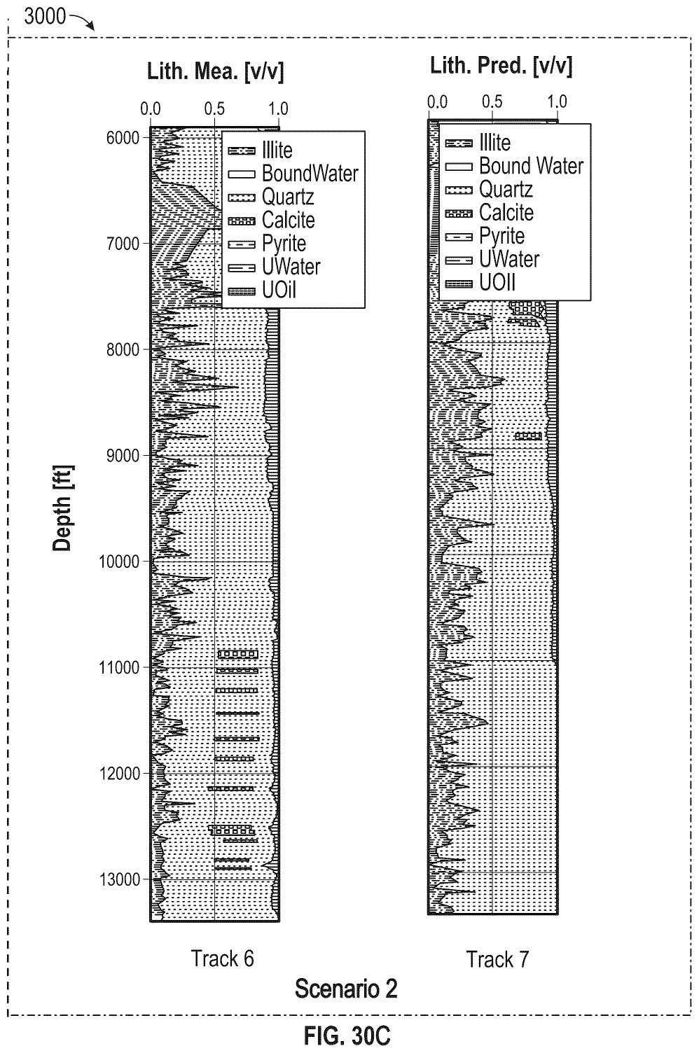

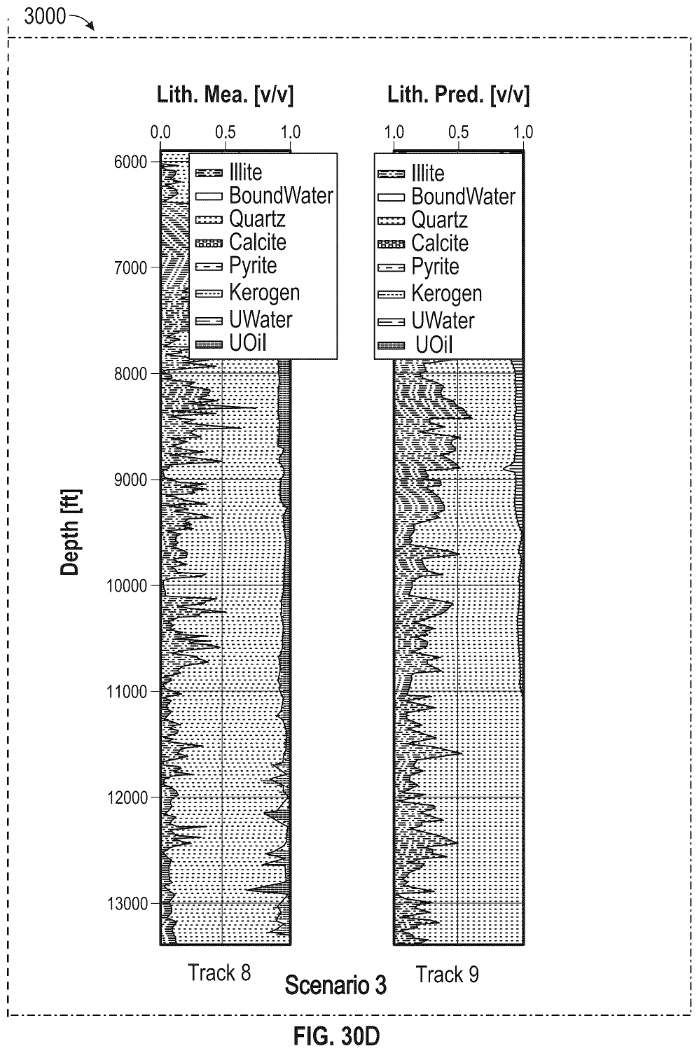

FIGS. 30A-D illustrates exemplary logs from an unconventional well from Midland basin. Track format can similar to the previous example, starting with triple combo logs and their reconstructed logs with black lines.

Finally, the process has evaluated the extent to which errors between measured and predicted triple combo logs would impact the geologic models derived from the physics-based inversion model. The evaluation procedure entailed three stages: (1) executing the inversion with measured triple combo logs, (2) executing the inversion with predicted triple combo logs from the ML model, and (3) comparing the discrepancies between the volumetric concentrations of lithologies and the corresponding petrophysical and geomechanical parameters from these two inversion models depicted in FIGS. 30A-D. Tracks 1-3 present the measured and predicted triple combo logs from the ML model, while Tracks 4-9 show the inverted lithologies for three different geologic scenarios (Scenarios 1-3) using measured triple combo logs (left) and predicted triple combo logs (right). Scenario 1 includes Tracks 4 and 5, Scenario 2 includes Tracks 6 and 7, and Scenario 3 includes Tracks 8 and 9. Plausible lithologic combinations in the region include illite, smectite, bound water, quartz, feldspar, calcite, pyrite, kerogen, free water, and oil. From here, the process added Pyrite and Kerogen incrementally to see how geologic model varies with number of components.

Although there were minor inconsistencies between the geologic models produced from measured and predicted triple combo logs in these three scenarios, the differences were localized and the model followed general trends well. Therefore, the difference between measured and predicted triple combo logs from the ML model did not result in significant discrepancies in the corresponding lithologic models. Additionally, integrating information from advanced logs obtained from nearby wells can lead to more realistic geological and petrophysical interpretations. One interesting observation here is that lithology inverted from ML predicted logs provides smoother interpretations eliminating thin laminations. This is because the machine learning model tried to avoid overfitting for generalization.

This disclosure presents a novel approach for estimating reservoir properties by combining machine learning with physics-based joint inversion. Real-time drilling dynamics data can be utilized to train a machine learning model and predict triple combo logs. The primary factors affecting drilling dynamics are identified as vibrations and engine load fluctuations, with noise and drilling pipe connections also playing a role.

The machine learning model can be trained using preprocessed drilling dynamics and triple combo measurements, and the proposed workflow is validated on blind test wells. The predicted logs agree well with the corresponding triple combo measurements and they can be used in the physics-based joint inversion model to estimate reservoir properties, enabling faster decision-making during drilling campaigns.

The approach may accurately predict reservoir properties, and the geologic model created using the inversion model parameters is successfully validated with ECS measurements. Additionally, the proposed workflow can provide geologic lithofacies with petrophysical properties to determine an optimized perforation plan, ultimately increasing hydrocarbon production and profitability.

Overall, this workflow provides real-time petrophysical well log interpretation with valuable insights into the subsurface formations being drilled, enabling better decision-making and improved drilling efficiency while reducing uncertainty in exploration and production projects. To enhance the accuracy of the inversion and further decrease uncertainties in reservoir characterizations, it may be beneficial to incorporate advanced logs acquired from neighboring wells such as image logs, core data, Nuclear Magnetic Resonance (NMR), fluid samples from Modular Formation Dynamics Tester (MDT), dipole or quadrupole sonic logs, dielectric logs, PEF, or ECS logs.

If the presented workflow is applied into a real-time drilling operation and simultaneously yield petrophysical well log interpretation with MWD measurements, it would have several advantages, including:
1. Immediate feedback: Real-time interpretations allowing for immediate feedback on the formation properties, enabling quick decisions to be made by operational geologists, drilling engineers, and geosteerers during drilling or completion operations.
2. Increased accuracy: Real-time interpretations enable the drilling team to make adjustments based on the most up-to-date data, which can improve the accuracy of well placement and reduce the risk of drilling into unexpected formations.
3. Cost savings: Real-time interpretations can help identify potential issues early on, which can reduce the risk of costly drilling mistakes or the need for expensive remedial actions.
4. Improved safety: Real-time interpretations can help identify potential hazards, such as unstable formations or high-pressure zones, which can improve the safety of drilling operations.
5. Enhanced efficiency: Real-time interpretations can help optimize drilling operations by enabling adjustments to be made in real-time, which can reduce drilling time and increase overall efficiency.

It is important to note that the models presented in this disclosure have certain limitations that should be taken into consideration. First, to obtain reasonable triple combo logs, the bottom hole assembly (BHA) and properties of the drilling mud used in both the training and test wells should be similar. Second, in order to apply the same inversion parameters, the formations and lithologies in both the training and test wells should be comparable. Last, the set points for drilling operations should be analogous to ensure consistent drilling dynamics for all wells.

Furthermore, there is potential for further improvement, such as refining the inversion parameters, reducing forward model errors, incorporating geological constraints for more realistic models, adding additional water saturation models, and optimizing regularizations. It would also be beneficial to improve the imputation of missing logs and remove the straight lines of interpolated predictions.

While the proposed workflow provides estimates of essential geological, petrophysical, and geomechanical properties from MWD logs, it should be noted that it cannot replace the values obtained from measured logs. Therefore, it should only be used for wells where LWD or wireline logs are not available. This workflow can be applied in real time during the drilling operations, which is one of the key benefits of proposed method herein.

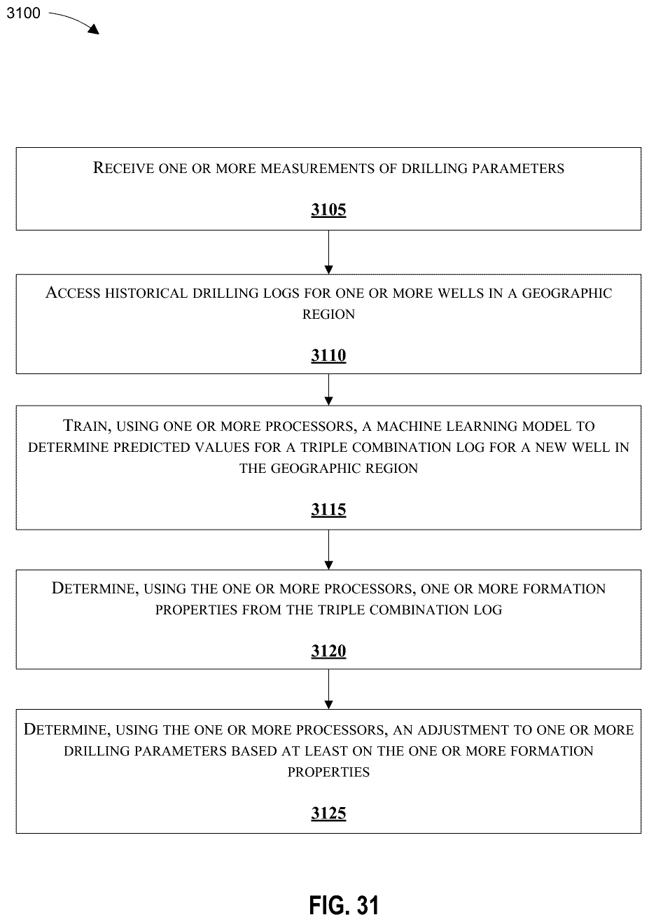

FIG. 31 is a flow chart of a process 3100 for drilling a well, according to an example of the present disclosure. According to an example, one or more process blocks of FIG. 31 may be performed by a computing device.

At block 3105, process 3100 may include receiving one or more measurements of drilling parameters. For example, the computing device may receive one or more measurements of drilling parameters, as described above. In various embodiments, the drilling parameters may include one or more of weight-on-bit, rate of penetration, torque, rotations per minute, or differential pressure.

At block 3110, process 3100 may include accessing historical drilling logs for one or more wells in a geographic region. For example, the computer device may access historical drilling logs for one or more wells in a geographic region, as described above.

At block 3115, process 3100 may include training, using one or more processors, a machine learning model to determine predicted values for a triple combo log for a new well in the geographic region. For example, the computing device may train, using one or more processors, a machine learning model to determine predicted values for a triple combo log for a new well in the geographic region, as described above.

At block 3120, process 3100 may include determining, using the one or more processors, one or more formation properties from the triple combo log. For example, the computing device may determine, using the one or more processors, one or more formation properties from the triple combo log, as described above.

At block 3125, process 3100 may include determining, using the one or more processors, an adjustment to one or more drilling parameters based at least on the one or more formation properties. For example, the computing device may determine, using the one or more processors, an adjustment to one or more drilling parameters based at least on the one or more formation properties, as described above.

Process 3100 may include additional implementations, such as any single implementation or any combination of implementations described below and/or in connection with one or more other processes described elsewhere herein.

In various embodiments, the historical drilling logs may include one or more of values for gamma ray, resistivity, neutron porosity, or bulk density.

In various embodiments, the training the machine learning model uses one or more of depth shifting, outlier detection, and feature selection to tune one or more parameters of the machine learning model.

In various embodiments, process 3100 may include applying one or more gradient boosting algorithms to train predictions sequentially for predicted values for the triple combo log.

In various embodiments, the one or more formation properties are predicted by applying a physics-based joint inversion model to the predicted values for the triple combo log.

In various embodiments, process 3100 may include determining one or more of reservoir properties may include total porosity, clay volume, water saturation, volumetric concentrations of lithology, permeability, rock type, or geomechanical parameters.

In various embodiments, process 3100 further includes determining a geologic model using the predicted values for a triple combo log; and validating the geologic model using one or more of mud logs and Elemental Capture Spectroscopy measurements.

In various embodiments, process 3100 may include identifying rock type of a formation using the triple combo log.

It should be noted that while FIG. 31 shows example blocks of process 3100, in some implementations, process 3100 may include additional blocks, fewer blocks, different blocks, or differently arranged blocks than those depicted in FIG. 31. Additionally, or alternatively, two or more of the blocks of process 3100 may be performed in parallel.

It is to be noted that the foregoing description is not intended to limit the scope of the claims. For example, it is noted that the disclosed methods and systems include additional features and can use additional drilling parameters and relationships beyond the examples provided. The examples and illustrations provided in the present disclosure are for explanatory purposes and should not be considered as limiting the scope of the invention, which is defined only by the following claims.

### NOMENCLATURE

### Abbreviations

BHA=Bottom Hole Assembly
CCS=Confined Compressive Strength
DTC=Compressional Sonic Slowness
DTS=Shear Sonic Slowness
ECS=Elemental Capture Spectroscopy
FANG=Angle of Internal Friction
GR=Gamma Ray
HFU=Hydraulic Flow Unit
KL=Kullback-Leibler
LWD=Logging While Drilling
MBE=Material Balanced Equation
ML=Machine Learning
MSE=Mechanical Specific Energy
MWD=Measurement While Drilling
PEF=Photoelectric Factor
ROP=Rate of Penetration
RPM=Rotation per Minute
QI=Quantitative Interpretation
RCA=Routine Core Analysis
RQI=Reservoir Quality Index
RT=Rock Type
SVR=Support Vector Regression
TOC=Total Organic Content
UCS=Unconfined Compressive Strength
WOB=Weight on Bit
XGBoost=Extreme Gradient Boosting
XGBR=Extreme Gradient Boosting Regression
XRD=X-Ray Diffraction
XRF=X-Ray Fluorescence

What is claimed is:

1. A method for drilling a borehole, comprising:
receiving one or more measurements of drilling parameters;
accessing historical drilling logs for one or more wells in a geographic region;
training, using one or more processors, a machine learning model to determine predicted values for a triple combo log for a new well in the geographic region;
determining, using the one or more processors, one or more formation properties from the triple combo log; and
determining, using the one or more processors, an adjustment to one or more drilling parameters based at least on the one or more formation properties.

2. The method of claim 1, wherein the drilling parameters comprise one or more of weight-on-bit, rate of penetration, torque, rotations per minute, or differential pressure.

3. The method of claim 1, wherein the historical drilling logs comprise one or more of values for gamma ray, resistivity, neutron porosity, or bulk density.

4. The method of claim 1, wherein the training the machine learning model uses one or more of depth shifting, outlier detection, and feature selection to tune one or more parameters of the machine learning model.

5. The method of claim 1, further comprising applying one or more gradient boosting algorithms to train predictions sequentially for predicted values for the triple combo log.

6. The method of claim 1, wherein the one or more formation properties are predicted by applying a physics-based joint inversion model to the predicted values for the triple combo log.

7. The method of claim 6, further comprising determining one or more of reservoir properties comprising total porosity, clay volume, water saturation, volumetric concentrations of lithology, permeability, rock type, or geomechanical parameters.

8. The method of claim 1, further comprising:
determining a geologic model using the predicted values for a triple combo log; and
validating the geologic model using one or more of mud logs and Elemental Capture Spectroscopy measurements.

9. The method of claim 1, further comprising identifying rock type of a formation using the triple combo log.

10. The method of claim 1, further comprising drilling a portion of a wellbore in accordance with the one or more formation properties and/or the drilling parameters.

11. The method of claim 1, wherein the method is performed in real-time during drilling of a wellbore.

12. The method of claim 1, further comprising steering the wellbore responsive to the triple combo log.

13. A system for drilling a borehole, comprising:
one or more sensors;
a drilling rig;
one or more processors; and
a memory storing instructions when executed by the one or more processors perform operations, comprising:
receiving one or more measurements of drilling parameters from the one or more sensors;
accessing historical drilling logs for one or more wells in a geographic region;
training, using one or more processors, a machine learning model to determine predicted values for a triple combo log for a new well in the geographic region;
determining, using the one or more processors, one or more formation properties from the triple combo log;
determining, using the one or more processors, an adjustment to one or more drilling parameters; and
drilling the borehole using the adjustment to the one or more drilling parameters at the drilling rig.

14. The system of claim 13, wherein the drilling parameters comprise one or more of weight-on-bit, rate of penetration, torque, rotations per minute, or differential pressure.

15. The system of claim 13, wherein the historical drilling logs comprise one or more of values for gamma ray, resistivity, neutron porosity, or bulk density.

16. The system of claim 13, wherein the training the machine learning model uses one or more of depth shifting, outlier detection, and feature selection to tune one or more parameters of the machine learning model.

17. The system of claim 13, wherein the operations further comprise applying one or more gradient boosting algorithms to train predictions sequentially for predicted values for the triple combo log.

18. The system of claim 13, wherein the one or more formation properties are predicted by applying a physics-based joint inversion model to the predicted values for the triple combo log.

19. The system of claim 18, wherein the operations further comprise determining one or more of reservoir properties comprising total porosity, clay volume, water saturation, volumetric concentrations of lithology, permeability, rock type, or geomechanical parameters.

20. The system of claim 13, wherein the operations further comprise:
determining a geologic model using the predicted values for a triple combo log; and
validating the geologic model using one or more of mud logs and Elemental Capture Spectroscopy measurements.

21. The system of claim 13, wherein the operations further comprise identifying rock type of a formation using the triple combo log.

22. A non-transitory computer readable medium storing instructions that when executed by one or more processors perform operations comprising:
receiving one or more measurements of drilling parameters from the one or more sensors;
accessing historical drilling logs for one or more wells in a geographic region;
training, using one or more processors, a machine learning model to determine predicted values for a triple combo log for a new well in the geographic region;
determining, using the one or more processors, one or more formation properties from the triple combo log;
determining, using the one or more processors, an adjustment to one or more drilling parameters; and
drilling the borehole using the adjustment to the one or more drilling parameters at the drilling rig.

23. The non-transitory computer readable medium of claim 22, wherein the drilling parameters comprise one or more of weight-on-bit, rate of penetration, torque, rotations per minute, or differential pressure.

24. The non-transitory computer readable medium of claim 22, wherein the historical drilling logs comprise one or more of values for gamma ray, resistivity, neutron porosity, or bulk density.

25. The non-transitory computer readable medium of claim 22, wherein the training the machine learning model uses one or more of depth shifting, outlier detection, and feature selection to tune one or more parameters of the machine learning model.

26. The non-transitory computer readable medium of claim 22, wherein the operations further comprise applying one or more gradient boosting algorithms to train predictions sequentially for predicted values for the triple combo log.

27. The non-transitory computer readable medium of claim 22, wherein the one or more formation properties are predicted by applying a physics-based joint inversion model to the predicted values for the triple combo log.

28. The non-transitory computer readable medium of claim 27, wherein the operations further comprise determining one or more of reservoir properties comprising total porosity, clay volume, water saturation, volumetric concentrations of lithology, permeability, rock type, or geomechanical parameters.

29. The non-transitory computer readable medium of claim 22, wherein the operations further comprise:
determining a geologic model using the predicted values for a triple combo log; and
validating the geologic model using one or more of mud logs and Elemental Capture Spectroscopy measurements.

30. The non-transitory computer readable medium of claim 22, wherein the operations further comprise identifying rock type of a formation using the triple combo log.
